(19) United States
(12) Patent Application Publication
(10) Pub. No.: US 2025/0220894 A1
(43) Pub. Date: Jul. 3, 2025

(54) SEMICONDUCTOR MEMORY DEVICE

(71) Applicant: SAMSUNG ELECTRONICS CO., LTD., SUWON-SI, GYEONGGI-DO (KR)

(72) Inventors: SEUNGHOON KIM, Suwon-si (KR); MISO MYUNG, Suwon-si (KR); MINSOO KIM, Suwon-si (KR); YONG KWAN KIM, Suwon-si (KR); HUI-JUNG KIM, Suwon-si (KR); SANGJAE PARK, Suwon-si (KR); KISEOK LEE, Suwon-si (KR); HYUNJIN LEE, Suwon-si (KR); INHO CHA, Suwon-si (KR)

(21) Appl. No.: 18/907,640

(22) Filed: Oct. 7, 2024

(30) Foreign Application Priority Data
Dec. 27, 2023 (KR) 10-2023-0192116

(51) Int. Cl. H10B 12/00

(52) U.S. Cl. CPC H10B 12/50; H10B 12/315; H10B 12/482; H10B 12/485; H10B 12/488

(57) ABSTRACT

A semiconductor memory device is provided. The device includes a cell structure, a peripheral structure, and an interconnection structure sequentially stacked on a support substrate, in which the cell structure includes lower electrodes, a dielectric layer and an upper electrode with the dielectric layer and the upper electrode sequentially covering the lower electrodes, the peripheral structure includes a peripheral substrate and transistors disposed on a front surface of the peripheral substrate, and an upper surface of the upper electrode faces a back surface of the peripheral substrate.

### CROSS-REFERENCE TO RELATED APPLICATIONS

This U.S. non-provisional patent application claims priority under 35 U.S.C. § 119 to Korean Patent Application No. 10-2023-0192116, filed on Dec. 27, 2023, in the Korean Intellectual Property Office, the entire contents of which are herein incorporated by reference.

### TECHNICAL FIELD

The present inventive concept relates to a semiconductor memory device, and more particularly, relates to a semiconductor memory device including vertical channel transistors and a method of manufacturing the same.

### DISCUSSION OF RELATED ART

As a semiconductor device is scaled down, it may be necessary to develop a fabrication technology capable of increasing an integration density of the semiconductor device and enhancing an operation speed and a yield. Accordingly, a transistor with a vertical channel has been proposed to enhance an integration density of the semiconductor device, and to have a lower electrical resistance property and a higher current driving capability of the transistor.

A semiconductor memory device may include a cell structure and a peripheral structure. The cell structure may include memory cell arrays having memory cells formed of vertical channel transistors, and the peripheral structure may include peripheral circuits for driving the memory cell arrays. To reduce the horizontal area, arranging the cell structure and the peripheral structure vertically has been proposed. By stacking the peripheral structure and the cell structure vertically, the size of the semiconductor memory device may decrease, and accordingly, the number of memory cells can be integrated into the semiconductor memory device may increase.

### SUMMARY

The present inventive concept provides a semiconductor memory device with enhanced electrical characteristics and integration.

The problem to be solved by the present inventive concept is not limited to the problems mentioned above, and other problems not mentioned will be clearly understood by those skilled in the art from the description below.

A semiconductor memory device according to an embodiment of the present inventive concept includes a cell structure, a peripheral structure, and an interconnection structure sequentially stacked on a support substrate, in which the cell structure includes lower electrodes, a dielectric layer and an upper electrode with the dielectric layer and the upper electrode sequentially covering the lower electrodes, the peripheral structure includes a peripheral substrate and transistors disposed on a front surface of the peripheral substrate, and an upper surface of the upper electrode faces a back surface of the peripheral substrate.

A semiconductor memory device according to an embodiment of the present inventive concept includes a first peripheral structure, a cell structure, and an interconnection structure stacked sequentially, in which the cell structure includes a first cell insulating layer, cell connection pads disposed within and at a lower end of the first cell insulating layer, lower electrodes disposed on the first cell insulating layer, and a dielectric layer and an upper electrode, the dielectric layer and the upper electrode sequentially covering the lower electrodes, the first peripheral structure includes a first peripheral substrate, a first peripheral insulating layer covering a back surface of the first peripheral substrate, peripheral connection pads disposed within and at an upper end of the first peripheral insulating layer and connected to the cell connection pads, and first peripheral transistors disposed on a front surface of the first peripheral substrate, and lower surface of the upper electrode faces the back surface of the first peripheral substrate.

A semiconductor memory device according to an embodiment of the present inventive concept includes a peripheral structure, a cell structure, and an interconnection structure stacked sequentially, in which the peripheral structure includes a peripheral substrate, transistors disposed on a front surface of the peripheral substrate, a first peripheral insulating layer covering the front surface of the peripheral substrate, and first peripheral interconnections disposed within the first peripheral insulating layer, the cell structure includes first to third cell insulating layers sequentially covering the peripheral structure, first cell interconnections disposed in the first cell insulating layer, lower electrodes, a dielectric layer, and an upper electrode disposed in the second cell insulating layer, and active patterns, word lines, and bit lines disposed in the third cell insulating layer, the bit lines connect upper surfaces of the active patterns and extend in a first direction, the word lines are adjacent to one side of the active patterns and extend in a second direction intersecting the first direction, the dielectric layer and the upper electrode sequentially cover sidewalls and lower surfaces of the lower electrodes, and a first distance between the upper electrode and the peripheral substrate is smaller than a second distance between the lower electrodes and the peripheral substrate.

### BRIEF DESCRIPTION OF THE DRAWINGS

Embodiments of the present inventive concept will be more clearly understood from the following brief description taken in conjunction with the accompanying drawings in which:

FIG. 1A is a block diagram of a semiconductor memory device including a semiconductor device according to an embodiment of the present inventive concept;

FIG. 1B is a schematic perspective view of a semiconductor memory device according to an embodiment of the present inventive concept;

FIG. 2 is a plan view of a semiconductor memory device according to an embodiment of the inventive concept;

FIG. 3 is a cross-sectional view taken along line A-A′ of FIG. 2 according to an embodiment of the present inventive concept;

FIG. 4 is an enlarged view of portion ‘P1’ of FIG. 3 according to an embodiment of the present inventive concept;

FIGS. 5A to 5H are cross-sectional views sequentially showing a process of manufacturing the semiconductor memory device of FIG. 3 according to an embodiment of the present inventive concept;

FIG. 6 is a cross-sectional view taken along line A-A′ of FIG. 2 according to an embodiment of the present inventive concept;

FIGS. 7A to 7I are cross-sectional views sequentially showing a process of manufacturing the semiconductor memory device of FIG. 6 according to an embodiment of the present inventive concept;

FIG. 8 is a cross-sectional view taken along line A-A′ of FIG. 2 according to an embodiment of the present inventive concept;

FIG. 9 is a cross-sectional view taken along line A-A′ of FIG. 2 according to an embodiment of the present inventive concept;

FIG. 10 is a cross-sectional view taken along line A-A′ of FIG. 2 according to an embodiment of the present inventive concept;

FIG. 11 is a cross-sectional view taken along line A-A′ of FIG. 2 according to an embodiment of the present inventive concept;

FIG. 12 is a cross-sectional view taken along line A-A′ of FIG. 2 according to an embodiment of the present inventive concept;

FIG. 13 is a cross-sectional view taken along line A-A′ of FIG. 2 according to an embodiment of the present inventive concept;

FIGS. 14A to 14J are plan views each showing an arrangement of word line contact plugs according to an embodiment of the present inventive concept;

FIGS. 15A to 15H are plan views each showing an arrangement of back gate line contact plugs according to an embodiment of the present inventive concept;

FIGS. 16A to 16H are perspective views showing structures of bit lines and shield lines each according to an embodiment of the present inventive concept;

FIGS. 17A to 17G are plan views each showing an arrangement of bit line contact plugs according to an embodiment of the present inventive concept;

FIGS. 18A to 18L are plan views each showing an arrangement of shield line contact plugs according to an embodiment of the present inventive concept;

FIG. 19 is a cross-sectional view taken along line A-A′ of FIG. 2 according to an embodiment of the present inventive concept;

FIG. 20 is a cross-sectional view taken along line A-A′ of FIG. 2 according to an embodiment of the present inventive concept;

FIG. 21 is a cross-sectional view taken along line A-A′ of FIG. 2 according to an embodiment of the present inventive concept;

FIGS. 22A to 22G are plan views each showing an arrangement of an upper electrode and upper electrode contact plugs according to an embodiment of the present inventive concept;

FIG. 23 is a cross-sectional view taken along line A-A′ of FIG. 2 according to an embodiment of the present inventive concept;

FIGS. 24A to 24C are plan views of semiconductor memory devices each according to an embodiment of the present inventive concept;

FIGS. 25A to 25E are plan views each showing an arrangement and shape of cell connection pads and peripheral connection pads according to an embodiment of the present inventive concept;

FIG. 26 is an enlarged view of ‘P2’ of FIG. 6 according to an embodiment of the present inventive concept;

FIGS. 27A to 27D are enlarged views of ‘P3’ in FIG. 6 each according to an embodiment of the present inventive concept;

FIG. 28 is a cross-sectional view taken along line A-A′ of FIG. 2 according to an embodiment of the present inventive concept;

FIG. 29 is a cross-sectional view taken along line A-A′ of FIG. 2 according to an embodiment of the present inventive concept; and

FIGS. 30A to 30E are plan views each showing an arrangement and structure of word lines and active patterns according to an embodiment of the present inventive concept.

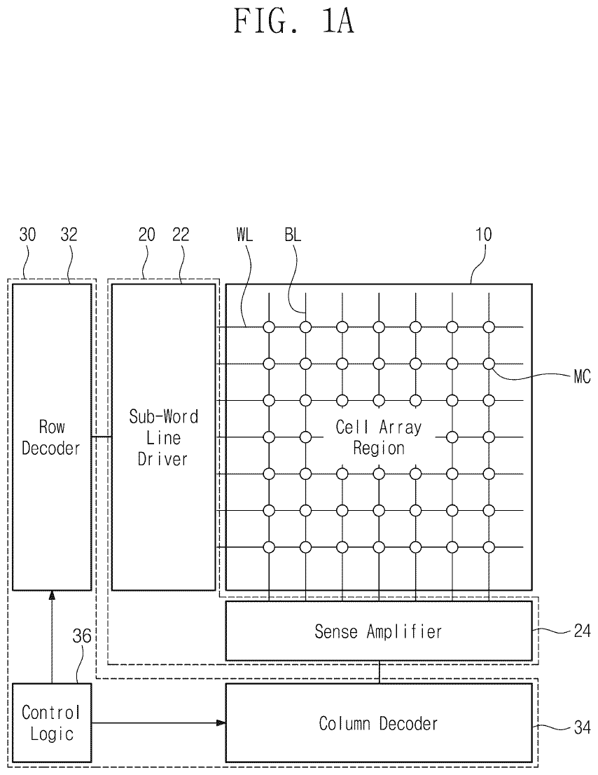

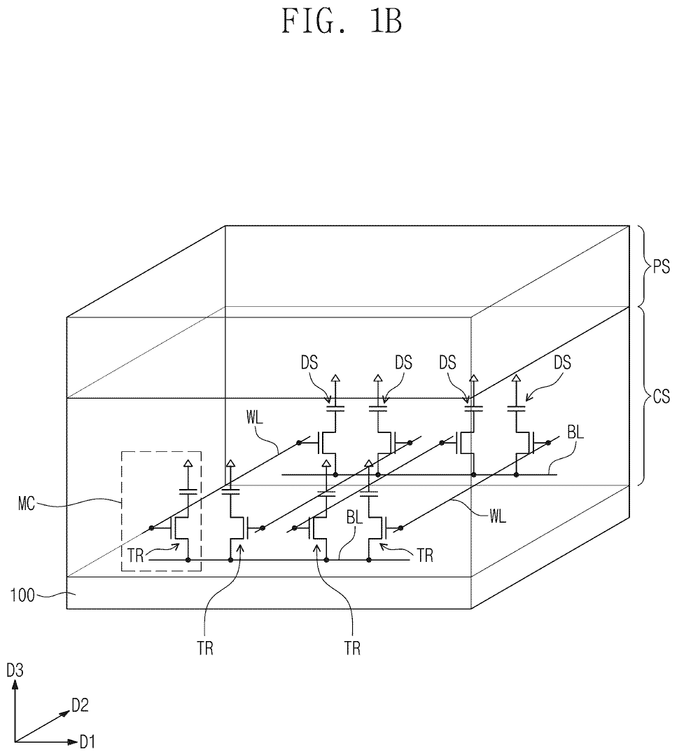

Since the drawings in FIGS. 1A-30E are intended for illustrative purposes, the elements in the drawings are not necessarily drawn to scale. For example, some of the elements may be enlarged or exaggerated for clarity purpose.

### DETAILED DESCRIPTION OF THE EMBODIMENTS

Hereinafter, with reference to the drawings, a semiconductor memory device and a manufacturing method thereof according to embodiments of the present inventive concept will be described in detail.

FIG. 1A is a block diagram of a semiconductor memory device including a semiconductor device according to an embodiments of the present inventive concept.

Referring to FIG. 1A, a semiconductor memory device according to the present embodiment may include a cell array region 10. Word lines WL and bit lines BL that intersect each other may be arranged in the cell array region 10. A plurality of memory cells MC may be arranged two-dimensionally or three-dimensionally in the cell array region 10. When the plurality of memory cells MC are arranged three-dimensionally, a plurality of memory cell strings may be two-dimensionally arranged along first and second directions D1 and D2, and may extend along a third direction D3. Each of the memory cells MC may be connected between the word line WL and the bit line BL that intersect each other.

A core region 20 may be disposed around the cell array region 10. A sub-word line driver 22 and a sense amplifier 24 may be disposed in the core region 20. A peripheral circuit region 30 may be disposed around the core region 20. A row decoder 32, a column decoder 34, and a control logic 36 may be disposed in the peripheral circuit region 30.

The row decoder 32 may decode an externally input row address signal or refresh address signal. For example, the row decoder 32 may select memory cells and at least one of the world lines WL according to the input row address signal, and may further transmit a voltage for performing a memory operation to the word line WL of the selected memory cells. The sub-word line driver 22 may perform a function of selecting a specific word line WL in response to the row address signal or the refresh address signal.

The sense amplifier 24 may detect and amplify a voltage difference between the selected bit line BL and the reference bit line in response to the address decoded from the column decoder 34, and may output the amplified voltage difference.

The column decoder 34 may provide a data transmission path between sense amplifier 24 and an external device (e.g., memory controller). The column decoder 34 may decode an externally input column address signal and may select one of the bit lines BL.

The control logic 36 may generate control signals that control operations for writing or reading data into the memory cell array of the cell array region 10. The control logic 36 may generate various internal control signals used in the semiconductor memory device in response to a control signal. For example, the control logic 36 may adjust a voltage level of a voltage supplied to the word line WL and the bit line BL when performing a memory operation such as, for example, a program operation or an erase operation.

FIG. 1B is a schematic perspective view of a semiconductor memory device according to an embodiment of the present inventive concept.

Referring to FIGS. 1A and 1B, a semiconductor memory device may include a support substrate 100, a cell structure CS, and a peripheral structure PS that are sequentially stacked. However, the present inventive concept is not limited thereto. For example, unlike FIG. 1B, the peripheral structure PS may be disposed between the support substrate 100 and the cell structure CS.

The peripheral structure PS may include the core region 20 and the peripheral circuit region 30 of FIG. 1A. The sub-word line driver 22 and the sense amplifier 24 may be disposed in the core region 20. The row decoder 32, the column decoder 34, and the control logic 36 may be disposed in the peripheral circuit region 30.

The cell structure CS may include the cell array region 10 of FIG. 1A. The cell array region 10 may include bit lines BL, word lines WL, and memory cells MC (e.g., in FIG. 1A) therebetween. The memory cells MC (e.g., in FIG. 1A) may be arranged two-dimensionally or three-dimensionally on a plane extending in first and second directions D1 and D2 that intersect each other. As described above, each of the memory cells MC (e.g., in FIG. 1A) may include a selection element TR and a data storage element DS. When the memory cells MC are arranged three-dimensionally, the selection element TR may include a cell string which includes a plurality of memory cell transistors respectively located at different levels.

Alternatively, according to an embodiment of the present inventive concept, each memory cell MC (e.g., in FIG. 1A) may include a vertical channel transistor (VCT) as a selection element TR. The vertical channel transistor may have a structure in which a channel length extends in a direction perpendicular to an upper surface of the support substrate 100 (i.e., a third direction D3). For example, when the memory cells MC are arranged three-dimensionally, a plurality of memory cell transistors extending along the third direction D3 may use a vertical channel structure as channel regions. Additionally, a capacitor may be provided as a data storage element DS of each memory cell MC (e.g., in FIG. 1A).

The cell structure CS may include a plurality of cell array regions 10. The peripheral structure PS may include a plurality of core regions 20. The cell array regions 10 may each vertically overlap the corresponding one of the core regions 20.

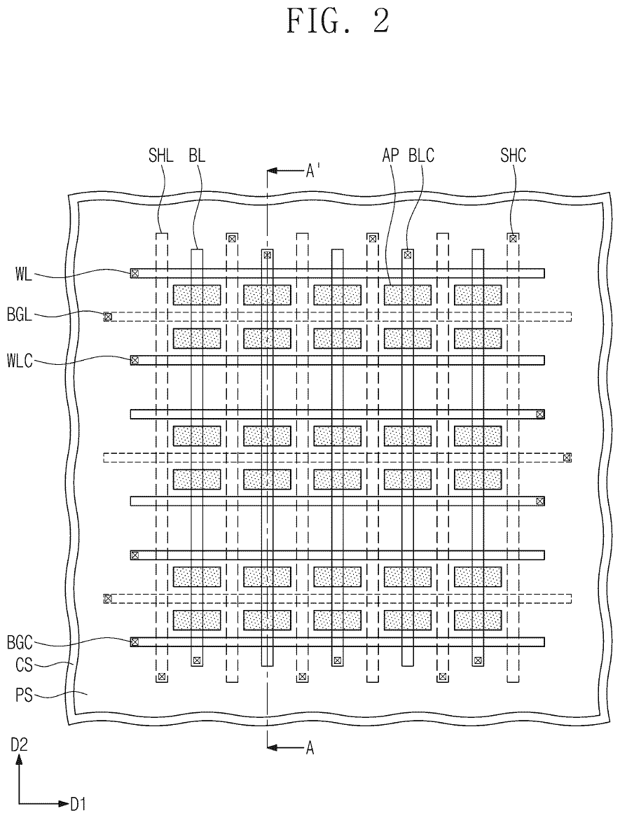

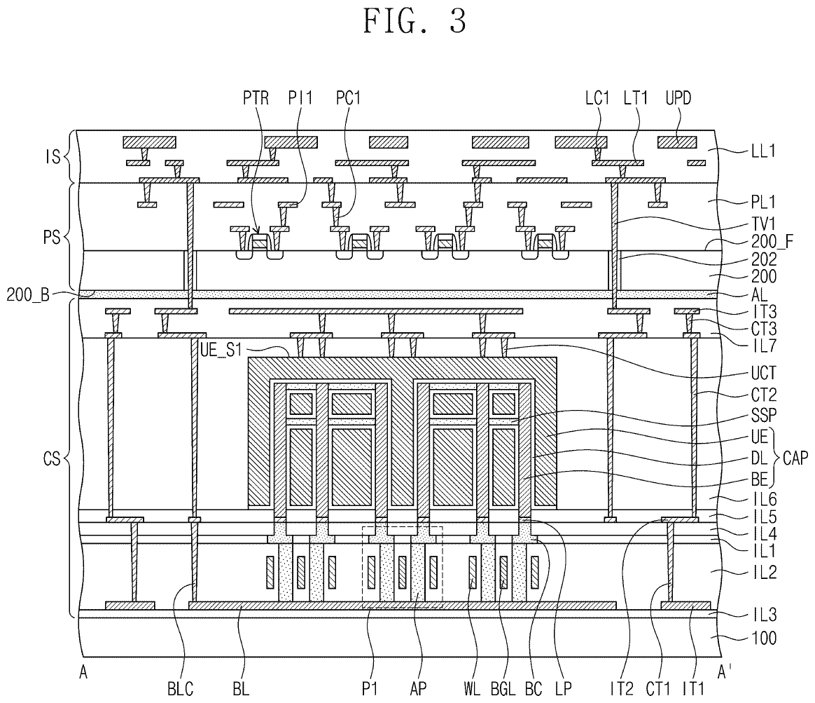

FIG. 2 is a plan view of a semiconductor memory device according to an embodiment of the present inventive concept. FIG. 3 is a cross-sectional view taken along line A-A′ of FIG. 2 according to an embodiment of the present inventive concept.

Referring to FIGS. 2 and 3, a semiconductor memory device may include a support substrate 100, a cell structure CS, a peripheral structure PS, and an interconnection structure IS that are sequentially stacked. The support substrate 100 may be, for example, a semiconductor substrate, a silicon on insulator (SOI) substrate, a III-V compound semiconductor substrate, a single-crystalline epitaxial layer grown on a single-crystalline silicon (sc-Si) substrate, or an insulating substrate. In an embodiment of the present inventive concept, the support substrate 100 may include impurities. For example, the cell substrate 100 may include n-type impurities (e.g., phosphorus (P), arsenic (As), etc.).

Referring to FIGS. 2 and 3, the cell structure CS may include multi-layered first to seventh cell insulating layers IL1 to IL7, bit lines BL, with shield lines SHL, word lines WL, back gate lines BGL, and capacitors CAP disposed therein. Each of the first to seventh cell insulating layers IL1 to IL7 may have a single-layer or multi-layer structure of at least one of, for example, silicon oxide (SiO₂), silicon nitride (Si₃N₄), silicon oxynitride (SiON), or porous insulator. In an embodiment of the present inventive concept, one or more of the first to seventh cell insulating layers IL1 to IL7 may include a low-k material having a dielectric constant lower than that of the silicon oxide (SiO₂).

In detail, the third cell insulating layer IL3 is in contact with the support substrate 100. The bit lines BL, the shield lines SHL, and the first cell interconnections IT1 are disposed on the third cell insulating layer IL3. The bit lines BL and the shield lines SHL may extend in the second direction D2 and be spaced apart from each other in the first direction D1. The shield lines SHL may be interposed between the bit lines BL.

The bit lines BL, the shield lines SHL, and first cell interconnections IT1 may be covered with the second cell insulating layer IL2. Active patterns AP may penetrate the second cell insulating layer IL2 and may be in contact with the bit lines BL. The Active patterns AP may be disposed between lower electrodes BE (to be described) and the support substrate 100, and may be arranged two-dimensionally along an upper surface of the support substrate 100. The bit lines BL may be disposed between the active patterns AP and the support substrate 100, and may extend in the second direction D2. The word line WL is disposed on one side of one of the active patterns AP and the back gate line BGL is disposed on the other side of the one active pattern AP. The back gate line BGL is interposed between adjacent active patterns AP. The word lines WL and the back gate lines BGL may extend in the first direction D1, and may be spaced apart from each other in the second direction D2. For example, the word lines WL may be adjacent to sidewalls of the active patterns AP and extending in the first direction D1 intersecting the second direction D2.

The first cell insulating layer IL1 is disposed on the second cell insulating layer IL2. The fourth cell insulating layer IL4 is disposed on the first cell insulating layer IL1. Storage node contacts BC may penetrate the fourth cell insulating layer IL4 and the first cell insulating layer IL1 to be in contact with upper ends of the active patterns AP. The storage node contact BC may have a wider width within the first cell insulating layer IL1 than within the fourth cell insulating layer IL4.

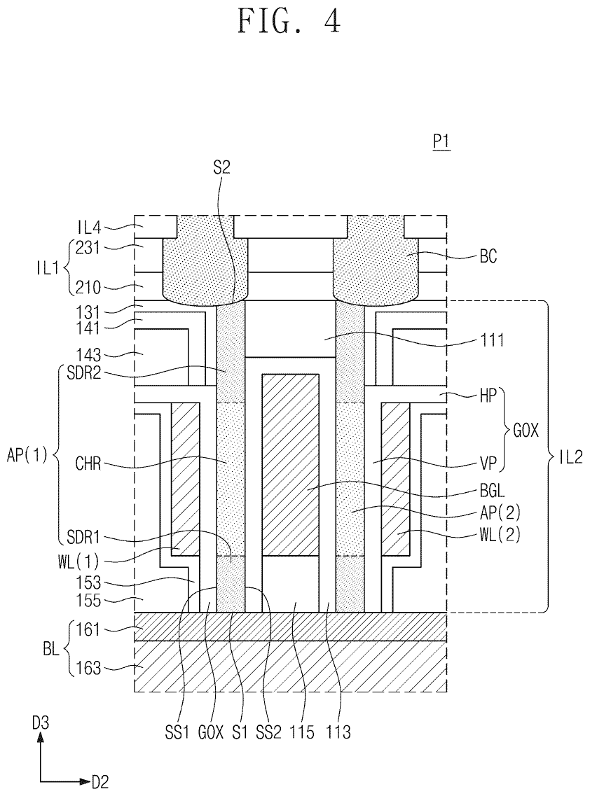

FIG. 4 is an enlarged view of portion ‘P1’ of FIG. 3 according to an embodiment of the present inventive concept.

Referring to FIGS. 2 to 4, the second cell insulating layer IL2 may include layers 111, 113, 115, GOX, 131, 141, 143, 153, and 155 formed of an insulating material. Each of the bit lines BL may include a polysilicon (p-Si) pattern 161 and a metal pattern 163 that are sequentially stacked. Each of the shield lines SHL may have at least one of a polysilicon (p-Si) pattern 161 or a metal pattern 163. A level of an upper surface of each of the bit lines BL may be the same as or different from a level of an upper surface of each of the shield lines SHL. A level of a lower surface of each of the bit lines BL may be the same as or different from a level of a lower surface of each of the shield lines SHL. The metal pattern 163 may include a conductive metal nitride (e.g., titanium nitride (TiN), tantalum nitride (TaN), etc.) and a metal (e.g., tungsten (W), titanium (Ti), tantalum (Ta), etc.). The metal pattern 163 may include metal silicide, such as, for example, titanium silicide (TiSi₂), tungsten silicide (WSi₂), cobalt silicide (CoSi₂), or nickel silicide (NiSi₂).

Referring to FIGS. 2 to 4, the active patterns AP may include a pair of first active patterns AP(1) and second active patterns AP(2) adjacent to each other in the second direction D2. The word lines WL may include a pair of first word lines WL(1) and second word lines WL(2) adjacent to each other in the second direction D2.

The active patterns AP may be formed of a single crystal semiconductor material. As an example, the active patterns AP may be formed of single crystal silicon (sc-Si). Each of the first active pattern AP(1) and the second active pattern AP(2) may have a length in the first direction D1 and a width in the second direction D2, and a length in a vertical direction perpendicular to the first and second directions D1 and D2. Each of the first active pattern AP(1) and the second active pattern AP(2) may have a substantially uniform width.

A width of the first active pattern AP(1) and the second active pattern AP(2) may be several nanometers to tens of nanometers. For example, the width of the first active pattern AP(1) and the second active pattern AP(2) may be in a range from about 1 nm to about 30 nm. For example, the width of the first active pattern AP(1) and the second active pattern AP(2) may be in a range from about 1 nm to about 10 nm. A length of each of the first active pattern AP(1) and the second active pattern AP(2) may be larger than a line width of the bit line BL. When the term “about” is used in this specification in connection with a numerical value, it is intended that the associated numerical value includes a tolerance of up to +10% around the stated numerical value.

Each of the first active pattern AP(1) and the second active pattern AP(2) may have a first surface S1 and a second surface S2 that are opposite to each other in the third direction D3 perpendicular to the first direction D1 and the second direction D2. In an embodiment of the present inventive concept, the first surfaces S1 of the first active pattern AP(1) and the second active pattern AP(2) may be in contact with the polysilicon (p-Si) pattern 161 of the bit line BL, and when the polysilicon pattern (p-Si) 161 is omitted, may be in contact with the metal pattern 163.

Each of the first active pattern AP(1) and the second active pattern AP(2) may have a first side SS1 and a second side SS2 that are opposite to each other in the second direction D2. The first side SS1 of the first active pattern AP(1) may be adjacent to the first word line WL(1), and the second side SS2 of the second active pattern AP(2) may be adjacent to the second word line WL(2).

The first active pattern AP(1) and the second active pattern AP(2) may each include a first dopant region SDR1 adjacent to the bit line BL, a second dopant region SDR2 adjacent to the storage node contact BC, and a channel region CHR between the first and second dopant regions SDR1 and SDR2. The first and second dopant regions SDR1 and SDR2 may be regions doped with a dopant in the first active pattern AP(1) and the second active pattern AP(2), and a dopant concentration in the first active pattern AP(1) and the second active pattern AP(2) may be greater than a dopant concentration in the channel region CHR. In an embodiment of the present inventive concept, the channel region CHR may not be doped with a dopant.

The selection element TR or the vertical channel transistor in FIG. 1A may be constituted with a portion of the word line WL adjacent to one active pattern AP serving as a gate electrode, the first and second dopant regions SDR1 and SDR2 doped within the one active pattern AP serving as source/drain regions, and the channel region CHR between the first and second dopant regions SDR1 and SDR2 serving as a channel.

In this specification, a vertical channel transistor is disclosed as a selection element TR, but the present inventive concept is not limited thereto, and the selection element TR may have a form of, for example, a planar transistor, a fin field-effect transistor (FinFET), a multi-bridge channel FET (MBCFET), a gate all around (GAA) transistor, or a buried channel array transistor (BCAT).

The channel regions CHR of the first active pattern AP(1) and the second active pattern AP(2) may be controlled by the first and second word lines WL(1) and WL(2) and the back gate lines BGL during operation of the semiconductor memory device. As the first active pattern AP(1) and the second active pattern AP(2) are formed of a single crystal semiconductor material, leakage current characteristics may be enhanced during the operation of the semiconductor memory device.

The back gate lines BGL may be arranged to be spaced apart from each other at a certain distance in the second direction D2 on the bit lines BL. The back gate lines BGL may extend in the first direction D1 across the bit lines BL.

Each of the back gate lines BGL may be disposed between a pair of first active patterns AP(1) and second active patterns AP(2) adjacent to each other in the second direction D2. For example, the first active pattern AP(1) may be disposed on one side of each of the back gate lines BGL, and the second active pattern AP(2) may be disposed on the other side of the back gate lines BGL. The back gate lines BGL may have a height smaller than a height of the first active pattern AP(1) and the second active pattern AP(2) in the vertical direction.

The back gate line BGL may have a first surface close to the bit line BL and a second surface close to the storage node contact BC. Referring to FIG. 4, the first surface of the back gate line BGL may be a lower surface or a bottom surface, and the second surface of the back gate line BGL may be an upper surface or a top surface. The first and second surfaces of the back gate line BGL may be vertically spaced apart from the first and second surfaces S1 and S2 of the first active pattern AP(1) and the second active pattern AP(2).

A level of an upper surface of each of the back gate lines BGL may be the same as or different from a level of an upper surface of each of the word lines WL. A level of a lower surface of each of the back gate lines BGL may be the same as or different from a level of a lower surface of each of the word lines WL.

The back gate lines BGL may be formed of, for example, doped polysilicon (p-Si), a conductive metal nitride (e.g., titanium nitride (TiN), tantalum nitride (TaN), etc.), a metal (e.g., tungsten (W), titanium (Ti), tantalum (Ta), etc.), a conductive metal silicide (e.g., titanium silicide (TiSi₂), tungsten silicide (WSi₂), cobalt silicide (CoSi₂), nickel silicide (NiSi₂), etc.), a conductive metal oxide (e.g., iridium oxide (IrO₂), ruthenium oxide (RuO₂), strontium ruthenium oxide (SrRuO₃), etc.), or a combination thereof.

During the operation of the semiconductor memory device, a negative voltage may be applied to the back gate lines BGL, and the threshold voltage of the vertical channel transistor may be increased. For example, as the vertical channel transistor is miniaturized, the threshold voltage may decrease, and thus, leakage current characteristics may be prevented from deteriorating.

A first insulating pattern 111 may be disposed between the first active pattern AP(1) and the second active pattern AP(2), which are adjacent to each other in the second direction D2. The first insulating pattern 111 may be disposed between the second dopant region SDR2 of the first active pattern AP(1) and the second dopant region SDR2 of the second active pattern AP(2). The first insulating pattern 111 may include, for example, a silicon oxide (SiO₂) layer, a silicon oxynitride (SiON) layer, or a silicon nitride (Si₃N₄) layer.

A back gate insulating pattern 113 may be disposed between the back gate line BGL and the first and second active patterns AP(1) and AP(2), and between the back gate line BGL and the first insulating pattern 111, respectively. The back gate insulating pattern 113 may include vertical portions covering both sides of the back gate line BGL and a horizontal portion connecting the vertical portions. The horizontal portion of the back gate insulating pattern 113 may be closer to the storage node contact BC than the bit line BL and may cover the second surface of the back gate line BGL.

The back gate insulating pattern 113 may be formed of a silicon oxide (SiO₂) layer, a silicon oxynitride (SiON) layer, a high-k dielectric layer having a dielectric constant higher than that of the silicon oxide (SiO₂) layer, or a combination thereof.

A back gate capping pattern 115 may be disposed between the bit lines BL and the back gate line BGL. The back gate capping pattern 115 may be formed of an insulating material, and a lower surface of the back gate capping pattern 115 may be in contact with the polysilicon (p-Si) pattern 161 of the bit lines BL. The back gate capping pattern 115 may be disposed between the vertical portions of the back gate insulating pattern 113. A thickness of the back gate capping pattern 115 between the bit lines BL may be different from a thickness of the back gate capping pattern 115 on the bit lines BL.

The first word line WL(1) and the second word line WL(2) may include, for example, doped polysilicon (p-Si), a metal, a conductive metal nitride, a conductive metal silicide, a conductive metal oxide, or a combination thereof. Gate insulating patterns GOX may be disposed between the first and second word lines WL(1) and WL(2) and the first and second active patterns AP(1) and AP(2). The gate insulating patterns GOX may extend in the first direction D1 parallel to the first and second word lines WL(1) and WL(2).

The gate insulating pattern GOX may be formed of, for example, a silicon oxide (SiO₂) layer, a silicon oxynitride (SiON) layer, a high-k dielectric layer having a dielectric constant higher than that of the silicon oxide (SiO₂) layer, or a combination thereof. The high-k dielectric layer may be formed of, for example, metal oxide or metal oxynitride. For example, the high-k dielectric layer used as a gate insulating layer may be formed of, for example, hafnium oxide (HfO₂), hafnium silicon oxide (HfSiO₄), hafnium silicon oxynitride (HfSiON), hafnium tantalum oxide (HfₓTa_{y}O_{z}), hafnium titanium oxide (HfTiO₄), hafnium zirconium oxide (HfZrO₄), zirconium oxide (ZrO₂), aluminum oxide (Al₂O₃), lanthanum oxide (La₂O₃), lanthanum hafnium oxide (La₂Hf₂O₇), lanthanum aluminum oxide (LaAlO₃), or a combination thereof, but the present inventive concept is not limited thereto.

The gate insulating pattern GOX may cover the first side SS1 of the first active pattern AP(1) and the second side SS2 of the second active pattern AP(2). The gate insulation pattern GOX may have a substantially uniform thickness. Each of the gate insulating patterns GOX may include a vertical portion VP adjacent to the first and second active patterns AP(1) and AP(2) and a horizontal portion HP protruding from the vertical portion VP in the second direction D2.

As an example, a pair of first and second word lines WL(1) and WL(2) may be disposed on the horizontal portion HP of each of the gate insulating patterns GOX. The gate insulating patterns GOX may be arranged to be spaced apart from each other and may be mirror symmetrical to each other. For example, each of the gate insulating patterns GOX may have the vertical portion VP interposed between the first word line WL(1) and the channel region CHR of the first active pattern AP(1), or interposed between the second word line WL(2) and the channel region CHR of the second active pattern AP(2).

A second insulating pattern 143 may be disposed between the horizontal portion HP of the gate insulating pattern GOX and the storage node contacts BC. As an example, the second insulating pattern 143 may include silicon oxide (SiO₂). First and second etch stop layers 131 and 141 may be disposed between the second dopant regions SDR2 of the first and second active patterns AP(1) and AP(2) and the second insulating pattern 143.

On the gate insulating pattern GOX, the first and second word lines WL(1) and WL(2) may be separated from each other by a third insulating pattern 155. The third insulating pattern 155 may extend in the first direction D1 between the first and second word lines WL(1) and WL(2). A first capping layer 153 may be disposed between the third insulating pattern 155 and the first and second word lines WL(1) and WL(2). The first capping layer 153 may have a substantially uniform thickness.

The first cell insulating layer IL1 may include an etch stop layer 210 and an interlayer insulating layer 231 that are sequentially stacked. The storage node contacts BC may penetrate the interlayer insulating layer 231 and the etch stop layer 210 and be connected to the first and second active patterns AP(1) and AP(2), respectively. For example, the storage node contacts BC may be connected to the second dopant regions SDR2 of the first and second active patterns AP(1) and AP(2), respectively. The storage node contacts BC may each have a lower width greater than an upper width thereof. The storage node contacts BC adjacent to each other may be separated from each other by the fourth cell insulating layer IL4. Each of the storage node contacts BC may have various shapes such as, for example, circular, oval, rectangular, square, diamond, hexagonal, etc. when viewed in a plan view. The storage node contacts BC may be arranged in a matrix in the first direction D1 and the second direction D2. The storage node contacts BC may be formed of, for example, doped polysilicon (p-Si), aluminum (Al), copper (Cu), titanium (Ti), tantalum (Ta), ruthenium (Ru), tungsten (W), molybdenum (Mo), platinum (Pt), nickel (Ni), cobalt (Co), titanium nitride (TiN), tantalum nitride (TaN), tungsten nitride (WN), niobium nitride (NbN), titanium aluminum (TiAl), titanium aluminum nitride (TiAlN), titanium silicide (TiSi₂), titanium silicon nitride (TiSiN), tantalum silicide (TaSi₂), tantalum silicon nitride (TaSiN), ruthenium titanium nitride (RuTiN), nickel silicide (NiSi₂), cobalt silicide (CoSi₂), iridium oxide (IrOₓ), ruthenium oxide (RuOₓ), or a combination thereof, but the present inventive concept is not limited thereto.

Landing pads LP may be placed on the storage node contacts BC. Each of the landing pads LP may have various shapes, such as, for example, a circle, an oval, a rectangle, a square, a diamond, or a hexagon, when viewed in a plan view. The landing pads LP may completely or partially vertically overlap the storage node contacts BC. The landing pads LP may be arranged in a matrix form in the first direction D1 and the second direction D2 when viewed in a plan view. Alternatively, the landing pads LP may be arranged in a honeycomb shape when viewed in a plan view. The landing pads LP may be formed of, for example, doped polysilicon (p-Si), aluminum (Al), copper (Cu), titanium (Ti), tantalum (Ta), ruthenium (Ru), tungsten (W), molybdenum (Mo), platinum (Pt), nickel (Ni), cobalt (Co), titanium nitride (TiN), tantalum nitride (TaN), tungsten nitride (WN), niobium nitride (NbN), titanium aluminum (TiAl), titanium aluminum nitride (TiAlN), titanium silicide (TiSi₂), titanium silicon nitride (TiSiN), tantalum silicide (TaSi₂), tantalum silicon nitride (TaSiN), ruthenium titanium nitride (RuTiN), nickel silicide (NiSi₂), cobalt silicide (CoSi₂), iridium oxide (IrOₓ), ruthenium oxide (RuOₓ), or a combination thereof, but the present inventive concept is not limited thereto.

Referring to FIG. 3, a first cell contact plugs CT1 may penetrate the fourth cell insulating layer IL4, the first cell insulating layer IL1, and the second cell insulating layer IL2 to be in contact with the first cell interconnections IT1. The bit line contact plugs BLC may penetrate the fourth cell insulating layer IL4, the first cell insulating layer IL1, and the second cell insulating layer IL2 to be in contact with an end of the bit line BL. The shield line contact plugs SHC, the word line contact plugs WLC, and back gate line contact plugs BGC of FIG. 2 may also penetrate a fourth cell insulating layer IL4 and a first cell insulating layer IL1, respectively to be in contact with ends of the shield lines SHL, word lines WL, and back gate lines BGL, respectively.

Second cell interconnections IT2 may be disposed on the fourth cell insulating layer IL4. The second cell interconnections IT2 may be positioned at a level the same as that of the landing pads LP. The fifth to seventh cell insulating layers IL5, IL6, and IL7 may be sequentially stacked on the fourth cell insulating layer IL4. The fifth cell insulating layer IL5 may cover the second cell interconnections IT2. The second cell interconnections IT2 may be in contact with the first cell contact plugs CT1, bit line contact plugs BLC, shield line contact plugs SHC, word line contact plugs WLC, and back gate line contact plugs BGC.

Lower electrodes BE may be respectively disposed on the landing pads LP. The lower electrodes BE may be electrically connected to the first and second active patterns AP(1) and AP(2) through the landing pads LP and the storage node contacts BC, respectively. Each of the lower electrodes BE may have a pillar shape or a hollow cup shape.

The lower electrodes BE may be arranged in a matrix shape or in a honeycomb shape in the first direction D1 and the second direction D2. The lower electrodes BE may completely or partially overlap the landing pads LP. The lower electrodes BE may be in contact with all or a portion of upper surfaces of the landing pads LP. A spacing between the lower electrodes BE may be constant. The lower electrodes BE may partially penetrate the fifth cell insulating layer IL5 to be in contact with the landing pads LP, respectively. The lower electrodes BE may include at least one of, for example, polysilicon (p-Si) doped with impurities, a metal, a metal oxide layer, or a metal nitride layer. In an embodiment of the present inventive concept, the lower electrodes BE may include a titanium nitride (TiN) layer.

Upper sidewalls of the lower electrodes BE may be in partial contact with support patterns SSP. The support patterns SSP may prevent the lower electrodes BE from collapsing. For example, the support patterns SSP may maintain a constant distance between two adjacent lower electrodes BE and prevent the lower electrodes BE from tilting or falling. The support patterns SSP may be located at different vertical levels on the sidewalls of the lower electrodes BE. The support patterns SSP may have a plate or mesh shape with a plurality of holes formed when viewed in a plan view. The support patterns SSP may be formed of one layer or two or more layers. The support patterns SSP may be formed of, for example, a single layer or a multilayer of at least one of, for example, silicon nitride (Si₃N₄), silicon boron nitride (SiBN), or silicon carbon nitride (SiCN).

A dielectric layer DL conformally covers the lower electrodes BE and the support patterns SSP. The dielectric layer DL covers an upper surface of the fifth cell insulating layer IL5. The dielectric layer DL may be formed as a single layer or a multilayer of, for example, a silicon oxide (SiO₂) layer or a material having a dielectric constant higher than that of a silicon oxide (SiO₂) layer sch as, for example, an aluminum oxide (Al₂O₃) layer. An upper electrode TE may be disposed on the dielectric layer DL. The upper electrode TE may be formed as a single-layer or a multi-layer structure of at least one of, for example, a titanium nitride (TiN) layer, a tungsten (W) layer, an impurity-doped polysilicon (p-Si) layer, or an impurity-doped silicon germanium (SiGe) layer. A sidewall of the upper electrode TE may be aligned with a sidewall of the dielectric layer DL. The sidewall of the upper electrode TE may be maintained at a certain distance from a sidewall of the outermost one of the lower electrodes BE.

The lower electrodes BE, the dielectric layer DL, and the upper electrode TE may constitute capacitors CAP. The capacitors CAP may store electric charges in the dielectric layer DL by a potential difference generated between the lower electrodes BE and the upper electrode UE. The capacitors CAP may correspond to the data storage element DS of FIG. 1A. The capacitor CAP and the fifth cell insulating layer IL5 are covered with the sixth cell insulating layer IL6. An upper electrode contact plug UCT penetrates the sixth cell insulating layer IL6 and is in contact with an upper surface of the upper electrode UE. The second cell contact plugs CT2 may penetrate the sixth cell insulating layer IL6 and be connected to the second cell interconnections IT2. The second cell contact plugs CT2 may each have a circular shape in a plan view, but the present inventive concept is not limited thereto. A seventh cell insulating layer IL7 is disposed on the sixth cell insulating layer IL6. Third cell contact plugs CT3 and third cell interconnections IT3 may be disposed in the seventh cell insulating layer IL7.

An interface layer AL is disposed between the cell structure CS and the peripheral structure PS. The interface layer AL may have a single-layer or multi-layer structure of at least one of, for example, silicon carbon nitride (SiCN) or silicon oxide (SiO₂).

The peripheral structure PS includes a peripheral substrate 200. The peripheral substrate 200 may be a semiconductor substrate. The peripheral substrate 200 may have a front surface 200_F and a back surface 200_B that are opposite to each other. Peripheral transistors PTR may be disposed on the front surface 200_F of the peripheral substrate 200. The peripheral transistors PTR may be in a form of a planar transistor, fin field-effect transistor (FinFET), multi-bridge channel FET (MBCFET), gate all around (GAA) transistor, or buried channel array transistor (BCAT). The peripheral transistors PTR may transfer signals and/or power to memory cells MC included in the cell array region 10 illustrated in FIG. 1A. The interface layer AL may be disposed between the back surface 200_B of the peripheral substrate 200 and the seventh cell insulating layer IL7. The back surface 200_B of the peripheral substrate 200 may be in contact with the interface layer AL.

The peripheral transistors PTR may be connected to first peripheral contact plugs PC1 and first peripheral interconnections PI1. The peripheral transistors PTR and the front surface 200_F of the peripheral substrate 200 may be covered with a first peripheral insulating layer PL1. The first peripheral insulating layer PL1 may have a single-layer or multi-layer structure of at least one of, for example, silicon oxide (SiO₂), silicon nitride (Si₃N₄), silicon oxynitride (SiON), or porous insulator. The first peripheral contact plugs PC1 and first peripheral interconnections PI1 may be disposed in the first peripheral insulating layer PL1. The peripheral transistors PTR, the first peripheral contact plugs PC1, and the first peripheral interconnections PI1 may constitute circuits of the sub-word line driver 22, the sense amplifier 24, the row decoder 32, the column decoder 34, and the control logic 36 described in FIG. 1A.

An interconnection structure IS is disposed on the peripheral structure PS. The interconnection structure IS may include an interconnection insulating layer LL1 and multi-layered upper interconnections LT1, upper contact plugs LC1, and upper connection pads UPD. Each of the upper interconnections LT1, upper contact plugs LC1, and upper connection pads UPD may include at least one of, for example, copper (Cu), tungsten (W), or aluminum (Al). A thickness of each of the upper interconnections LT1 and the upper connection pads UPD may be equal to or greater than a thickness of each of the first peripheral interconnections PI1.

The semiconductor memory device of FIG. 3 further includes through vias TV1. The through vias TV1 may partially penetrate the peripheral insulating layer PL1 and the peripheral substrate 200 of the peripheral structure PS, the interface layer AL and the seventh cell insulating layer IL7 to connect some of the third cell interconnections IT3 to the interconnection structure IS. For example, the through via TV1 may penetrate the interface layer AL and a part of the seventh cell insulating layer IL7 to be connected to one of the third cell interconnections IT3. The through vias TV1 may have a smaller width as it goes downward. The through vias TV1 may include a metal such as, for example, copper (Cu) or tungsten (W). A via insulating layer 202 may be interposed between the through vias TV1 and the peripheral substrate 200. The via insulating layer 202 may be formed to surround the side surface of the through via TV1, such that the via insulating layer 202 electrically isolates the through via TV1 from the surrounding peripheral substrate 200. The via insulating layer 202 may be formed of, for example, silicon oxide (SiO₂).

The third cell interconnections IT3 may be connected to the bit line BL through the bit line contact plug BLC, the second cell interconnection IT2 and the second cell contact plug CT2, and thus, the through via TV1 may penetrate the peripheral substrate 200 to be connected to the interconnection structure IS and applying an electrical signal to one of the bit lines BL.

In the semiconductor memory device of FIG. 3, the back surface 200_B of the peripheral substrate 200 faces an upper surface UE_S1 of the upper electrode UE. In the present inventive concept, the upper surface UE_S1 of the upper electrode UE may be defined as a surface furthest from the landing pad LP among surfaces of the upper electrode UE. In the structure of the semiconductor memory device of FIG. 3, degree of freedom in interconnection routing between the cell structure CS and the peripheral structure PS may be increased, and the connection between the cell structure CS and the peripheral structure PS may be facilitated, and high integration may be realized. The connection manner between the cell structure CS, the peripheral structure PS, and the interconnection structure IS is not limited to FIG. 3 and may be variously changed.

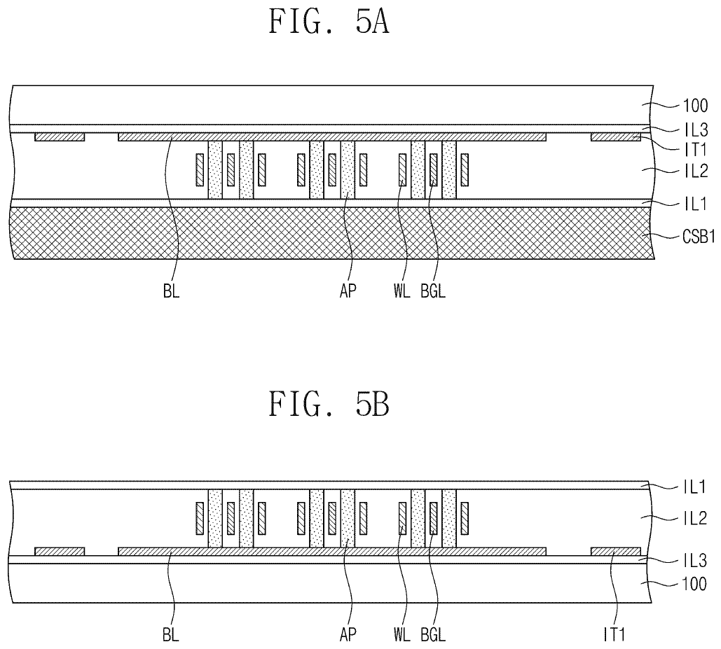

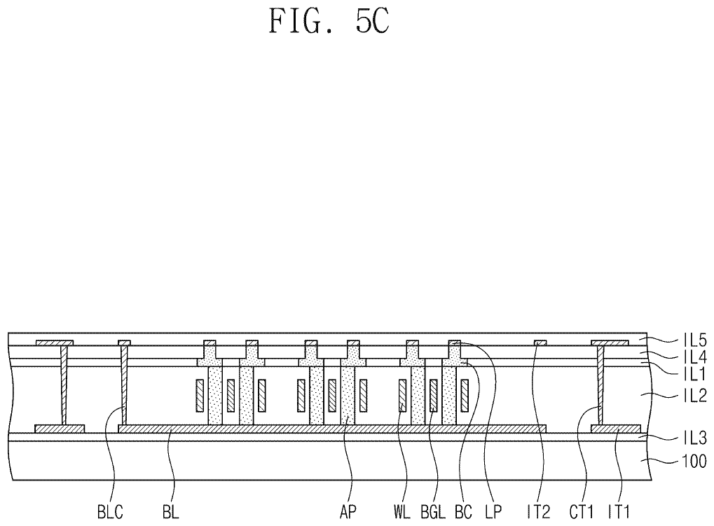

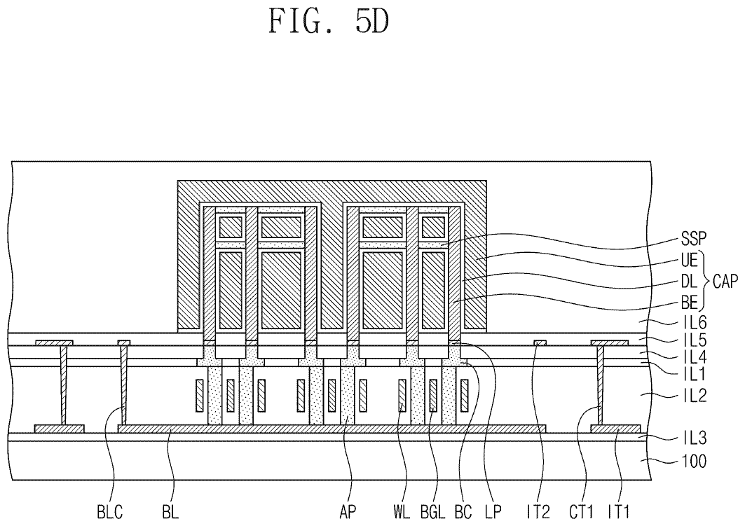

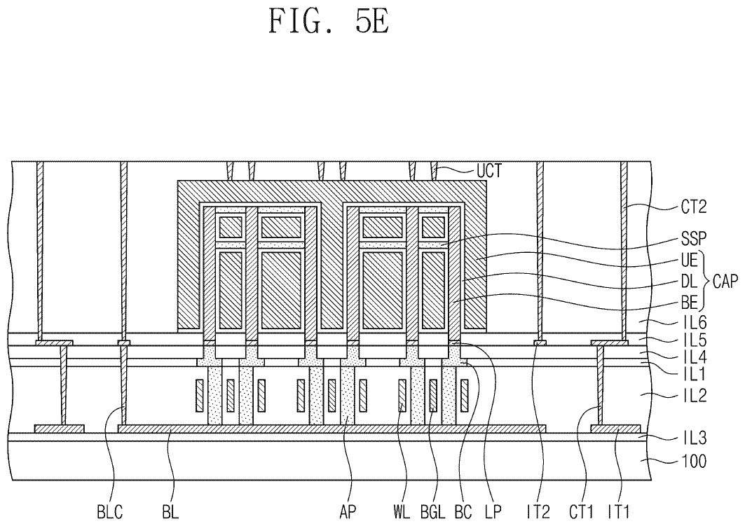

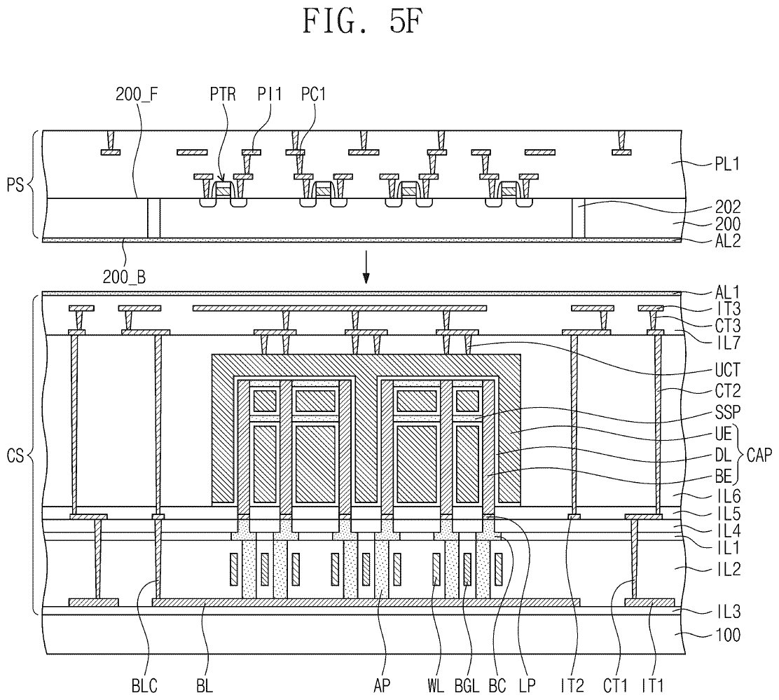

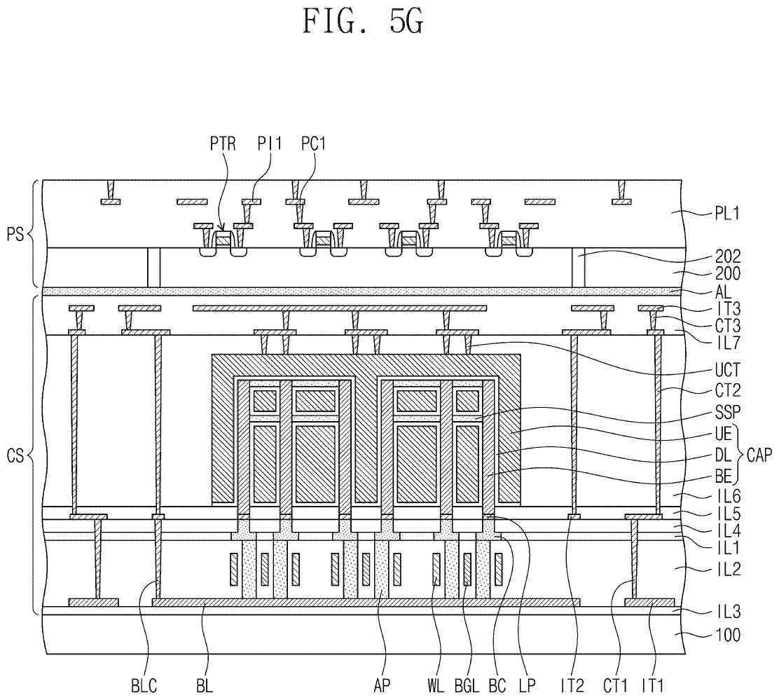

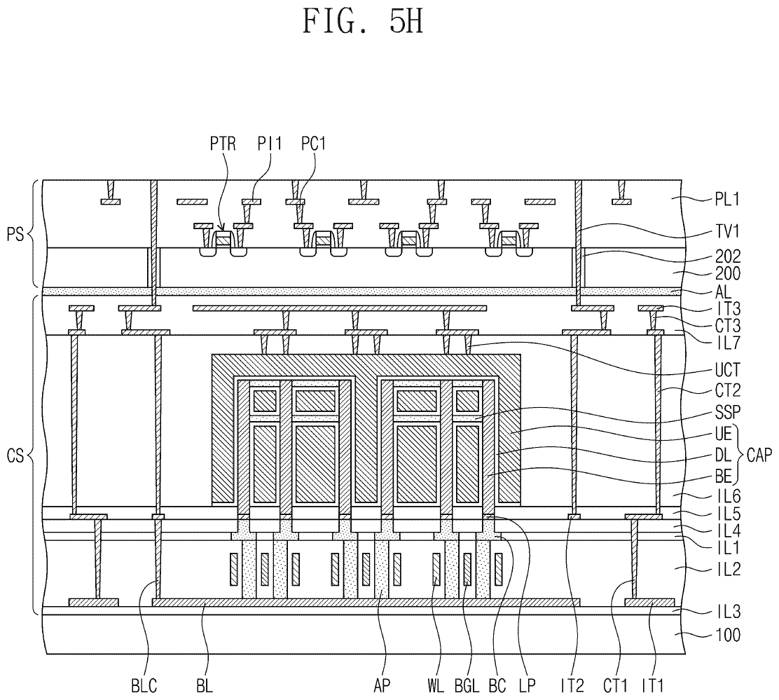

FIGS. 5A to 5H are cross-sectional views sequentially showing a process of manufacturing the semiconductor memory device of FIG. 3 according to an embodiment of the present inventive concept.

Referring to FIGS. 2 to 4 and FIG. 5A, a first cell insulating layer IL1 is formed on a first sacrificial substrate CSB1. A second cell insulating layer IL2 is formed on the first cell insulating layer IL1. Active patterns AP, word lines WL, and back gate lines BGL are formed in the second cell insulating layer IL2. Bit lines BL, shield lines SHL, and first cell interconnections IT1 are formed on the second cell insulating layer IL2. For example, referring to FIG. 5A, the bit lines BL, the shield lines SHL, and the first cell interconnections IT1 may be formed within and at an upper end of the second cell insulating layer IL2. A third cell insulating layer IL3 is formed on the second cell insulating layer IL2, the bit lines BL, the shield line SHL, and the first cell interconnections IT1. A support substrate 100 is bonded on the third cell insulating layer IL3.

Referring to FIG. 5B, after the structure of FIG. 5A is reversed, the first sacrificial substrate CSB1 is separated from the first cell insulating layer IL1. As a result, an upper surface of the first cell insulating layer IL1 may be exposed.

Referring to FIG. 5C, a lower portion of a storage node contact BC may be formed within the first cell insulating layer IL1. A fourth cell insulating layer IL4 is formed on the first cell insulating layer IL1. An upper portion of the storage node contact BC is formed within the fourth cell insulating layer IL4. The lower portion of the storage node contact BC may have a width within the first cell insulating layer IL1 wider than a width of the upper portion of the storage node contact BC within the fourth cell insulating layer IL4. Bit line contact plugs BLC and first cell contact plugs CT1 are formed in the fourth cell insulating layer IL4, the first cell insulating layer IL1, and the second cell insulating layer IL2. Landing pads LP and second cell interconnections IT2 are formed on the fourth cell insulating layer IL4. A fifth cell insulating layer IL5 is formed to cover the fourth cell insulating layer IL4, the landing pads LP, and the second cell interconnections IT2.

Referring to FIG. 5D, a capacitor CAP including lower electrodes BE, a dielectric layer DL, and an upper electrode UE is formed on the fifth cell insulating layer IL5, with at least one support pattern SSP formed on the sidewalls of the lower electrodes BE to prevent the lower electrodes BE from collapsing. If multilayers of the support patterns SSP are formed, the support patterns SSP may be located at different vertical levels on the sidewalls of the lower electrodes BE. A sixth cell insulating layer IL6 is formed to cover the capacitor CAP.

Referring to FIG. 5E, upper electrode contact plugs UCT and second cell contact plugs CT2 are formed to penetrate the sixth cell insulating layer IL6.

Referring to FIG. 5F, third cell interconnections IT3, third cell contact plugs CT3, and seventh cell insulating layer IL7 are formed on the sixth cell insulating layer IL6. A first interface layer AL1 is formed on the seventh cell insulating layer IL7. The first interface layer AL1 is formed of, for example, silicon carbon nitride (SiCN). As a result, a cell structure CS may be completed on the support substrate 100.

Thereafter, a peripheral structure PS is prepared. To manufacture the peripheral structure PS, via insulating layers 202 are first formed in a peripheral substrate 200. Peripheral transistors PTR, first peripheral contact plugs PC1, first peripheral interconnections PI1, and first peripheral insulating layer PL1 are formed on a front surface 200_F of the peripheral substrate 200. A back surface 200_B of the peripheral substrate 200 is back-grinded to expose the via insulating layers 202. A second interface layer AL2 is formed on the back surface 200_B of the peripheral substrate 200.

Plasma treatment is performed on surfaces of the first interface layer AL1 and the second interface layer AL2 to remove carbonitride (CN) groups at an outermost end of the silicon carbon nitride (SiCN) layer and to form dangling bonds. Then, the surfaces of the first interface layer AL1 and the second interface layer AL2 are treated with deionized water to form OH groups in the dangling bonds. The peripheral structure PS is placed on the cell structure CS and a heat compression process is performed. For example, the surface of the first interface layer AL1 of the cell structure CS may be pressed against the surface of the second interface layer AL2 of the peripheral structure PS during the heat compression process.

Referring to FIGS. 5G and 5H, through the thermal compression process, as OH groups are combined in a form of H₂O at the interfaces between the first interface layer AL1 and the second interface layer AL2, the remaining O is combined with the neighboring Si to form a SiO₂ layer between the first interface layer AL1 and the second interface layer AL2. As a result, the peripheral structure PS is bonded to the cell structure CS, and an interface layer AL is formed therebetween. The interface layer AL may include a triple-layer structure of a silicon carbon nitride (SiCN) layer, a SiO₂ layer, and a silicon carbon nitride (SiCN) layer sequentially stacked.

Referring to FIG. 5H, a portion of the peripheral structure PS, the interface layer AL, and the seventh cell insulating layer IL7 are etched to form a through-via hole exposing a portion of the third cell interconnections IT3, and the through via hole is filled with a conductive layer to form through vias TV1. The through vias TV1 are formed to penetrate the pre-formed via insulating layer 202. As a result, the through vias TV1 may be insulated from the peripheral substrate 200. For example, after the through via hole is filled with a conductive layer to form the through via TV1, the side surface of the through via TV1 may be surrounded by the via insulating layer 202, such that the through via TV1 may be electrically isolated from the surrounding peripheral substrate 200 by the via insulating layer 202. As the via insulating layer 202 is formed in advance on the peripheral substrate 200, process defects may be reduced and process burden may be reduced, compared to a process of forming a via insulating layer that covers all inner walls of a through via hole with a high aspect ratio.

Referring again to FIG. 3, an interconnection structure IS is formed on the peripheral structure PS. The interconnection structure IS may include an interconnection insulating layer LL1 and multi-layered upper interconnections LT1, upper contact plugs LC1, and upper connection pads UPD. The interconnection structure IS is formed after bonding the peripheral structure PS to the cell structure CS, the chip size may be reduced and the degree of freedom in interconnection routing between the cell structure CS and the peripheral structure PS may be increased. Therefore, the semiconductor memory device of FIG. 3 may be manufactured. In the method of manufacturing a semiconductor memory device according to the present embodiment, the capacitor CAP is first formed and then the peripheral structure PS is bonded to the cell structure CS, which is superior in terms of heat budget, and leakage current may be minimized or prevented by preventing deterioration of the dielectric layer DL of the capacitor CAP.

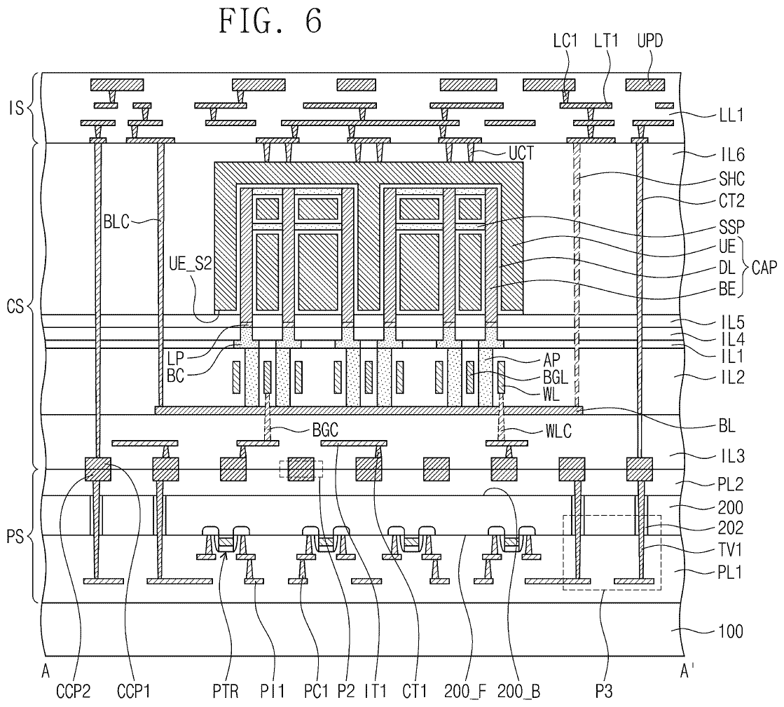

FIG. 6 is a cross-sectional view taken along line A-A′ of FIG. 2 according to an embodiment of the present inventive concept.

Referring to FIG. 6, in the semiconductor memory device according to the present embodiment, the peripheral structure PS, the cell structure CS, and the interconnection structure IS are sequentially stacked on the support substrate 100. The peripheral structure PS may have a structure the same as/similar to that of the peripheral structure PS of FIG. 3. The front surface 200_F of the peripheral substrate 200 faces the support substrate 100. A second peripheral insulating layer PL2 is disposed on the back surface 200_B of the peripheral substrate 200. Peripheral connection pads CCP2 are disposed within and at an upper end of the second peripheral insulating layer PL2. The through vias TV1 may partially penetrate the second peripheral insulating layer PL2, the via insulating layer 202, and the first peripheral insulating layer PL1 to be in contact with a portion of the first peripheral interconnections PI1. The peripheral connection pads CCP2 may include copper (Cu), for example.

The cell structure CS may include a multi-layer structure, with the first to sixth cell insulating layers IL1 to IL6 and bit lines BL, shield lines SHL, word lines WL, and back gate lines BGL and capacitor CAP disposed therein. In detail, a lower surface of the third cell insulating layer IL3 is in contact with an upper surface of the second peripheral insulating layer PL2. The first cell interconnections IT1 and first cell contact plugs CT1 are disposed in the third cell insulating layer IL3. The cell connection pads CCP1 are disposed at a lower end of the third cell insulating layer IL3. The cell connection pads CCP1 may include copper (Cu), for example. The cell connection pads CCP1 may be in contact with the peripheral connection pads CCP2, respectively. In this case, the cell connection pads CCP1 and the peripheral connection pads CCP2 may be bonded to each other through a metal to metal bonding (e.g., copper (Cu) to copper (Cu) bonding), while the third cell insulating layer IL3 and the second peripheral insulating layer PL2 may be boded to each other through a dielectric to dielectric bonding (e.g., silicon oxide (SiO₂) to silicon oxide (SiO₂) bonding). The bit lines BL and shield lines SHL are disposed on the third cell insulating layer IL3.

The bit lines BL and shield lines SHL may be covered with the second cell insulating layer IL2. The active patterns AP may penetrate the second cell insulating layer IL2 to be in contact with the bit lines BL. A word line WL is disposed on one side of one of the active patterns AP and the back gate line BGL is disposed on the other side of the one active pattern AP. The back gate line BGL is interposed between adjacent active patterns AP.

The word line contact plugs WLC may partially penetrate the third cell insulating layer IL3 and the second cell insulating layer IL2 to be in contact with lower surfaces of ends of the word lines WL. The back gate line contact plugs BGC may partially penetrate the third cell insulating layer IL3 and the second cell insulating layer IL2 to be in contact with lower surfaces of ends of the back gate lines BGL.

The first cell insulating layer IL1 is disposed on the second cell insulating layer IL2. The fourth cell insulating layer IL4 is disposed on the first cell insulating layer IL1. The storage node contacts BC may penetrate the fourth cell insulating layer IL4 and the first cell insulating layer IL1 to be in contact with upper ends of the active patterns AP. The landing pads LP may be disposed on the storage node contacts BC. The fifth cell insulating layer IL5 and the sixth cell insulating layer IL6 are sequentially stacked on the fourth cell insulating layer IL4. The capacitor CAP is disposed in the sixth cell insulating layer IL6. The capacitor CAP may be electrically connected to the active patterns AP through the landing pads LP and the storage node contacts BC. An upper surface of the sixth cell insulating layer IL6 is in contact with the lower surface of the interconnection insulating layer LL1 of the interconnection structure IS.

The second cell contact plugs CT2 may penetrate the sixth cell insulating layer IL6, the fifth cell insulating layer IL5, the fourth cell insulating layer IL4, the first cell insulating layer IL1, the second cell insulating layer IL2, and the third cell insulating layer IL3 to connect at least one of the cell connection pads CCP1 to the interconnection structure IS. The bit line contact plug BLC may penetrate the sixth cell insulating layer IL6, the fifth cell insulating layer IL5, the fourth cell insulating layer IL4, the first cell insulating layer IL1, and the second cell insulating layer IL2 to connect ends of the bit lines BL to the interconnection structure IS. The shield line contact plug SHC may penetrate the sixth cell insulating layer IL6, the fifth cell insulating layer IL5, the fourth cell insulating layer IL4, the first cell insulating layer IL1, and the second cell insulating layer IL2 to connect ends of the shield lines SHL, which are interposed between the bit lines BL, to the interconnection structure IS.

In the semiconductor memory device of FIG. 6, the back surface 200_B of the peripheral substrate 200 faces a lower surface UE_S2 of the upper electrode UE. In the present inventive concept, the lower surface UE_S2 of the upper electrode UE may be defined as a surface closest to the landing pad LP among surfaces of the upper electrode UE. The structure of the semiconductor memory device of FIG. 6 facilitates interconnection routing between the cell structure CS and the peripheral structure PS and high integration may be realized. Other structures may be the same as/similar to those described with reference to FIGS. 2 to 4. The connection manner between the cell structure CS, the peripheral structure PS, and the interconnection structure IS is not limited to FIG. 6 and may be variously changed.

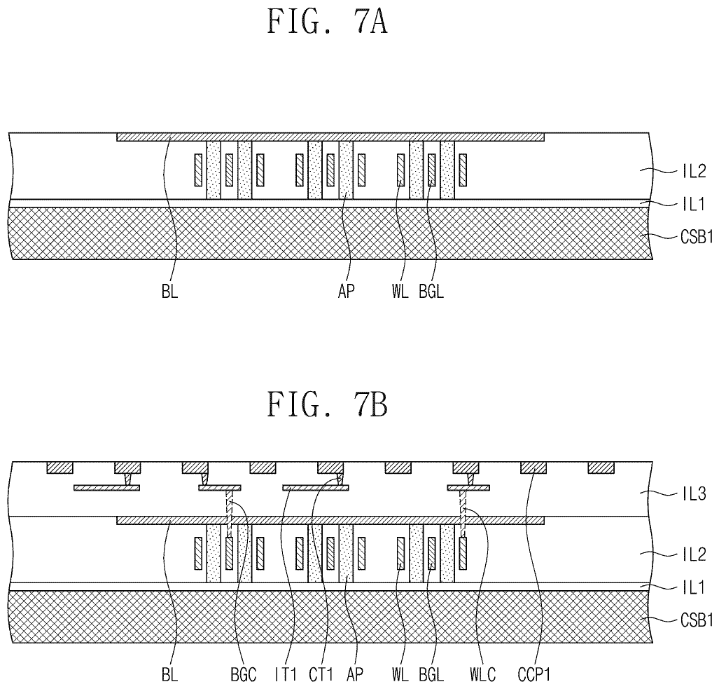

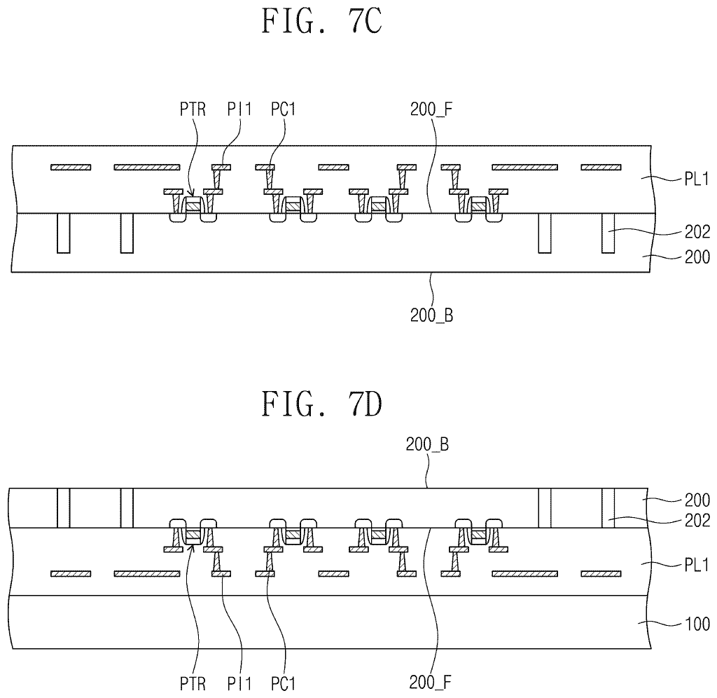

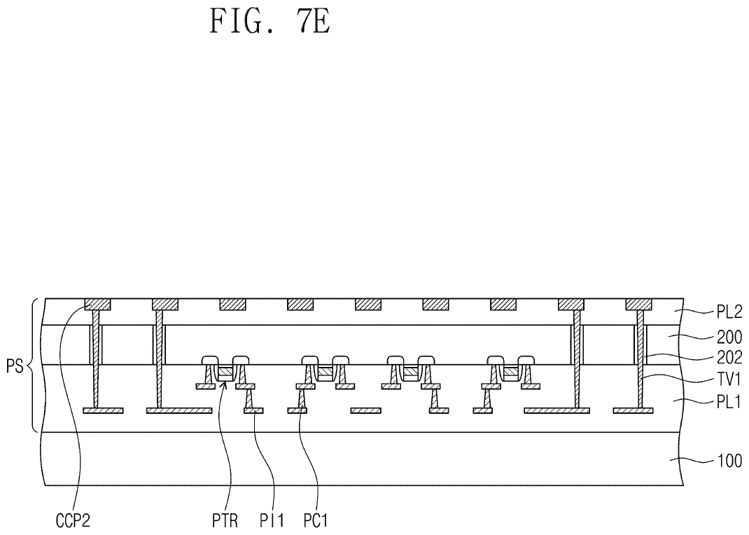

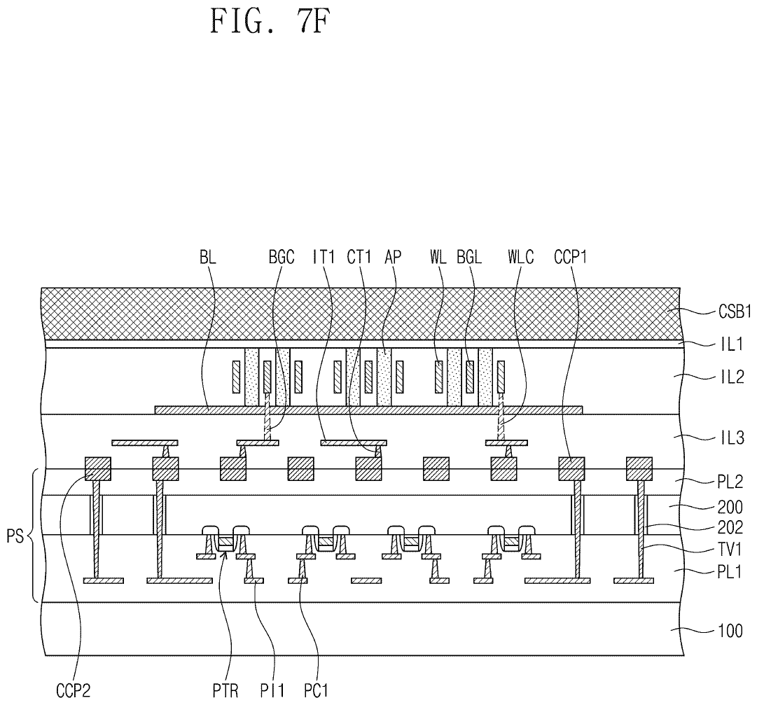

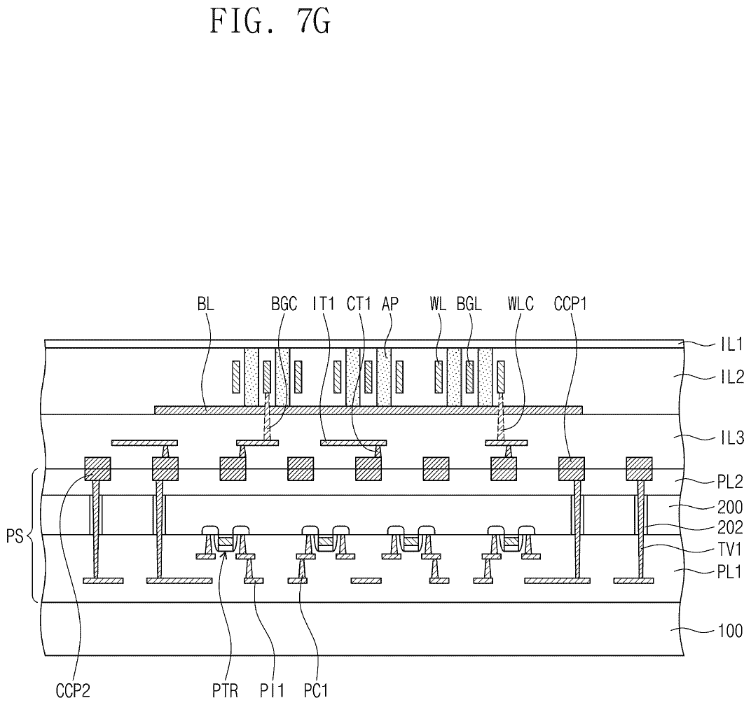

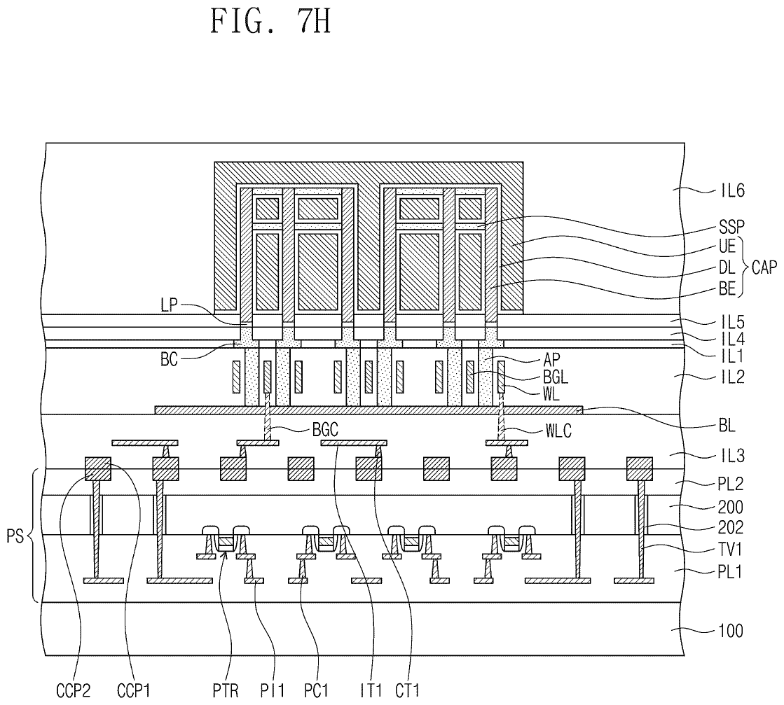

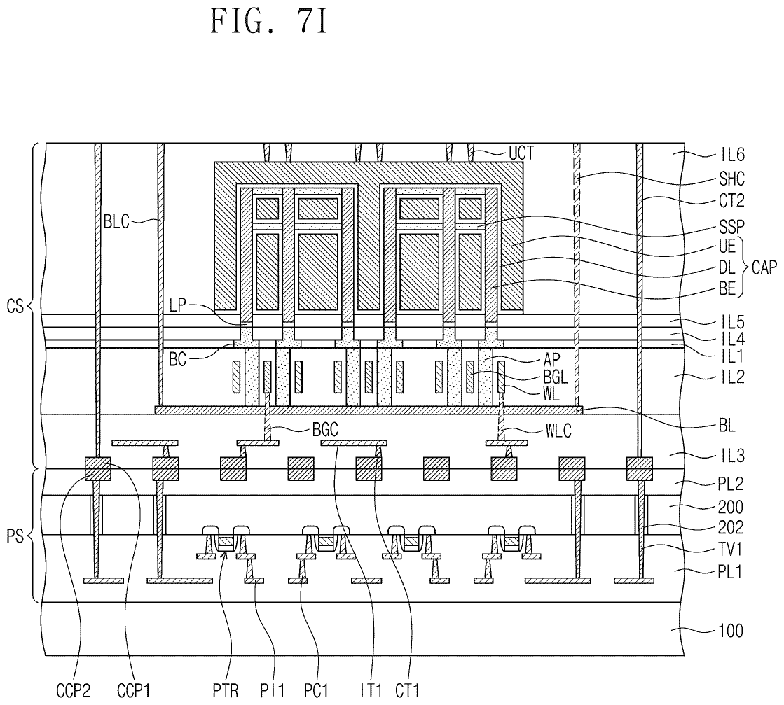

FIGS. 7A to 7I are cross-sectional views sequentially showing a process of manufacturing the semiconductor memory device of FIG. 6 according an embodiment of the present inventive concept.

Referring to FIGS. 2, 4, and 7A, a first cell insulating layer IL1 is formed on a first sacrificial substrate CSB1. A second cell insulating layer IL2 is formed on the first cell insulating layer IL1. Active patterns AP, word lines WL, and back gate lines BGL are formed in the second cell insulating layer IL2. Bit lines BL and shield lines SHL are formed on the second cell insulating layer IL2. For example, referring to FIG. 7A, the bit lines BL and the shield lines SHL may be formed within and at an upper end of the second cell insulating layer IL2.

Referring to FIG. 7B, word line contact plugs WLC, back gate line contact plugs BGC, first cell interconnections IT1, first cell contact plugs CT1, a third cell insulating layer IL3, and cell connection pads CCP1 are formed on the second cell insulating layer IL2. The word line contact plugs WLC may partially penetrate the third cell insulating layer IL3 and the second cell insulating layer IL2 to be in contact with lower surfaces of ends of the word lines WL. The back gate line contact plugs BGC may partially penetrate the third cell insulating layer IL3 and the second cell insulating layer IL2 to be in contact with lower surfaces of ends of the back gate lines BGL.

Referring to FIG. 7C, a peripheral substrate 200 is provided. Via insulating layers 202 are formed on the peripheral substrate 200. In this case, lower surfaces of the via insulating layers 202 may be disposed within the peripheral substrate 200. Peripheral transistors PTR, first peripheral interconnections PI1, first peripheral contact plugs PC1, and first peripheral insulating layer PL1 are formed on a front surface 200_F of the peripheral substrate 200.

Referring to FIG. 7D, a support substrate 100 is bonded on an upper surface of the first peripheral insulating layer PL1. A back grinding process is performed on the back surface 200_B of the peripheral substrate 200 to remove a portion of the peripheral substrate 200 to expose the via insulating layers 202. Then, the peripheral substrate 200 is turned over.

Referring to FIG. 7E, a second peripheral insulating layer PL2 is formed on the back surface 200_B of the peripheral substrate 200. The second peripheral insulating layer PL2, the via insulating layer 202, and the first peripheral insulating layer PL1 are partially removed to form a through-via hole exposing one of the first peripheral interconnections PI1, and the through-via hole is filled with conductive material to form a through via TV1. Peripheral connection pads CCP2 are formed within and at an upper end of the second peripheral insulating layer PL2. The peripheral connection pads CCP2 are connected to a portion of the first peripheral interconnections PI1 through the through vias TV1. As a result, the peripheral structure PS may be formed on the support substrate 100.

Referring to FIG. 7F, the structure of FIG. 7B is turned over and placed on the peripheral structure PS of FIG. 7E, and then a heat compression process is performed to bond the structure of FIG. 7B to the peripheral structure PS of FIG. 7E. As a result, the second peripheral insulating layer PL2 may be in contact with the third cell insulating layer IL3. Additionally, the peripheral connection pads CCP2 may be in contact with the cell connection pads CPP1, respectively. In this case, the cell connection pads CCP1 and the peripheral connection pads CCP2 may be bonded to each other through a metal to metal bonding (e.g., copper (Cu) to copper (Cu) bonding), while the third cell insulating layer IL3 and the second peripheral insulating layer PL2 may be boded to each other through a dielectric to dielectric bonding (e.g., silicon oxide (SiO₂) to silicon oxide (SiO₂) bonding).

Referring to FIG. 7G, the first sacrificial substrate CSB1 of FIG. 7F is separated from a surface of the first cell insulating layer IL1. As a result, an upper surface of the first cell insulating layer IL1 may be exposed.

Referring to FIG. 7H, a lower portion of the storage node contact BC may be formed within the first cell insulating layer IL1. A fourth cell insulating layer IL4 is formed on the first cell insulating layer IL1. An upper portion of the storage node contact BC is formed within the fourth cell insulating layer IL4. Landing pads LP are formed on the fourth cell insulating layer IL4. A fifth cell insulating layer IL5 is formed to cover the fourth cell insulating layer IL4. A capacitor CAP including lower electrodes BE, a dielectric layer DL, and an upper electrode UE is formed on the fifth cell insulating layer IL5, with at least one support pattern SSP formed on the sidewalls of the lower electrodes BE to prevent the lower electrodes BE from collapsing. If multilayers of the support patterns SSP are formed, the support patterns SSP may be located at different vertical levels on the sidewalls of the lower electrodes BE. A sixth cell insulating layer IL6 is formed to cover the capacitor CAP.

Referring to FIG. 7I, upper electrode contact plugs UCT penetrating the sixth cell insulating layer IL6 are formed. Then, second cell contact plugs CT2, bit line contact plug BLC, and shield line contact plug SHC are formed. The second cell contact plugs CT2 may penetrate the sixth cell insulating layer IL6, the fifth cell insulating layer IL5, the fourth cell insulating layer IL4, the first cell insulating layer IL1, the second cell insulating layer IL2, and the third cell insulating layer IL3 to be in contact with the cell connection pads CCP1. The bit line contact plug BLC may penetrate the sixth cell insulating layer IL6, the fifth cell insulating layer IL5, the fourth cell insulating layer IL4, the first cell insulating layer IL1, and the second cell insulating layer IL2 to be in contact with ends of the bit lines BL. The shield line contact plug SHC may penetrate the sixth cell insulating layer IL6, the fifth cell insulating layer IL5, the fourth cell insulating layer IL4, the first cell insulating layer IL1, and the second cell insulating layer IL2 to be in contact with ends of the shield lines SHL. As a result, a cell structure CS may be manufactured.

Subsequently, referring to FIG. 6, an interconnection structure IS is formed on the cell structure CS. The interconnection structure IS may include an interconnection insulating layer LL1 and multi-layered upper interconnections LT1, upper contact plugs LC1, and upper connection pads UPD. Therefore, the semiconductor memory device of FIG. 6 may be manufactured. In the method of manufacturing a semiconductor memory device according to the present embodiment, density of interconnections may be reduced and difficulty of interconnection patterning may be reduced.

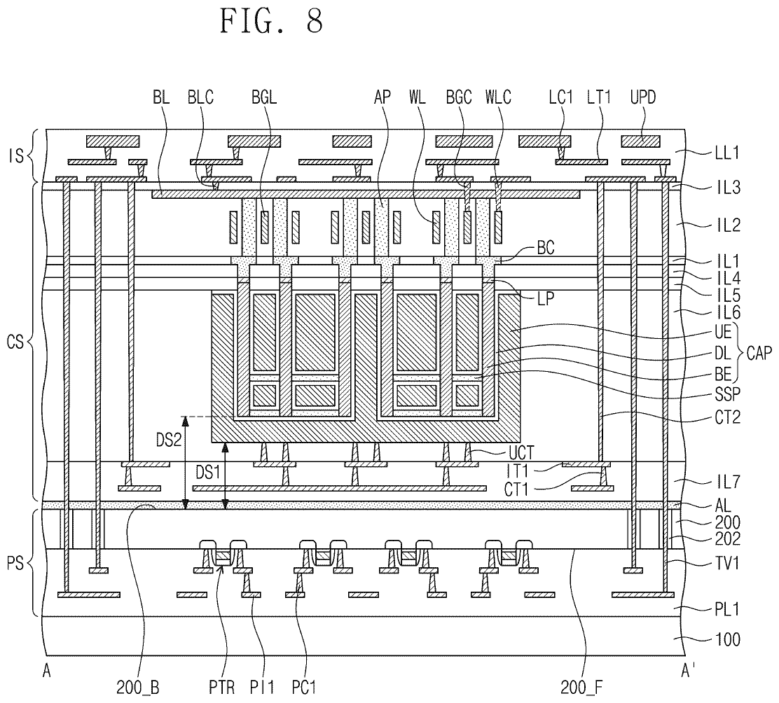

FIG. 8 is a cross-sectional view taken along line A-A′ of FIG. 2 according to an embodiment of the present inventive concept.

Referring to FIG. 8, a semiconductor memory device according to the present embodiment includes a peripheral structure PS, an interface layer AL, a cell structure CS, and an interconnection structure IS sequentially stacked on a support substrate 100. A structure of the peripheral structure PS in FIG. 8 may be the same as/similar to the structure in which the peripheral structure PS in FIG. 3 is flipped. A back surface 200_B of the peripheral substrate 200 is in contact with the interface layer AL.

The cell structure CS of FIG. 8 may be identical/similar to the structure of the cell structure CS of FIG. 3 turned upside down. A lower surface of the seventh cell insulating layer IL7 may be in contact with the interface layer AL. First cell interconnections IT1 and first cell contact plugs CT1 may be disposed in a seventh cell insulating layer IL7. A sixth cell insulating layer IL6 is disposed on the seventh cell insulating layer IL7. A capacitor CAP is disposed in the sixth cell insulating layer IL6. The capacitor CAP of FIG. 8 has a structure in which the capacitor CAP of FIG. 3 turned upside down. Accordingly, a first distance DS1 from the back surface 200_B of the peripheral substrate 200 to an upper electrode UE is smaller than a second distance DS2 from the back surface 200_B of the peripheral substrate 200 to the lower electrode BE. For example, the first distance DS1 from an uppermost surface of the peripheral substrate 200 to a lowermost surface of the upper electrode UE is smaller than the second distance DS2 from the uppermost surface of the peripheral substrate 200 to a lowermost surface of the lower electrode BE. A fifth cell insulating layer IL5, a fourth cell insulating layer IL4, and first to third cell insulating layers IL1, IL2, and IL3 are sequentially stacked on the sixth cell insulating layer IL6. Landing pads LP are disposed in the fifth cell insulating layer IL5. Storage node contacts BC penetrate the fourth cell insulating layer IL4 and the first cell insulating layer IL1. Active patterns AP, word lines WL, back gate lines BGL, bit lines BL, and shield lines SHL are disposed in the second cell insulating layer IL2. The capacitor CAP may be electrically connected to the active patterns AP through the landing pads LP and the storage node contacts BC. An upper surface of the third cell insulating layer IL3 is in contact with an interconnection structure IS.

Bit line contact plugs BLC may penetrate the third cell insulating layer IL3 and be connected to upper surfaces of the bit lines BL. The word line contact plugs WLC may partially penetrate the third cell insulating layer IL3 and the second cell insulating layer IL2 and be connected to the word lines WL. The back gate line contact plugs BGC may partially penetrate the third cell insulating layer IL3 and the second cell insulating layer IL2 and be connected to the back gate lines BGL.

Through vias TV1 partially penetrate the cell insulating layers IL1 to IL7 of the cell structure CS, the interface layer AL, the via insulating layer 202 and the first peripheral insulating layer PL1 of the peripheral structure PS to connect a portion of the first peripheral interconnections PI1 to the interconnection structure IS. The through via TV1 may be electrically isolated from the surrounding peripheral substrate 200 by the via insulating layer 202. Vertical lengths of the through vias TV1 may be different. The second cell contact plugs CT2 may penetrate the third, second, first, fourth to sixth cell insulating layers IL3, IL2, IL1, IL4 to IL6 to connect a portion of the first cell interconnections IT1 to the interconnection structure IS. Other structures may be the same as/similar to those described above with reference to FIGS. 2 to 4. The structure of the semiconductor memory device of FIG. 8 facilitates interconnection routing between the cell structure CS and the peripheral structure PS and high integration may be realized. The connection manner between the cell structure CS, the peripheral structure PS, and the interconnection structure IS is not limited to FIG. 8 and may be variously changed.

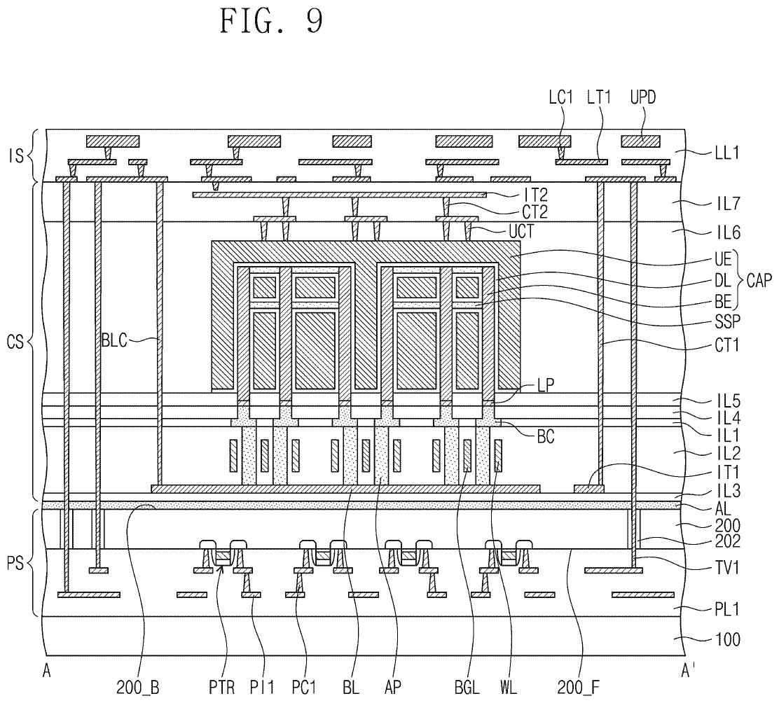

FIG. 9 is a cross-sectional view taken along line A-A′ of FIG. 2 according to an embodiment of the present inventive concept.

Referring to FIG. 9, the semiconductor memory device according to the present embodiment includes a peripheral structure PS, an interface layer AL, a cell structure CS, and an interconnection structure IS sequentially stacked on a support substrate 100. The structure of the peripheral structure PS in FIG. 9 may be the same as/similar to the structure in which the peripheral structure PS in FIG. 3 is flipped. The back surface 200_B of the peripheral substrate 200 is in contact with the interface layer AL.

The cell structure CS of FIG. 9 may be identical/similar to the structure of the cell structure CS of FIG. 8 turned upside down. A lower surface of the third cell insulating layer IL3 may be in contact with the interface layer AL. Bit lines BL, shield lines SHL, and first cell interconnections IT1 are disposed on the third cell insulating layer IL3. A second cell insulating layer IL2 is disposed on the third cell insulating layer IL3. Active patterns AP, word lines WL, and back gate lines BGL are disposed in the second cell insulating layer IL2. First, fourth to seventh cell insulating layers IL1, IL4 to IL7 are sequentially stacked on the second cell insulating layer IL2. Storage node contacts BC penetrate the fourth cell insulating layer IL4 and the first cell insulating layer IL1. Landing pads LP are disposed on the fourth cell insulating layer IL4.

A capacitor CAP is disposed in the sixth cell insulating layer IL6. The capacitor CAP of FIG. 9 has a structure the same as that of the capacitor CAP of FIG. 3. The capacitor CAP may be electrically connected to the active patterns AP through the landing pads LP and the storage node contacts BC. Second cell contact plugs CT2 and second cell interconnections IT2 are disposed in the seventh cell insulating layer IL7. Bit line contact plugs BLC may penetrate the seventh, sixth, fifth, fourth, first and second cell insulating layers IL7, IL6, IL5, IL4, IL1, and IL2 to be in contact with upper surfaces of ends of the bit lines BL.

First cell contact plugs CT1 may penetrate the seventh, sixth, fifth, fourth, first, and second cell insulating layers IL7, IL6, IL5, IL4, IL1, and IL2 to be in contact with upper surfaces of the first cell interconnections IT1. Through vias TV1 may partially penetrate the first to seventh cell insulating layers IL1 to IL7 of the cell structure CS, the interface layer AL, the via insulating layer 202 and the first peripheral insulating layer PL1 of the peripheral structure PS to connect a portion of the first peripheral interconnections PI1 to the interconnection structure IS. The through via TV1 may be electrically isolated from the surrounding peripheral substrate 200 by the via insulating layer 202. Vertical lengths of the through vias TV1 may be different. Other structures may be the same as/similar to those described above with reference to FIGS. 2 to 4. The structure of the semiconductor memory device of FIG. 9 facilitates interconnection routing between the cell structure CS and the peripheral structure PS and high integration may be realized. The connection manner between the cell structure CS, the peripheral structure PS, and the interconnection structure IS is not limited to FIG. 9 and may be variously changed.

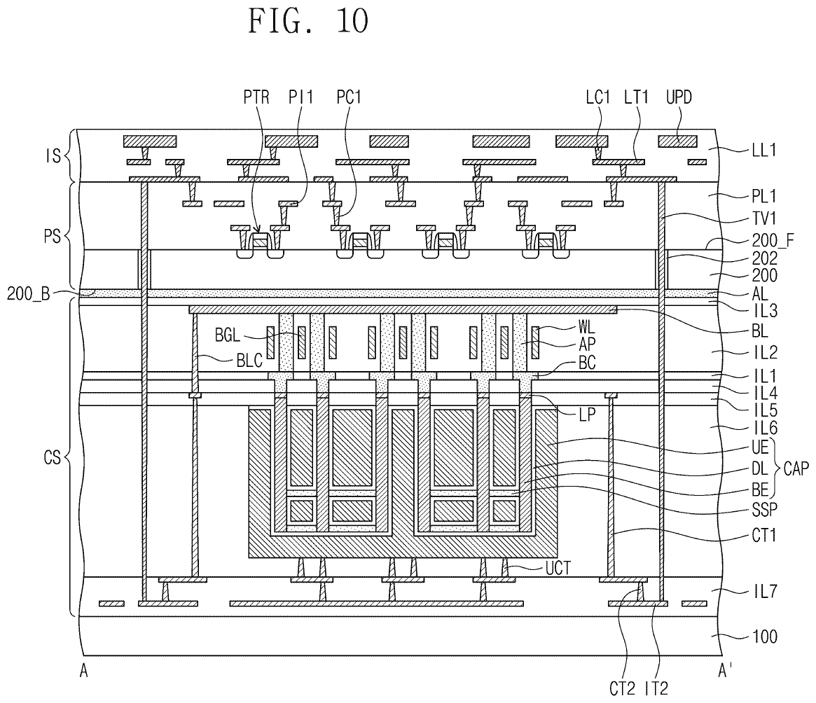

FIG. 10 is a cross-sectional view taken along line A-A′ of FIG. 2 according to an embodiment of the present inventive concept.

Referring to FIG. 10, the semiconductor memory device according to the present embodiment includes a cell structure CS, an interface layer AL, a peripheral structure PS, and an interconnection structure IS sequentially stacked on a support substrate 100. The structure of the peripheral structure PS of FIG. 10 may be the same as/similar to the peripheral structure PS of FIG. 3. A back surface 200_B of the peripheral substrate 200 is in contact with the interface layer AL.

The cell structure CS of FIG. 10 may be identical/similar to the structure of the cell structure CS of FIG. 3 turned upside down. A lower surface of a seventh cell insulating layer IL7 is in contact with an upper surface of the support substrate 100. Sixth, fifth, fourth, first to third cell insulating layers IL6, IL5, IL4, and IL1 to IL3 are sequentially stacked on the seventh cell insulating layer IL7. The third cell insulating layer IL3 is in contact with the interface layer AL. Second cell interconnections IT2 and second cell contact plugs CT2 are disposed in the seventh cell insulating layer IL7.

A capacitor CAP is disposed in the sixth cell insulating layer IL6. The capacitor CAP of FIG. 10 has a structure the same as that of the capacitor CAP of FIG. 8. Landing pads LP and first cell interconnections IT1 are disposed within and at an upper end of the fifth cell insulating layer IL5. Storage node contacts BC penetrate the fourth cell insulating layer IL4 and the first cell insulating layer IL1. Active patterns AP, word lines WL, and back gate lines BGL are disposed in the second cell insulating layer IL2. The capacitor CAP may be electrically connected to the active patterns AP through the landing pads LP and the storage node contacts BC. Bit lines BL and shield lines SHL are disposed within and at an upper end of the second cell insulating layer IL2.

The first cell contact plugs CT1 may penetrate the sixth and fifth cell insulating layers IL6 and IL5 to be in contact with a lower surface of the first cell interconnections IT1. Bit line contact plugs BLC may penetrate the fourth, first, and second cell insulating layers IL4, IL1, and IL2 to be in contact with lower surfaces of the bit lines BL. The first cell contact plugs CT1 and the bit line contact plugs BLC may have a width that narrows upward.

Through vias TV1 may penetrate the peripheral structure PS, the interface layer AL, and the third, second, first, fourth to seventh cell insulating layers IL3, IL2, IL1, IL4 to IL7 to connect some of the second cell interconnections IT2 to the interconnection structure IS. The through via TV1 may penetrate the via insulating layer 202 and the first peripheral insulating layer PL1 of the peripheral structure PS, and may be electrically isolated from the surrounding peripheral substrate 200 by the via insulating layer 202. The through vias TV1 have a width that narrows downward. Other structures may be the same as/similar to those described with reference to FIGS. 2 to 4. The structure of the semiconductor memory device of FIG. 10 facilitates interconnection routing between the cell structure CS and the peripheral structure PS and high integration may be realized. The connection manner between the cell structure CS, the peripheral structure PS, and the interconnection structure IS is not limited to FIG. 10 and may be variously changed.

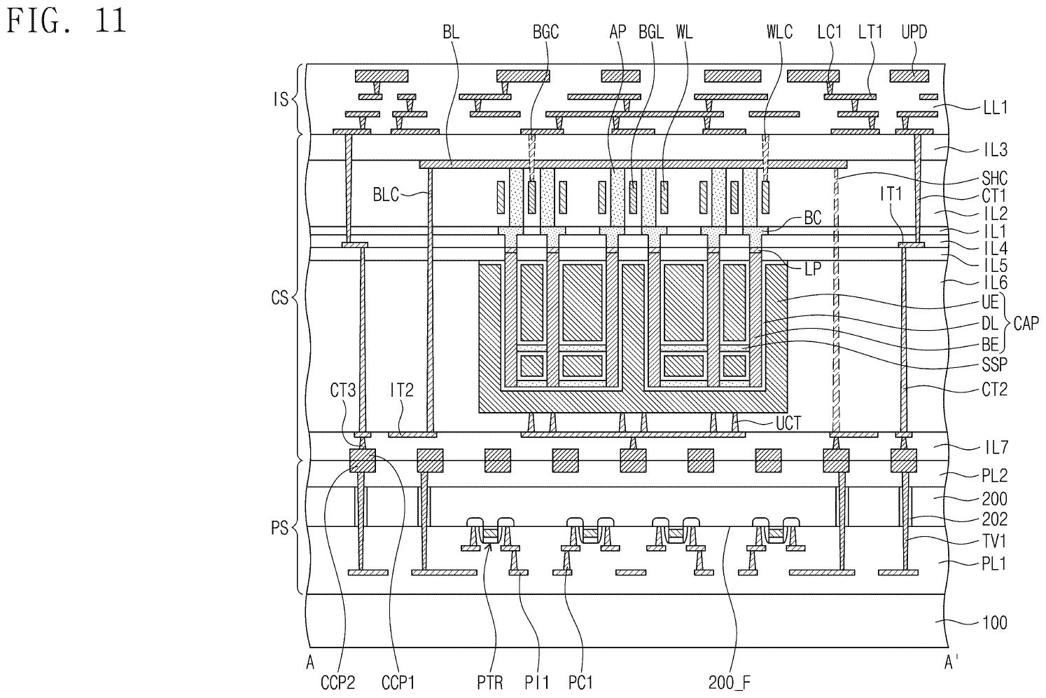

FIG. 11 is a cross-sectional view taken along line A-A′ of FIG. 2 according to an embodiment of the present inventive concept.

Referring to FIG. 11, in the semiconductor memory device according to the present embodiment, a peripheral structure PS, a cell structure CS, and an interconnection structure IS are sequentially stacked on a support substrate 100. The peripheral structure PS of FIG. 11 may have a structure the same as/similar to that of the peripheral structure PS of FIG. 6. A front surface 200_F of the peripheral substrate 200 faces the support substrate 100. A second peripheral insulating layer PL2 is disposed on a back surface 200_B of the peripheral substrate 200. Peripheral connection pads CCP2 are disposed within and at an upper end of the second peripheral insulating layer PL2. Through vias TV1 may partially penetrate the second peripheral insulating layer PL2, the via insulating layer 202, and the first peripheral insulating layer PL1 to be in contact with some of the first peripheral interconnections PI1. The through via TV1 may be electrically isolated from the surrounding peripheral substrate 200 by the via insulating layer 202. Peripheral connection pads CCP2 may include copper (Cu), for example. The through vias TV1 have a width that narrows downward.

The cell structure CS of FIG. 11 may be identical/similar to the structure of the cell structure CS of FIG. 6 turned upside down. A lower surface of a seventh cell insulating layer IL7 is in contact with an upper surface of the second peripheral insulating layer PL2. Cell connection pads CPP1 are disposed within and at a lower end of the seventh cell insulating layer IL7 and are in contact with the peripheral connection pads CPP2, respectively. In this case, the cell connection pads CCP1 and the peripheral connection pads CCP2 may be bonded to each other through a metal to metal bonding (e.g., copper (Cu) to copper (Cu) bonding), while the seventh cell insulating layer IL7 and the second peripheral insulating layer PL2 may be boded to each other through a dielectric to dielectric bonding (e.g., silicon oxide (SiO₂) to silicon oxide (SiO₂) bonding). An upper surface of the third cell insulating layer IL3 is in contact with a lower surface of the interconnection structure IS.

Sixth, fifth, fourth, first to third cell insulating layers IL6, IL5, IL4, IL1, IL2, and IL3 are sequentially stacked on the seventh cell insulating layer IL7. Second cell interconnections IT2 and third cell contact plugs CT3 are disposed in the seventh cell insulating layer IL7. A capacitor CAP is disposed in the sixth cell insulating layer IL6. The capacitor CAP of FIG. 11 has a structure the same as that of the capacitor CAP of FIG. 8. Landing pads LP are disposed within and at an upper end of the fifth cell insulating layer IL5. First cell interconnections IT1 are disposed in the fourth cell insulating layer IL4. Storage node contacts BC penetrate the fourth cell insulating layer IL4 and the first cell insulating layer IL1. Active patterns AP, word lines WL, and back gate lines BGL are disposed in the second cell insulating layer IL2. The capacitor CAP may be electrically connected to the active patterns AP through the landing pads LP and the storage node contacts BC. Bit lines BL and shield lines SHL are disposed within and at an upper end of the second cell insulating layer IL2.

First cell contact plugs CT1 penetrate the third, second, first, and fourth cell insulating layers IL3, IL2, IL1, and IL4 to connect the first cell interconnections IT1 to the interconnection structure IS. Word line contact plugs WLC penetrate the third and second cell insulating layers IL3 and IL2 to connect the word lines WL to the interconnection structure IS. Back gate line contact plugs BGC penetrate the third and second cell insulating layers IL3 and IL2 to connect the back gate lines BGL to the interconnection structure IS. The first cell contact plugs CT1, word line contact plugs WLC, and back gate line contact plugs BGC have a width that narrows downward.

The bit line contact plugs BLC penetrate the sixth, fifth, fourth, first, and second cell insulating layers IL6, IL5, IL4, IL1, and IL2 to connect ends of the bit lines BL to some of the second cell interconnections IT2. The third cell contact plugs CT3 may connect the second cell interconnections IT2 to the cell connection pads CCP1. Thus, the bit line contact plug BLC may connect one of the bit lines BL to one of the cell connection pads CCP1. For example, the bit lines BL may be connected to the cell connection pads CCP1 through the bit line contact plugs BLC, the second cell interconnections IT2, and the third cell contact plugs CT3. Shield line contact plugs SHC may penetrate the sixth, fifth, fourth, first and second cell insulating layers IL6, IL5, IL4, IL1 and IL2 to connect ends of the shield lines SHL to others of the cell interconnections IT2. The second cell contact plugs CT2 may penetrate the sixth and fifth cell insulating layers IL6 and IL5 to connect the others of the second cell interconnections IT2 to the first cell interconnections IT1. The first to third cell contact plugs CT1 to CT3 may be linked through the first and second cell interconnections IT1 and IT2 to penetrate the first to seventh cell insulating layers IL1 to IL7 to connect one of the cell connection pads CCP1 to the interconnection structure IS. The bit line contact plugs BLC, the shield line contact plugs SHC, and the second cell contact plugs CT2 may have a width that narrows upward. Other structures may be the same as/similar to those described with reference to FIGS. 2, 4, and 6. The structure of the semiconductor memory device of FIG. 11 facilitates interconnection routing between the cell structure CS and the peripheral structure PS and high integration may be realized. The connection manner between the cell structure CS, the peripheral structure PS, and the interconnection structure IS is not limited to FIG. 11 and may be variously changed.

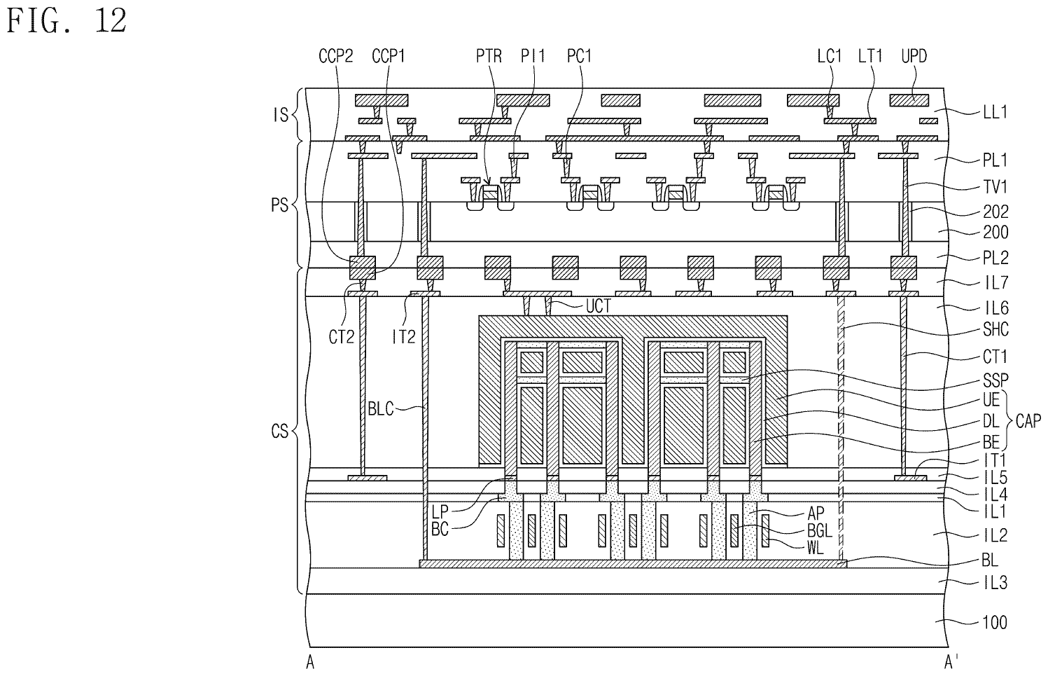

FIG. 12 is a cross-sectional view taken along line A-A′ of FIG. 2 according to an embodiment of the present inventive concept.

Referring to FIG. 12, in the semiconductor memory device according to the present embodiment, a cell structure CS, a peripheral structure PS, and an interconnection structure IS are sequentially stacked on a support substrate 100. The cell structure CS of FIG. 12 has a structure the same as/similar to that of the cell structure CS of FIG. 6. A lower surface of the third cell insulating layer IL3 is in contact with an upper surface of the support substrate 100. An upper surface of the seventh cell insulating layer IL7 is in contact with a lower surface of the second peripheral insulating layer PL2 of the peripheral structure PS. Landing pads LP and first cell interconnections IT1 are disposed on the fourth cell insulating layer IL4. First cell contact plugs CT1 may penetrate the sixth and fifth cell insulating layers IL6 and IL5 to be in contact with some of the first cell interconnections IT1. The bit line contact plugs BLC may penetrate the sixth, fifth, fourth, first, and second cell insulating layers IL6, IL5, IL4, IL1, and IL2 to be in contact with upper surfaces of the bit lines BL. The shield line contact plugs SHC may penetrate the sixth, fifth, fourth, first, and second cell insulating layers IL6, IL5, IL4, IL1, and IL2 to be in contact with upper surfaces of the shield lines SHL. Second cell contact plugs CT2 and second cell interconnections IT2 may be disposed in the seventh cell insulating layer IL7. Cell connection pads CCP1 may be disposed within and at an upper end of the seventh cell insulating layer IL7. For example, the cell connection pads CCP1 may be disposed within the seventh cell insulating layer IL7 and directly below the top surface of the seventh cell insulating layer IL7.

The peripheral structure PS of FIG. 12 may have a structure in which the peripheral structure PS of FIG. 6 turned upside down. For example, a back surface 200_B of the peripheral substrate 200 faces the support substrate 100. The back surface 200_B of the peripheral substrate 200 is covered with a second peripheral insulating layer PL2. Peripheral connection pads CCP2 are disposed within and at a lower end of the second peripheral insulating layer PL2 and may be in contact with the cell connection pads CCP1, respectively. In this case, the cell connection pads CCP1 and the peripheral connection pads CCP2 may be bonded to each other through a metal to metal bonding (e.g., copper (Cu) to copper (Cu) bonding), while the seventh cell insulating layer IL7 and the second peripheral insulating layer PL2 may be boded to each other through a dielectric to dielectric bonding (e.g., silicon oxide (SiO₂) to silicon oxide (SiO₂) bonding). Peripheral transistors PTR, first peripheral interconnections PI1, first peripheral contact plugs PC1, and first peripheral insulating layer PL1 are disposed on a front surface 200_F of the peripheral substrate 200. An interconnection structure IS is disposed on the peripheral structure PS. The interconnection structure IS may include an interconnection insulating layer LL1 and multi-layered upper interconnections LT1, upper contact plugs LC1, and upper connection pads UPD. The first peripheral interconnections PI1 are connected to the upper interconnections LT1 of the interconnection structure IS through first peripheral contact plugs PC1. Through vias TV1 may partially penetrate the second peripheral insulating layer PL2, the via insulating layer 202, and the first peripheral insulating layer PL1 to be in contact with some of the first peripheral interconnections PI1. The through via TV1 may be electrically isolated from the surrounding peripheral substrate 200 by the via insulating layer 202. The through vias TV1 may have a width that narrows upward. Other structures may be the same as/similar to those described with reference to FIGS. 2, 4, and 6. The structure of the semiconductor memory device of FIG. 12 facilitates interconnection routing between the cell structure CS and the peripheral structure PS and high integration may be realized. The connection manner between the cell structure CS, the peripheral structure PS, and the interconnection structure IS is not limited to FIG. 12 and may be variously changed.

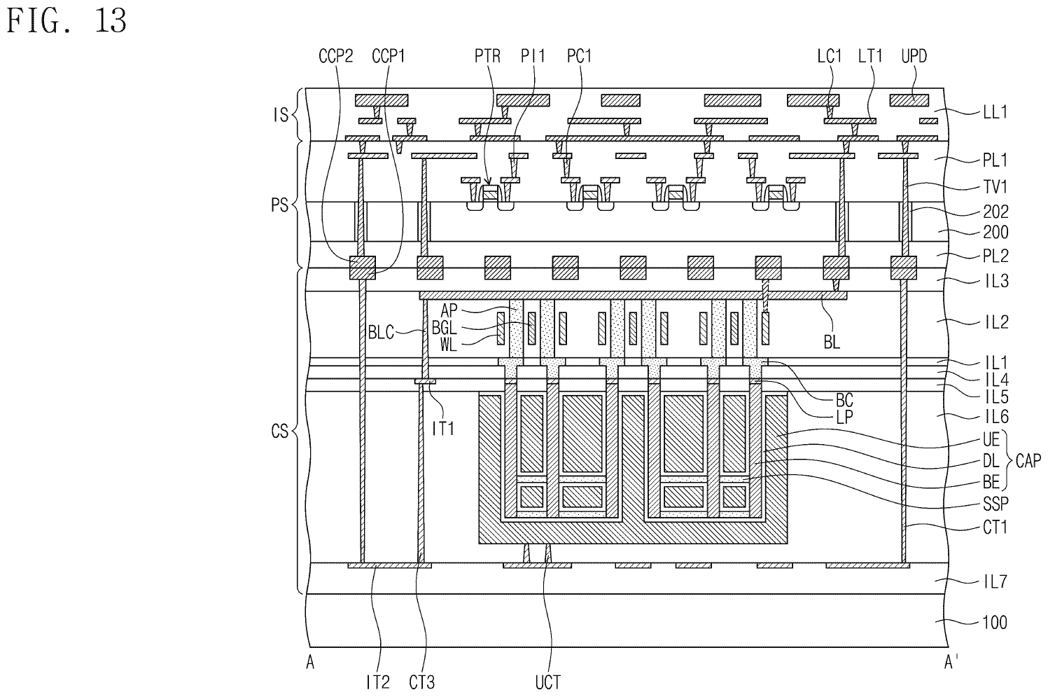

FIG. 13 is a cross-sectional view taken along line A-A′ of FIG. 2 according to an embodiments of the present inventive concept.

Referring to FIG. 13, in the semiconductor memory device according to the present embodiment, a cell structure CS, a peripheral structure PS, and an interconnection structure IS are sequentially stacked on a support substrate 100. The peripheral structure PS of FIG. 13 may be the same as/similar to the peripheral structure PS of FIG. 12. The structure of the cell structure CS of FIG. 13 may be similar to the structure of the cell structure CS of FIG. 11. A lower surface of a seventh cell insulating layer IL7 is in contact with an upper surface of the support substrate 100. An upper surface of the third cell insulating layer IL3 is in contact with a lower surface of the second peripheral insulating layer PL2 of the peripheral structure PS. Cell connection pads CCP1 may be disposed in the third cell insulating layer IL3 and may be in contact with the peripheral connection pads CCP2, respectively. In this case, the cell connection pads CCP1 and the peripheral connection pads CCP2 may be bonded to each other through a metal to metal bonding (e.g., copper (Cu) to copper (Cu) bonding), while the third cell insulating layer IL3 and the second peripheral insulating layer PL2 may be boded to each other through a dielectric to dielectric bonding (e.g., silicon oxide (SiO₂) to silicon oxide (SiO₂) bonding). The first cell contact plugs CT1 penetrate the third, second, first, fourth, fifth, and sixth cell insulating layers IL3, IL2, IL1, IL4, IL5, and IL6 to connect some of the second cell interconnections IT2 to the cell connection pads CCP1. Word line contact plugs WLC may partially penetrate the third cell insulating layer IL3 and the second cell insulating layer IL2 to connect the word lines WL to some of the cell connection pads CCP1. The first cell contact plugs CT1 and the word line contact plugs WLC may have a width that narrows downward.

Bit line contact plugs BLC may penetrate the fourth, first, and second cell insulating layers IL4, IL1, and IL2 to connect the first cell interconnections IT1 to the bit lines BL. Third cell contact plugs CT3 penetrate the sixth and fifth cell insulating layers IL6 and IL5 to connect some of the second cell interconnections IT2 to the first cell interconnections IT1. The bit line contact plugs BLC and the third cell contact plugs CT3 may have a width that narrows upward. Other structures may be the same as/similar to those described with reference to FIGS. 2, 4, and 6. The structure of the semiconductor memory device of FIG. 13 facilitates interconnection routing between the cell structure CS and the peripheral structure PS and high integration may be realized. The connection manner between the cell structure CS, the peripheral structure PS, and the interconnection structure IS is not limited to FIG. 13 and may be variously changed.

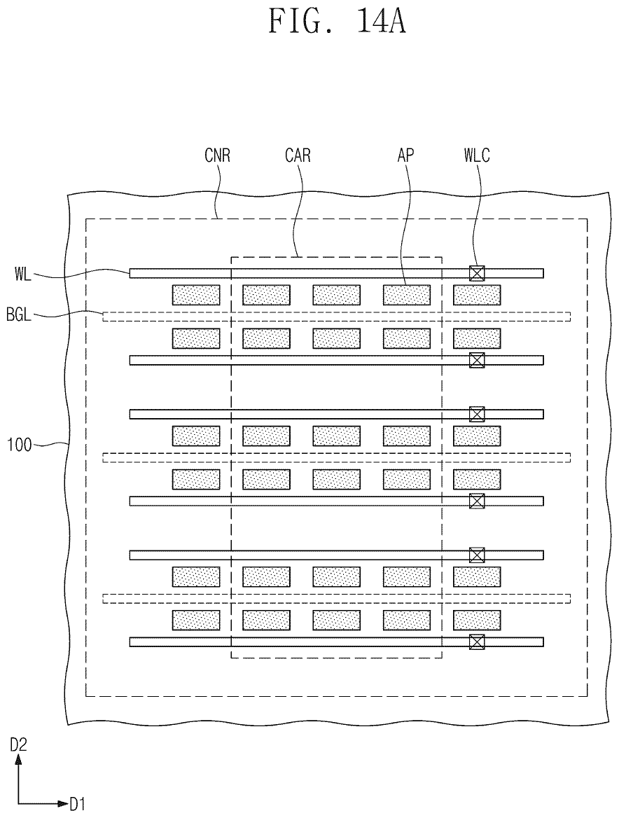

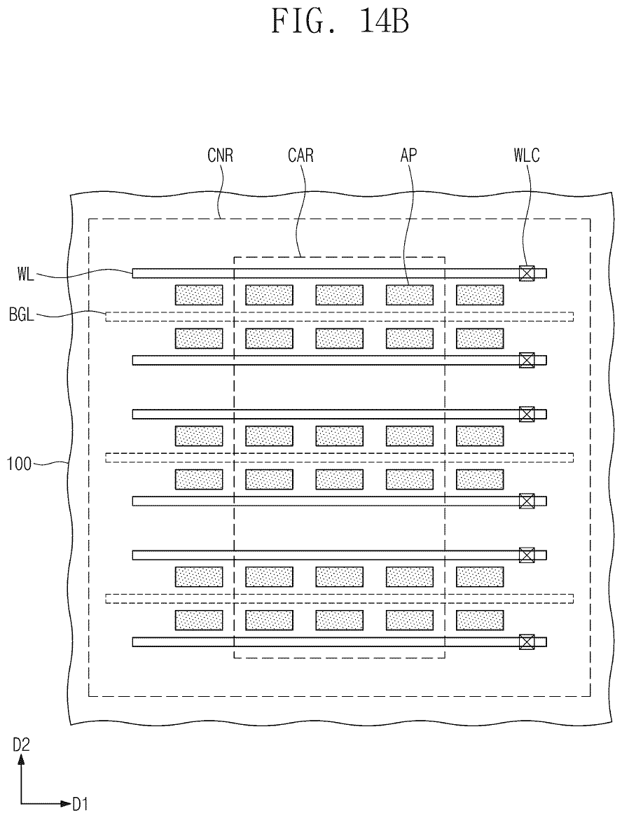

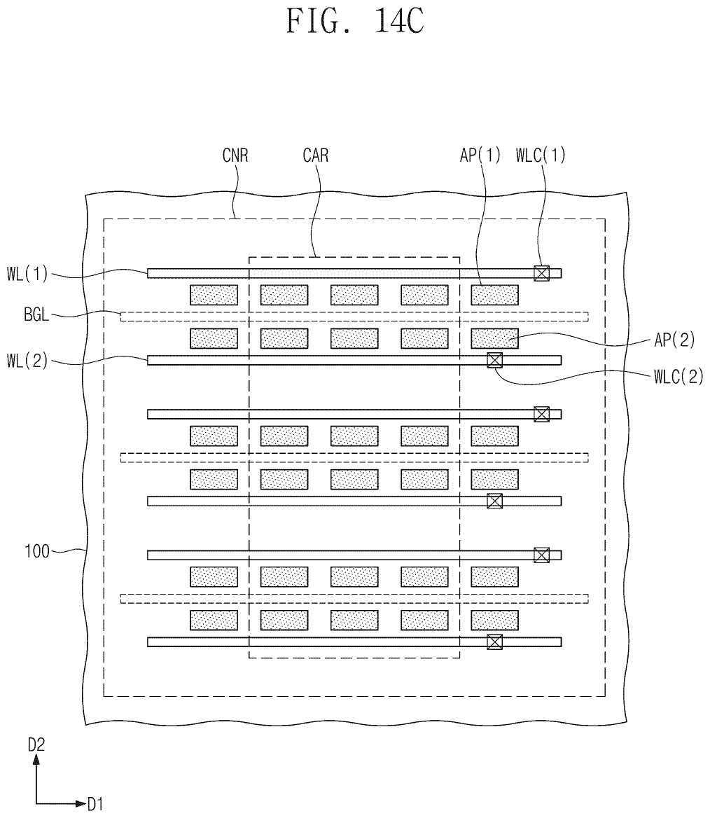

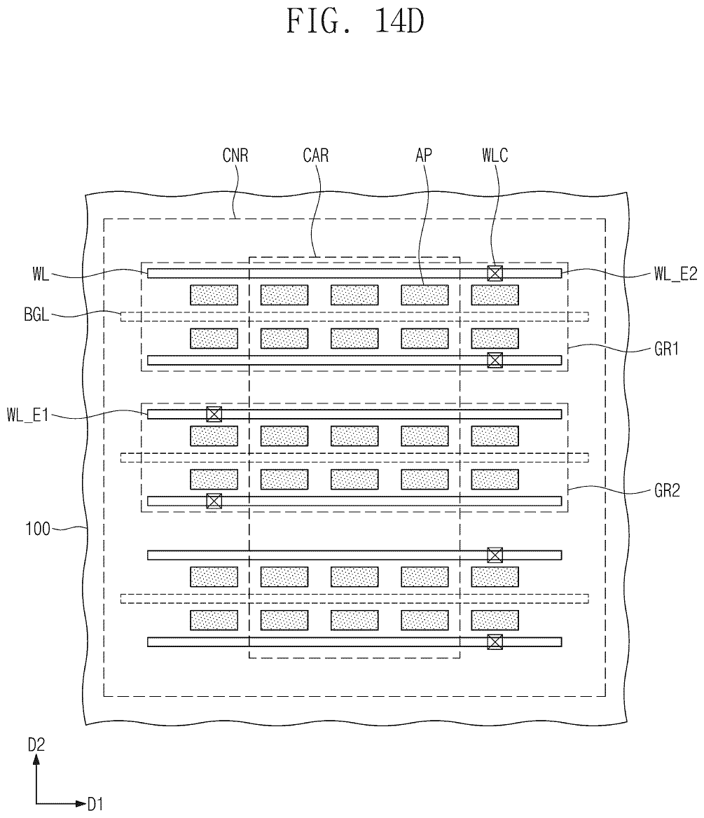

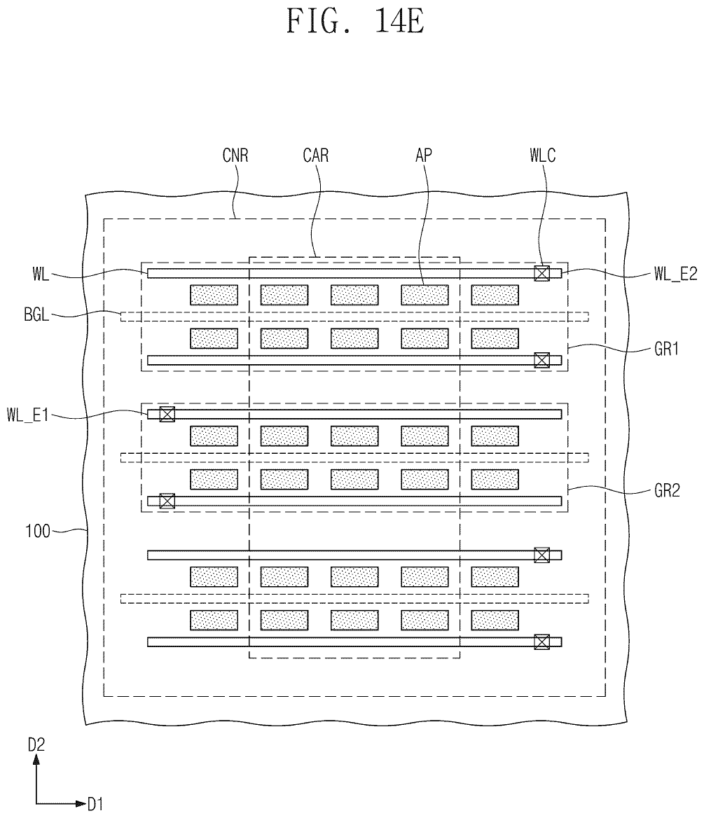

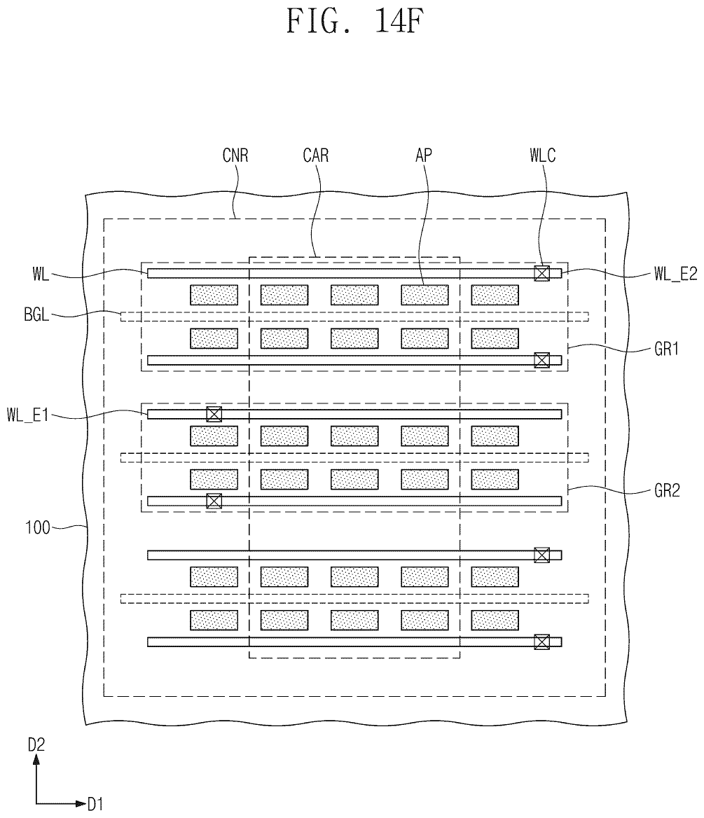

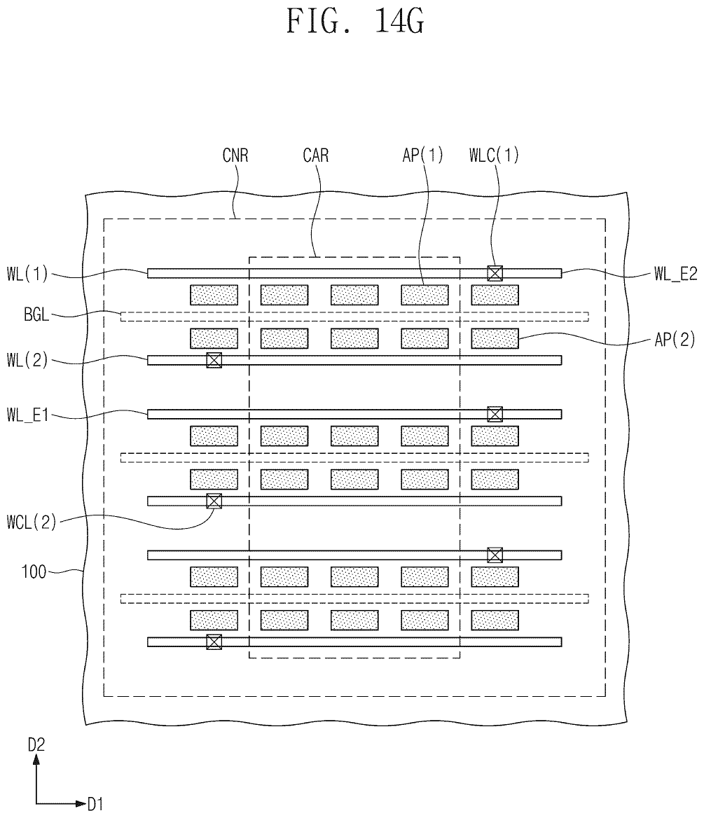

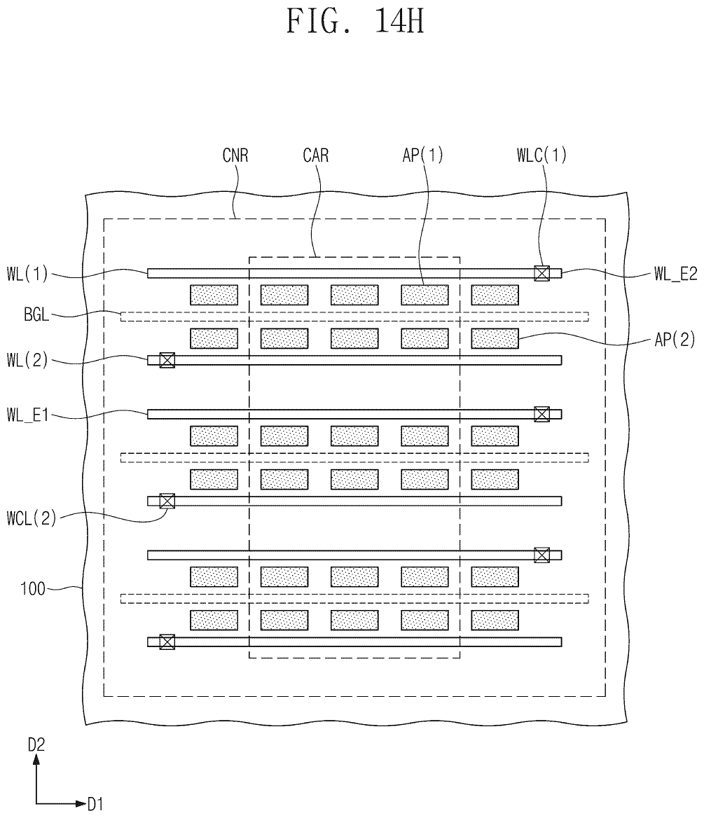

FIGS. 14A to 14J are plan views each showing an arrangement of word line contact plugs according to an embodiment of the present inventive concept.

Referring to FIG. 14A, a support substrate 100 may include a cell array region CAR and a connection region CNR surrounding the cell array region CAR. Word lines WL and back gate lines BGL may extend in a first direction D1 and be spaced apart from each other in a second direction D2. The word lines WL and back gate lines BGL may extend across the cell array region CAR to the connection region CNR. A length of the back gate line BGL in the first direction D1 may be larger than a length of the word line WL in the first direction D1. Some of active patterns AP may be disposed on the connection region CNR. The active patterns AP disposed on the connection region CNR may be dummy patterns. Word line contact plugs WLC may be disposed on the connection region CNR. The word line contact plugs WLC may be arranged adjacent to centers of the active patterns AP on the connection region CNR as shown in FIG. 14A. The word line contact plugs WLC may be arranged in a row in the second direction D2.

Alternatively, referring to FIG. 14B, the word line contact plugs WLC may be adjacent to ends of the word lines WL, may be arranged in a row in the second direction D2, and may be spaced apart from the active patterns AP in the first direction D1. The word line contact plugs WLC are not disposed in a straight line with the active patterns AP.

Alternatively, referring to FIG. 14C, the word line contact plugs WLC may be arranged in a zigzag manner in the second direction D2 adjacent to one side of the support substrate 100. For example, the word lines WL include a pair of first word lines WL(1) and second word lines WL(2) adjacent to each other in the second direction D2. The active patterns AP include a first active pattern AP(1) adjacent to the first word line WL(1), and a second active pattern AP(2) adjacent to the second word line WL(2). The word line contact plugs WLC includes a first word line contact plug WLC(1) connected to the first word line WL(1) at a position adjacent to an end of the first word line WL(1), and a second word line contact plug WLC(2) connected to the second word line WL(2) at a position adjacent to an end of the second word line WL(2). The first word line contact plug WLC(1) is spaced apart from the first active pattern AP(1) on the connection region CNR in the first direction D1. The second word line contact plug WLC(2) is disposed adjacent to a center of the second active pattern AP(2) on the connection region CNR.

Alternatively, referring to FIG. 14D, the word line contact plugs WLC are alternately arranged two by two in a zigzag manner. Each of the word lines WL may include first ends WL_E1 adjacent to a left side of the support substrate 100 and second ends WL_E2 adjacent to a right side of the support substrate 100. A pair of word lines WL adjacent to each other may form a first group GR1 or a second group GR2. The first group GR1 and the second group GR2 may be alternately arranged in the second direction D2. In the word lines WL belonging to the first group GR1, the word line contact plugs WLC may be adjacent to centers of the active patterns AP adjacent to the second ends WL_E2. In the word lines WL belonging to the second group GR2, the word line contact plugs WLC may be adjacent to centers of the active patterns AP adjacent to the first ends WL_E1.

Alternatively, referring to FIG. 14E, in the word lines WL belonging to the first group GR1, the word line contact plugs WLC may be adjacent to the second ends WL_E2 and may be spaced apart from the active patterns AP in the first direction D1. In the word lines WL belonging to the second group GR2, the word line contact plugs WLC may be adjacent to the first ends WL_E1 and may be spaced apart from the active patterns AP in a direction opposite to the first direction D1. For example, the word line contact plugs WLC adjacent to the first ends WL_E1 or adjacent to the second ends WL_E2 may be spaced apart from the active patterns AP in a direction away from the center of the respective word line WL.

Alternatively, referring to FIG. 14F, in the word lines WL belonging to the first group GR1, the word line contact plugs WLC may be adjacent to the second ends WL_E2 and may be spaced apart from the active patterns AP in the first direction D1. In the word lines WL belonging to the second group GR2, the word line contact plugs WLC may be adjacent to the first ends WL_E1 and may be adjacent to the centers of the active patterns AP.

Alternatively, referring to FIG. 14G, the word line contact plugs WLC may be arranged in a zigzag manner. The first word line contact plug WLC(1) may be disposed adjacent to a center of the first active pattern AP(1) adjacent to the second end WL_E2 of the first word line WL(1). The second word line contact plug WLC(2) may be disposed adjacent to a center of the second active pattern AP(2) adjacent to the first end WL_E1 of the second word line WL(2).

Alternatively, referring to FIG. 14H, the word line contact plugs WLC may be arranged in a zigzag manner. The first word line contact plug WLC(1) may be adjacent to the second end WL_E2 of the first word line WL(1) and may be spaced apart from the first active pattern AP(1) in the first direction D1 away from the center of the first word line WL(1). The second word line contact plug WLC(2) may be adjacent to the first end WL_E1 of the second word line WL(2) and may be spaced apart from the second active pattern AP(2) in a direction opposite to the first direction D1 and away from the center of the second word line WL(2).

Alternatively, referring to FIG. 14I, the word line contact plugs WLC may be arranged in a zigzag manner. In the first group GR1, the first word line contact plug WLC(1) may be adjacent to the second end WL_E2 of the first word line WL(1), and may be spaced apart from the first active pattern AP(1) in the first direction D1 away from the center of the first word line WL(1). In the first group GR1, the second word line contact plug WLC(2) may be adjacent to the second end WL_E2 of the second word line WL(2), and may be adjacent to the center of the second active pattern AP(2). In the second group GR2, the first word line contact plug WLC(1) may be adjacent to the first end WL_E1 of the first word line WL(1), and may be spaced apart from the first active pattern AP(1) in the direction opposite to the first direction D1 and away from the center of the first word line WL(1). In the second group GR2, the second word line contact plug WLC(2) may be adjacent to the first end WL_E1 of the second word line WL(2), and may be adjacent to the center and second active pattern AP(2).

Alternatively, referring to FIG. 14J, the word line contact plugs WLC may be arranged in a zigzag manner. In the first group GR1, the first word line contact plug WLC(1) may be adjacent to the second end WL_E2 of the first word line WL(1), and may be adjacent to the center of the first active pattern AP(1). In the first group GR1, the second word line contact plug WLC(2) may be adjacent to the first end WL_E1 of the second word line WL(2) and may be spaced apart from the second active pattern AP(2) in the direction opposite to the first direction D1 and away from the center of the second word line WL(2). In the second group GR2, the first word line contact plug WLC(1) may be adjacent to the second end WL_E2 of the first word line WL(1), and may be spaced apart from the active pattern AP(1) in the first direction D1 away from the center of the first word line WL(1). In the second group GR2, the second word line contact plug WLC(2) may be adjacent to the first end WL_E1 of the second word line WL(2), and may be adjacent to the center of the second active pattern AP(2).

As a result, the arrangement of word line contact plugs WLC may be variously changed. The arrangement of word line contact plugs WLC is not limited to FIGS. 14A to 14J.

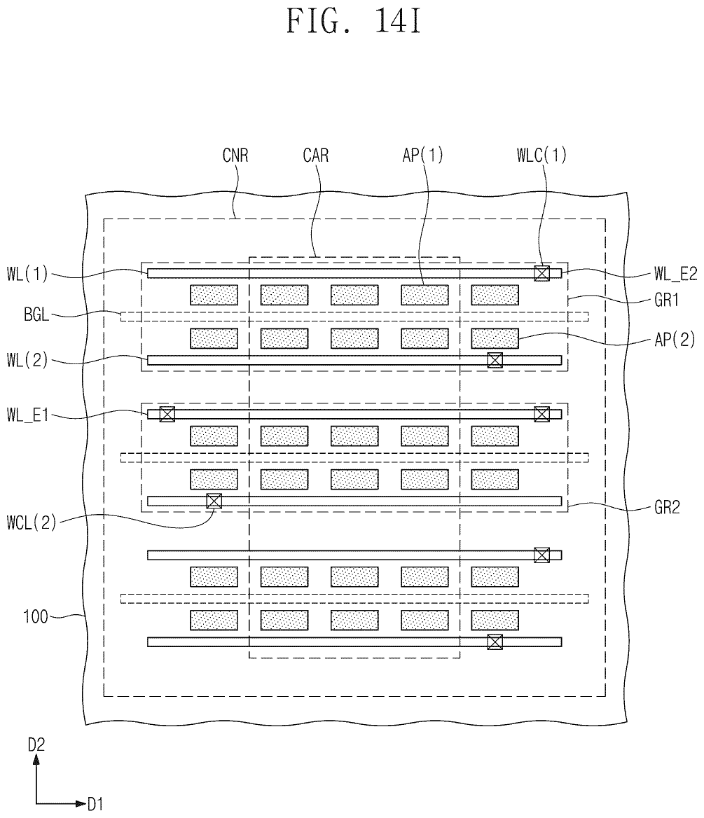

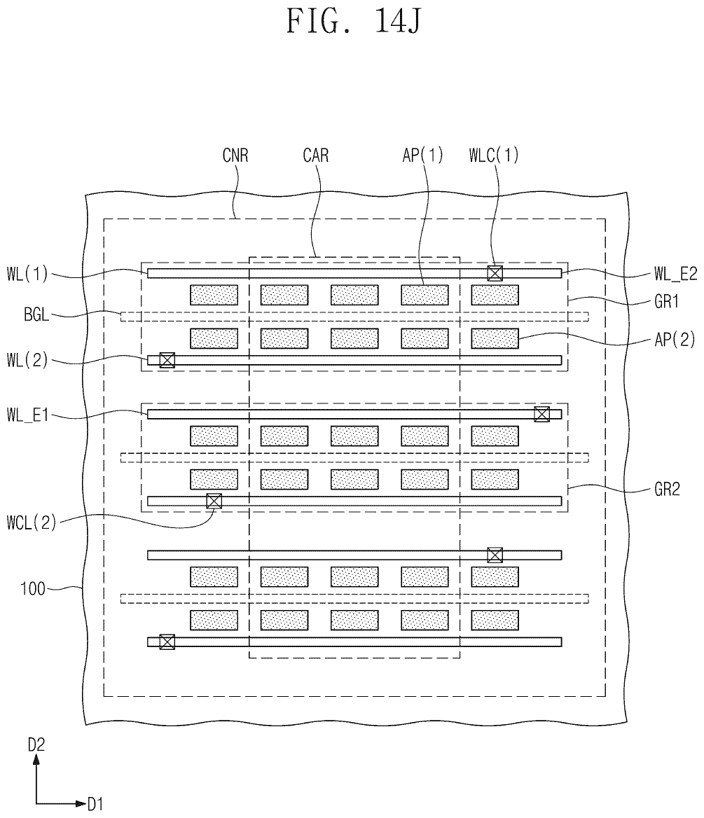

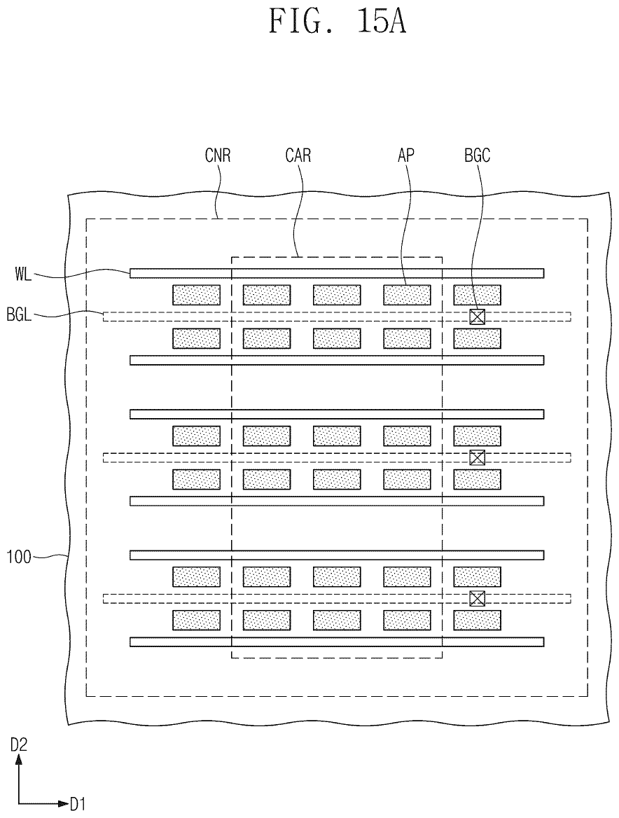

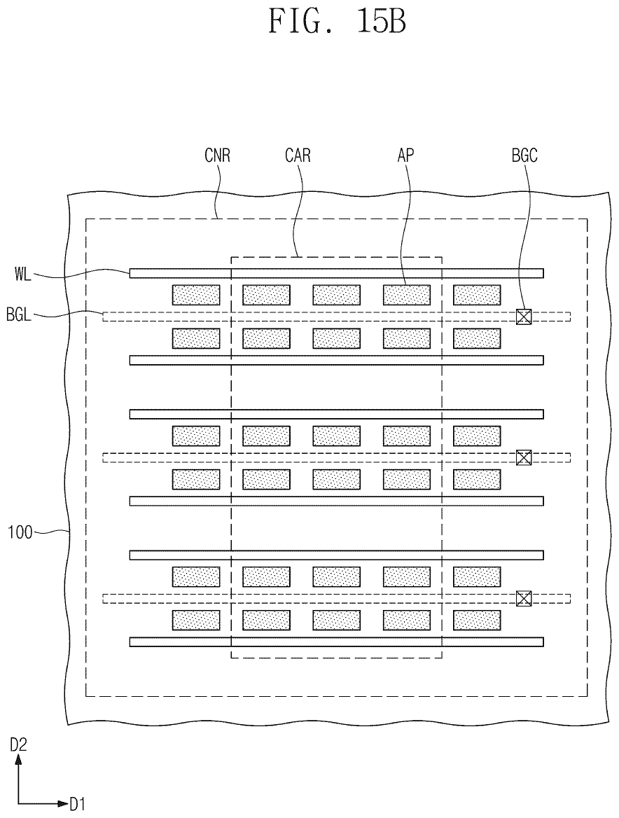

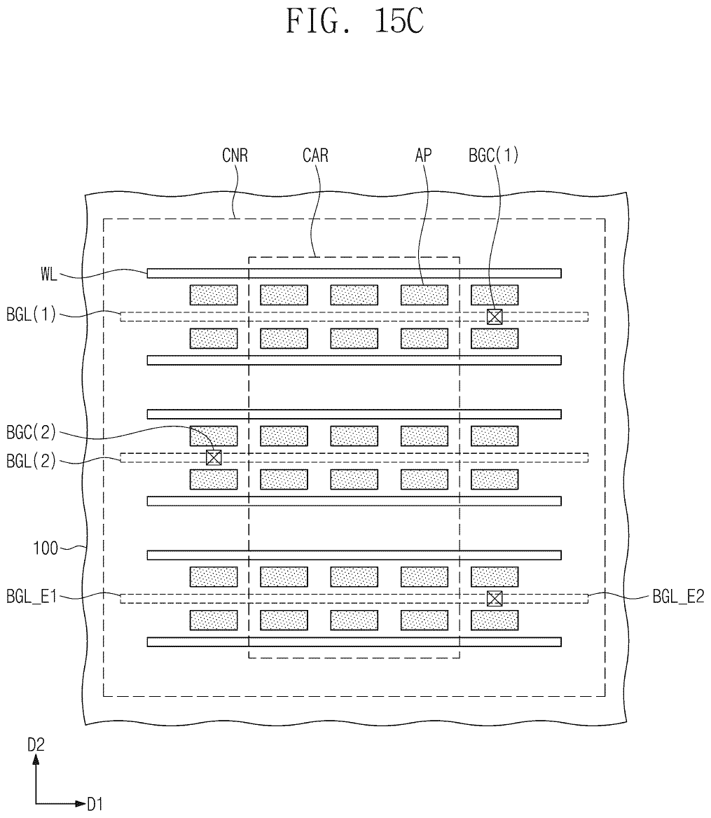

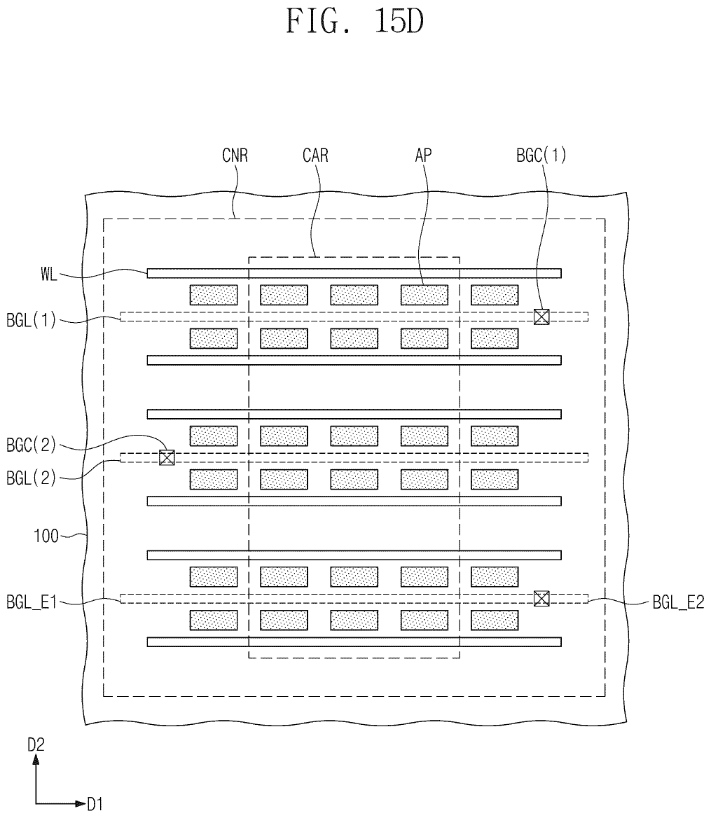

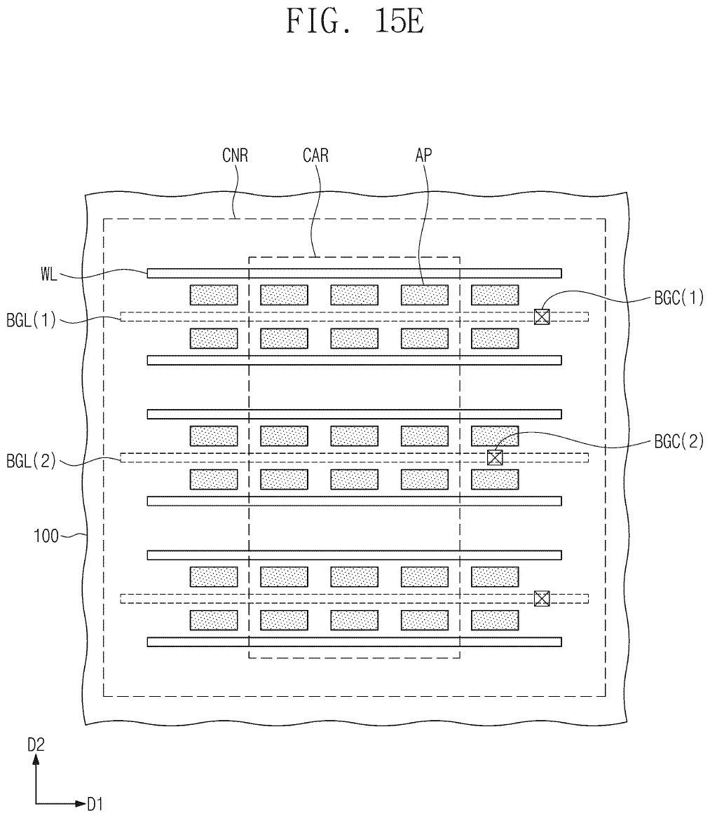

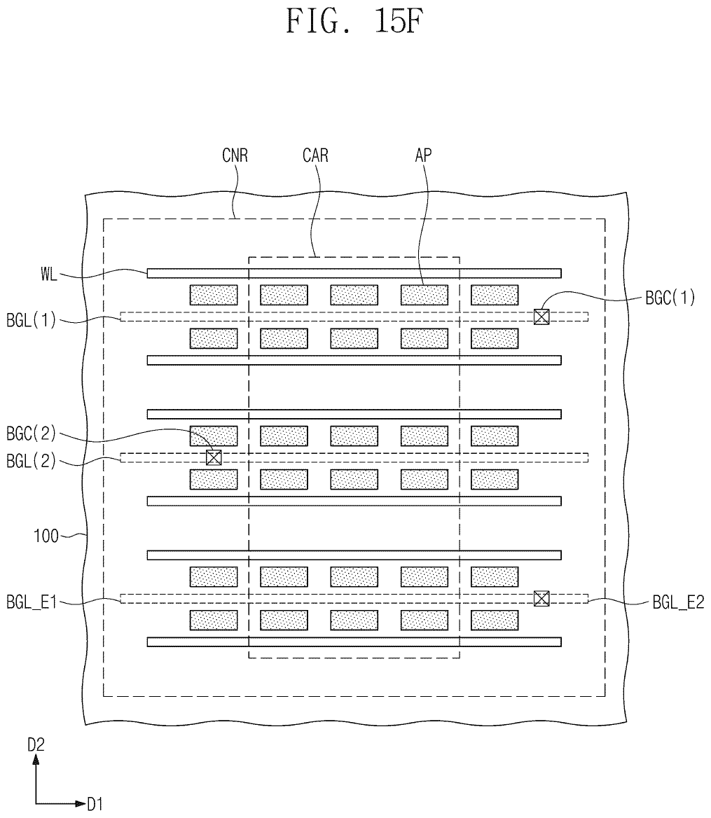

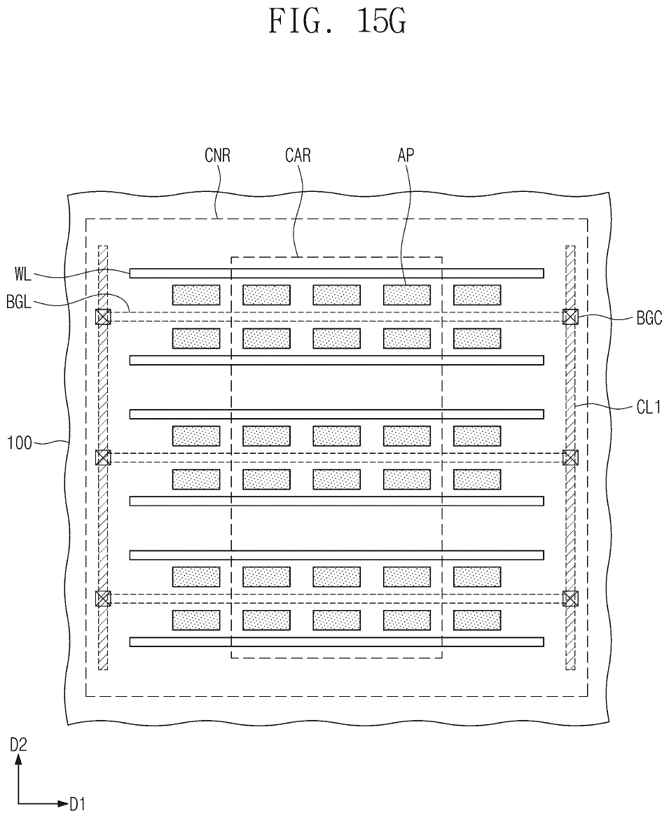

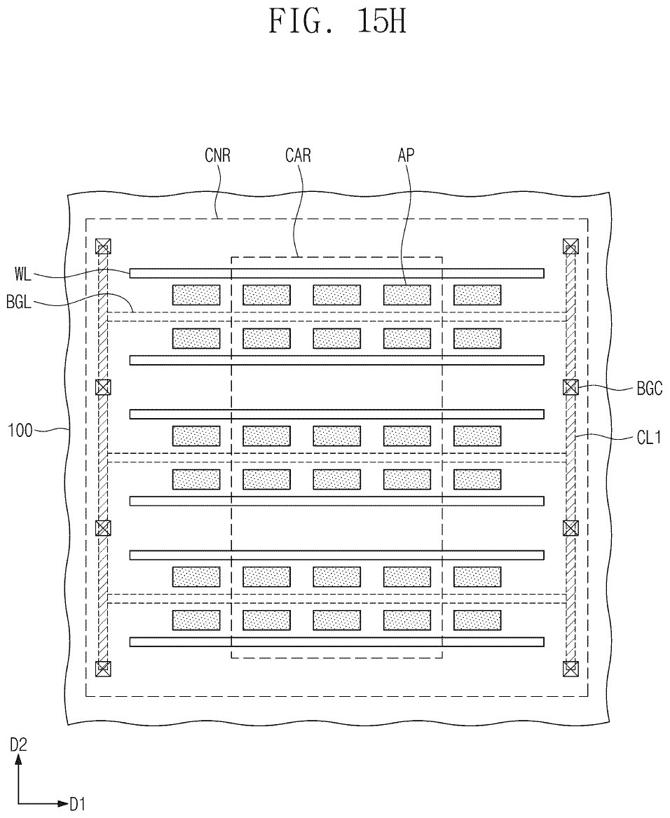

FIGS. 15A to 15H are plan views each showing an arrangement of back gate line contact plugs according to an embodiment of the present inventive concept.

Referring to FIG. 15A, the back gate line contact plugs BGC may be disposed adjacent to ends of the back gate lines BGL on the connection region CNR. The back gate line contact plugs BGC may be disposed between a pair of adjacent active patterns AP. For example, the back gate line contact plug BGC may be adjacent to the center of the active pattern AP. The back gate lines BGL may be arranged in a row in the second direction D2 adjacent to one side of the support substrate 100.

Alternatively, referring to FIG. 15B, the back gate line contact plugs BGC may be disposed adjacent to ends of the back gate lines BGL on the connection region CNR. The back gate line contact plugs BGC may be arranged to be spaced apart from the active patterns AP in the first direction D1 away from the center of the respective back gate line BGL. The back gate lines BGL may be arranged in a row in the second direction D2 adjacent to one side of the support substrate 100.

Alternatively, referring to FIG. 15C, the back gate line contact plugs BGC may be arranged in a zigzag manner on the connection region CNR. For example, a first back gate line contact plug BGC(1) may be adjacent to a right end BGL_E2 of the first back gate line BGL (1) and may be disposed between the active patterns AP. A second back gate line contact plug BGC(2) may be adjacent to a left end BGL_E1 of the second back gate line BGL (2) and may be disposed between the active patterns AP.

Alternatively, referring to FIG. 15D, the back gate line contact plugs BGC may be arranged in a zigzag manner on the connection region CNR. For example, the first back gate line contact plug BGC(1) may be adjacent to the right end BGL_E2 of the first back gate line BGL (1), and may be spaced apart from the active patterns AP in the first direction D1 away from the center of the first back gate line BGL (1). The second back gate line contact plug BGC(2) may be adjacent to the left end BGL_E1 of the second back gate line BGL (2) and may be spaced apart from the active patterns AP in a direction opposite to the first direction D1 and away from the center of the second back gate line BGL (2).

Alternatively, referring to FIG. 15E, the back gate line contact plugs BGC may be arranged in a zigzag manner on the connection region CNR on one side of the support substrate 100. For example, the first back gate line contact plug BGC(1) may be adjacent to the right end BGL_E2 of the first back gate line BGL (1), and may be spaced apart from the active patterns AP in the first direction D1 away from the center of the first back gate line BGL (1). The second back gate line contact plug BGC(2) may be adjacent to the right end BGL_E2 of the second back gate line BGL (2) and may be disposed between the active patterns AP.

Alternatively, referring to FIG. 15F, the back gate line contact plugs BGC may be arranged in a zigzag manner. For example, the first back gate line contact plug BGC(1) may be adjacent to the right end BGL_E2 of the first back gate line BGL (1), and may be spaced apart from the active patterns AP in the first direction D1 away from the center of the first back gate line BGL (1). The second back gate line contact plug BGC(2) may be adjacent to the left end BGL_E1 of the second back gate line BGL (2) and may be disposed between the active patterns AP.

Alternatively, referring to FIG. 15G, ends of the back gate lines BGL may be connected to each other by a first connection line CL1. The first connection line CL1 may extend in the second direction D2. The back gate line contact plugs BGC may be disposed at intersections of the back gate lines BGL and the first connection line CL1.

Alternatively, referring to FIG. 15H, ends of the back gate lines BGL may be connected to each other by the first connection line CL1 extending in the second direction D2, and the back gate line contact plugs BGC may be disposed on the first connection line CL1 between ends of the back gate lines BGL.

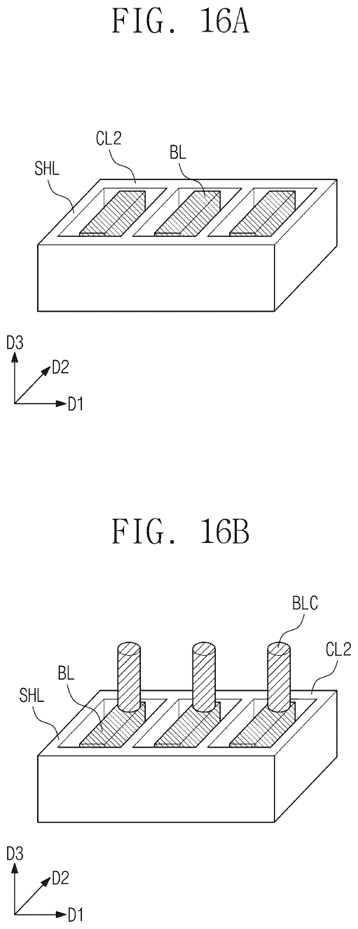

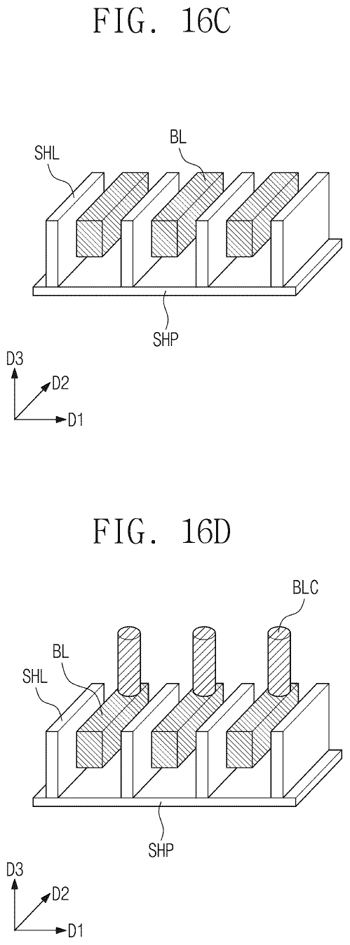

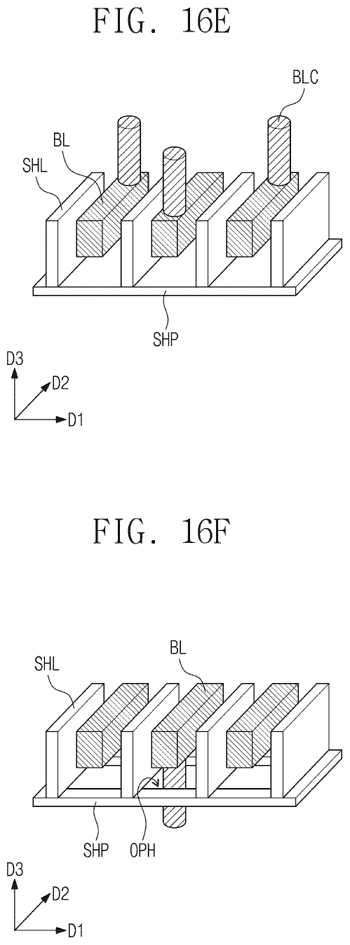

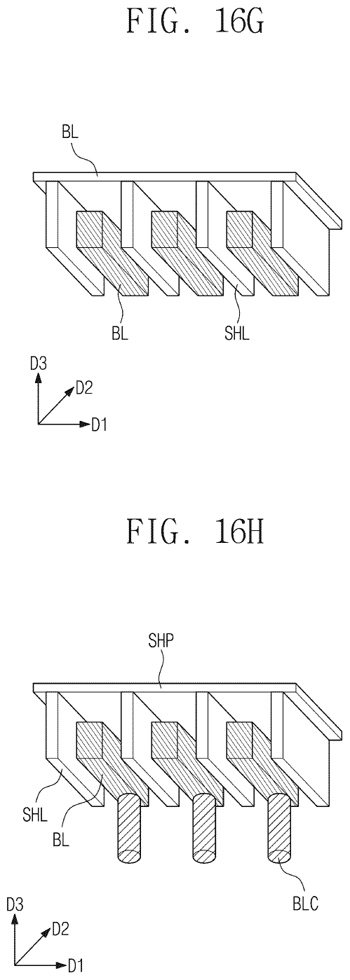

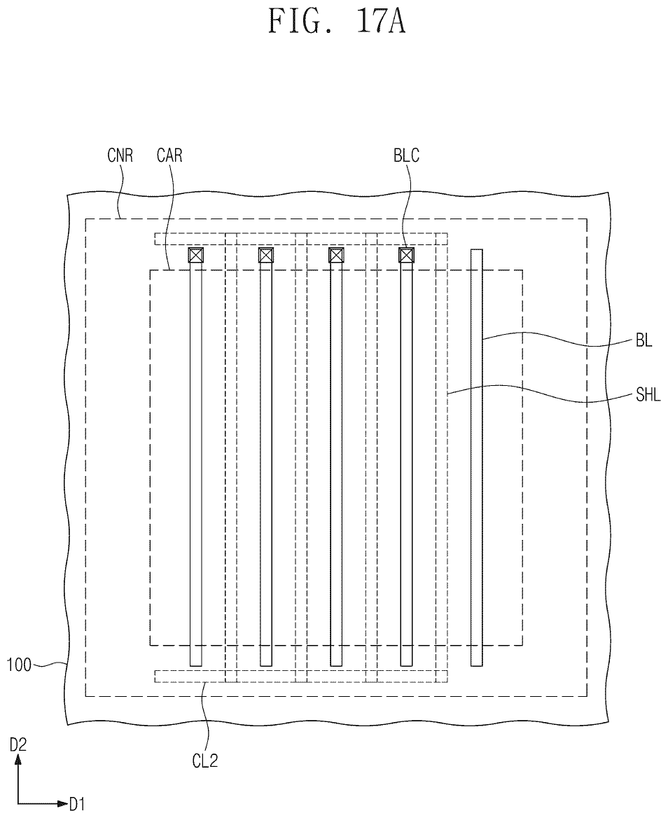

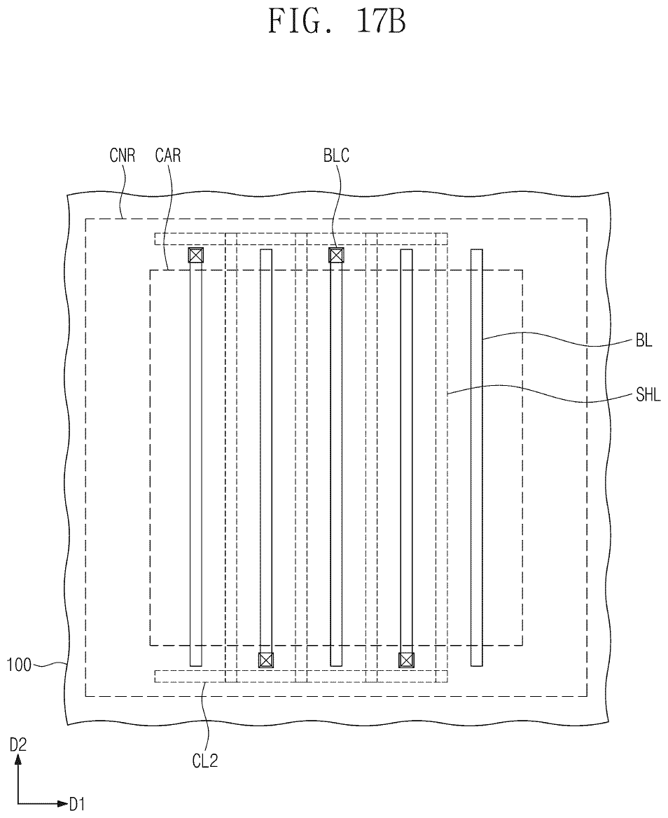

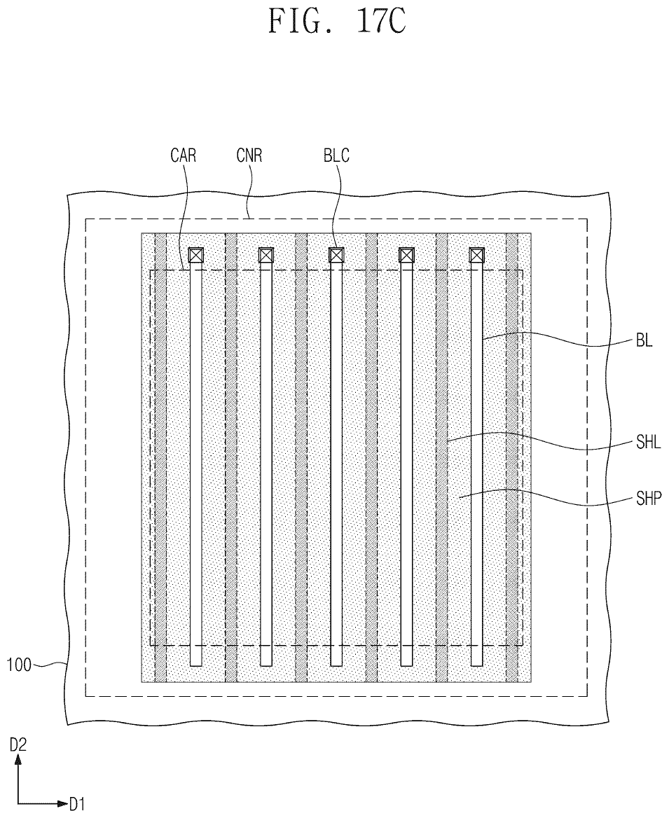

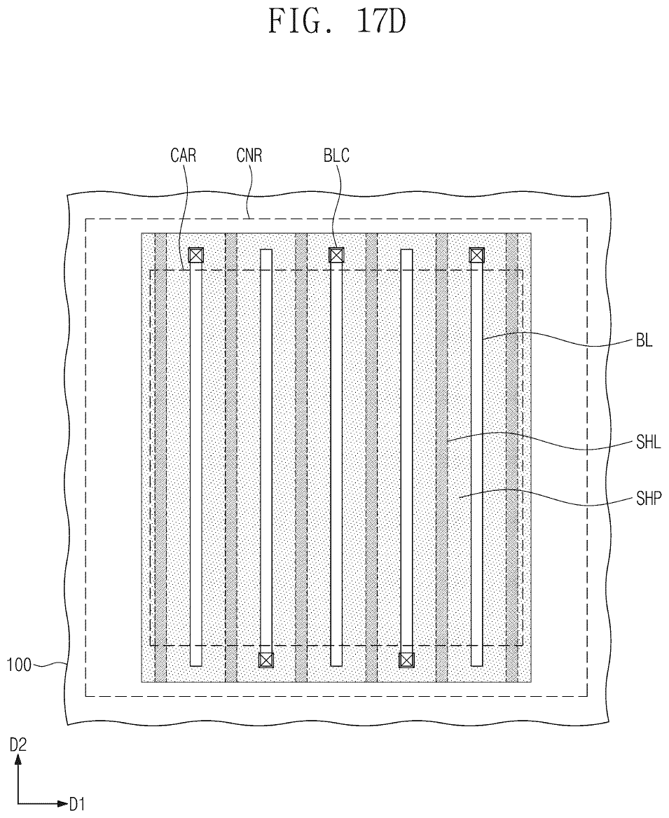

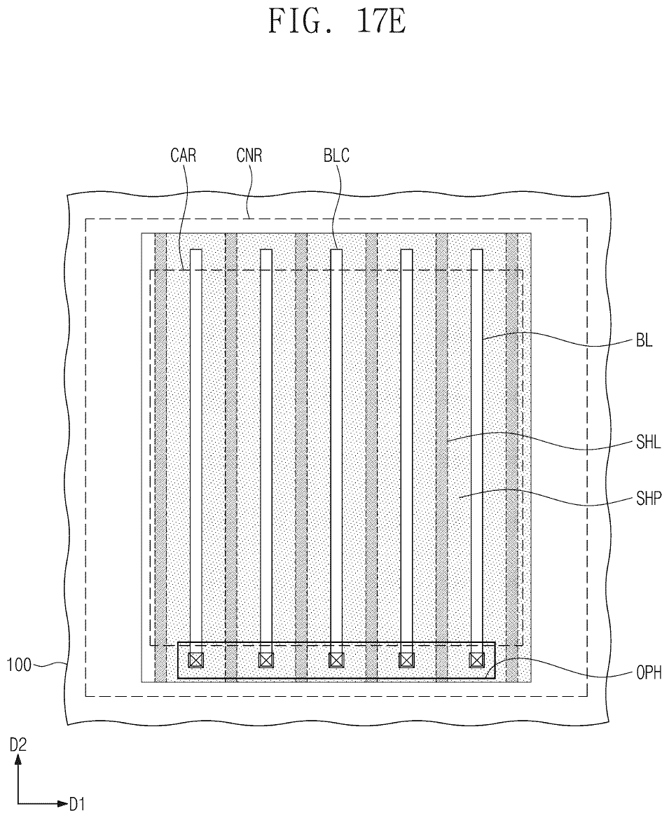

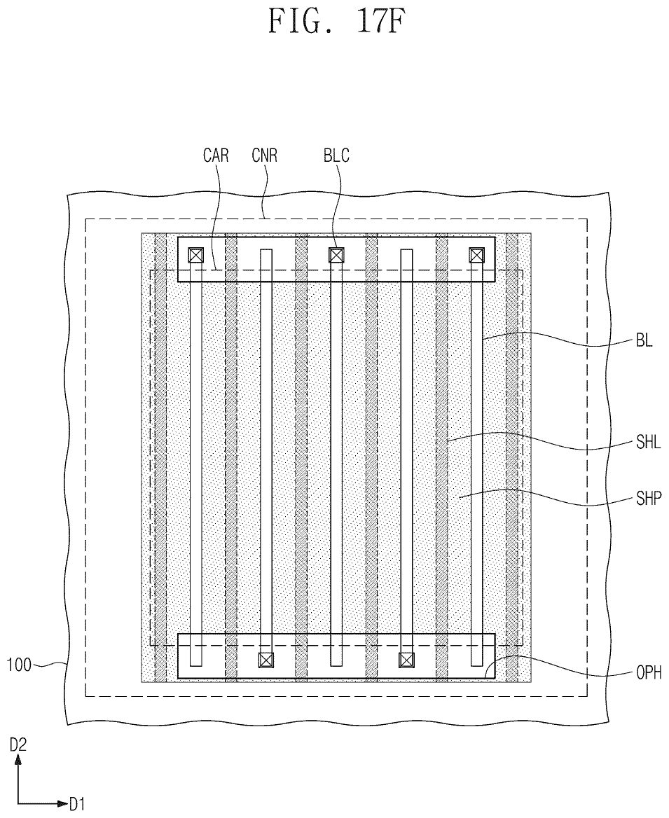

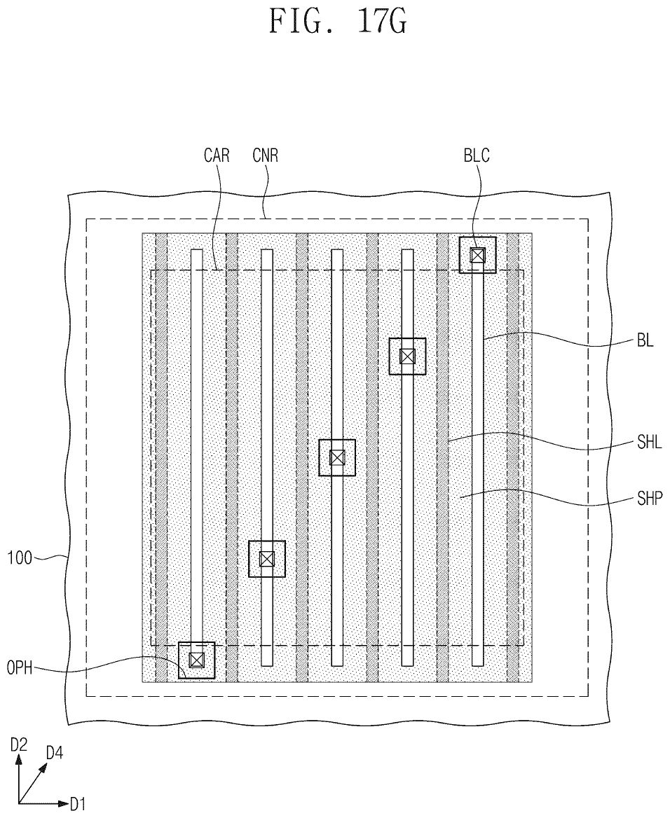

FIGS. 16A to 16H are perspective views showing structures of bit lines and shield lines each according to an embodiment of the present inventive concept. FIGS. 17A to 17G are plan views each showing an arrangement of bit line contact plugs according to an embodiment of the present inventive concept.

Referring to FIGS. 16A and 17A, each of the bit lines BL and the shield lines SHL may extend in the second direction D2. The bit lines BL and the shield lines SHL may be alternately and repeatedly arranged in the first direction D1. The bit lines BL and the shield lines SHL may extend across the cell array region CAR to the connection region CNR. Ends of the shield lines SHL may be connected to the second connection line CL2. The second connection line CL2 may extend in the first direction D1.

Referring to FIGS. 16B and 17A, the bit line contact plugs BLC may be arranged to be in contact with the ends of the bit lines BL on the connection region CNR adjacent to one side of the support substrate 100. The bit line contact plugs BLC may be arranged in a row in the first direction D1.

Alternatively, referring to FIG. 17B, the bit line contact plugs BLC may be arranged in a zigzag manner in the first direction D1. The bit line contact plugs BLC may be in contact with one ends of the odd bit lines BL and may be in contact with other ends of the even bit lines BL. The other ends of the even bit lines are also on the connection region, and are adjacent to opposite side of the one side of the support substrate 100.

Alternatively, referring to FIGS. 16C, 16D, and 17C, lower surfaces of the shield lines SHL may be connected by a shield plate SHP. In an embodiment of the present inventive concept, the bit lines BL and the shield lines SHL are completely overlapped by the shield plate SHP, and the shield plate SHP may overlap the entire cell array region CAR and a portion of the connection region CNR. However, the present inventive concept is not limited thereto. The bit line contact plugs BLC may be arranged to be in contact with ends of the bit lines BL on the connection region CNR adjacent to one side of the support substrate 100. The bit line contact plugs BLC may be arranged in a row in the first direction D1.

Alternatively, referring to FIGS. 16E and 17D, the bit line contact plugs BLC may be arranged in a zigzag manner in the first direction D1. The bit line contact plugs BLC may be in contact with one ends of the odd bit lines BL and may be in contact with other ends of the even bit lines BL.

Alternatively, referring to FIGS. 16F and 17E, an opening OPH may be formed in the shield plate SHP connecting lower surfaces of the shield lines SHL. The opening OPH may be elongated in the first direction D1 and may expose lower surfaces of one ends of the bit lines BL. The bit line contact plugs BLC may be in contact with lower surfaces of one ends of the bit lines BL through the opening OPH.

Alternatively, referring to FIG. 17F, two openings OPH may be formed in the shield plate SHP connecting the lower surfaces of the shield lines SHL to expose both ends of the bit lines BL. The bit line contact plugs BLC may be alternately arranged in the first direction D1. For example, the bit line contact plugs BLC may be arranged in a zigzag manner in the first direction D1. The bit line contact plugs BLC may be in contact with one ends of the lower surfaces of odd bit lines BL, and may be in contact with other ends of the lower surfaces of even bit lines BL.

Alternatively, referring to FIG. 17G, openings OPH in the shield plate SHP connecting the lower surfaces of the shield lines SHL may be formed to have the number corresponding to the number of bit lines BL. The openings OPH may be arranged in a fourth direction D4 that intersects both the first direction D1 and the second direction D2. The bit line contact plugs BLC may be connected to bit lines BL through the openings OPH. Accordingly, the bit line contact plugs BLC may be arranged in the fourth direction D4.

Alternatively, referring to FIGS. 16G and 16H, the shield plate SHP may connect upper surfaces of the shield lines SHL. As a result, lower surfaces of the bit lines BL may be exposed. The bit line contact plugs BLC may be in contact with the lower surfaces of the bit lines BL, respectively.

In an embodiment of the present inventive concept, an opening OPH may be formed in the shield plate SHP connecting the upper surfaces of the shield lines SHL, as shown in FIG. 16F. Here, the upper surfaces of the bit lines BL may be exposed by the opening OPH. In this case, the bit line contact plugs BLC may penetrate the shield plate SHP to be in contact with the upper surfaces of the bit lines BL. The opening OPH of the shield plate SHP exposing the upper surfaces of the shield lines SHL may be formed as one as shown in FIG. 17E and extend in the first direction D1, or may be formed as two as shown in FIG. 17F to expose the upper surfaces of both ends of the bit lines BL, or may be formed as three or more as shown in FIG. 17G and arranged in a row in the fourth direction D4. For example, the shield plate SHP may include at least one opening OPH exposing a portion of the bit lines BL, and bit line contact plugs BLC may be connected to the bit lines BL through the at least one opening OPH.

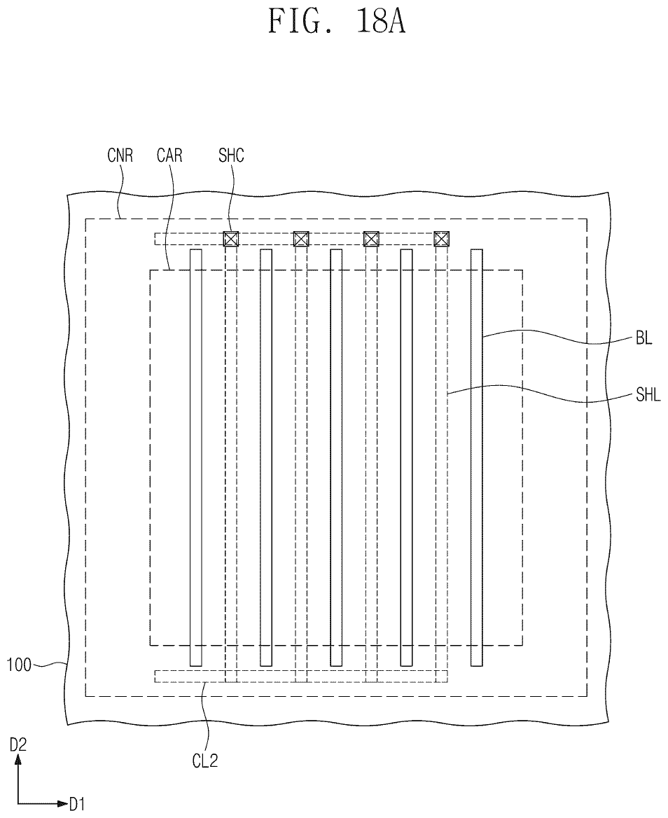

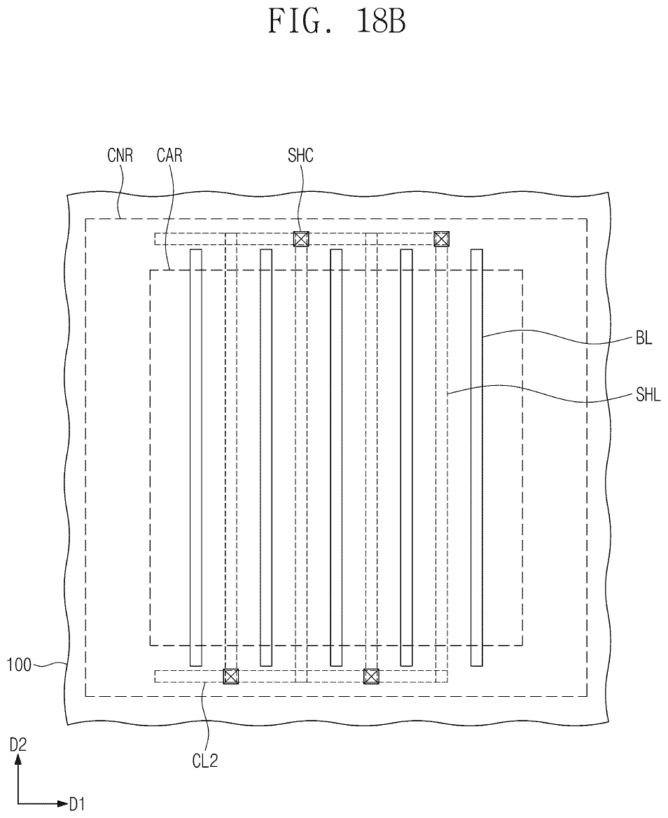

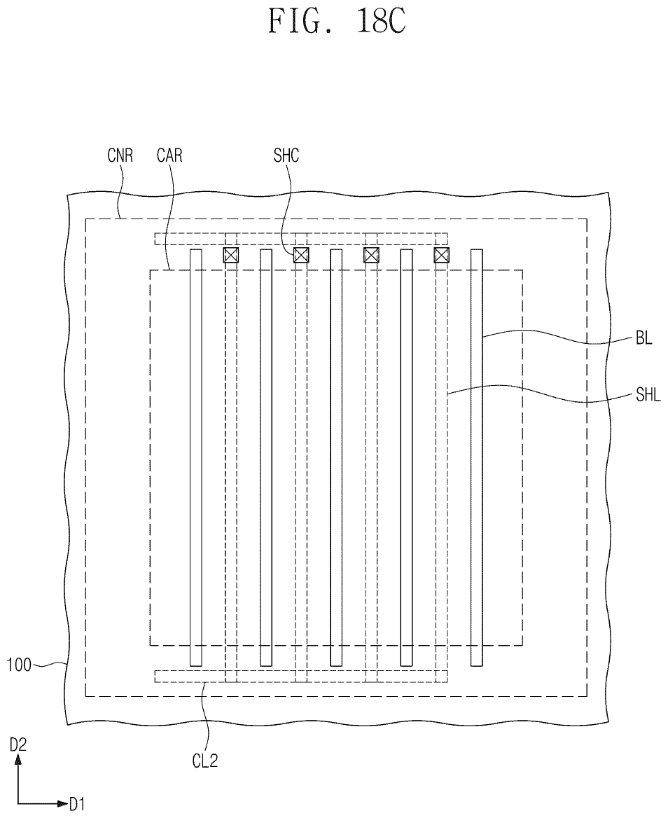

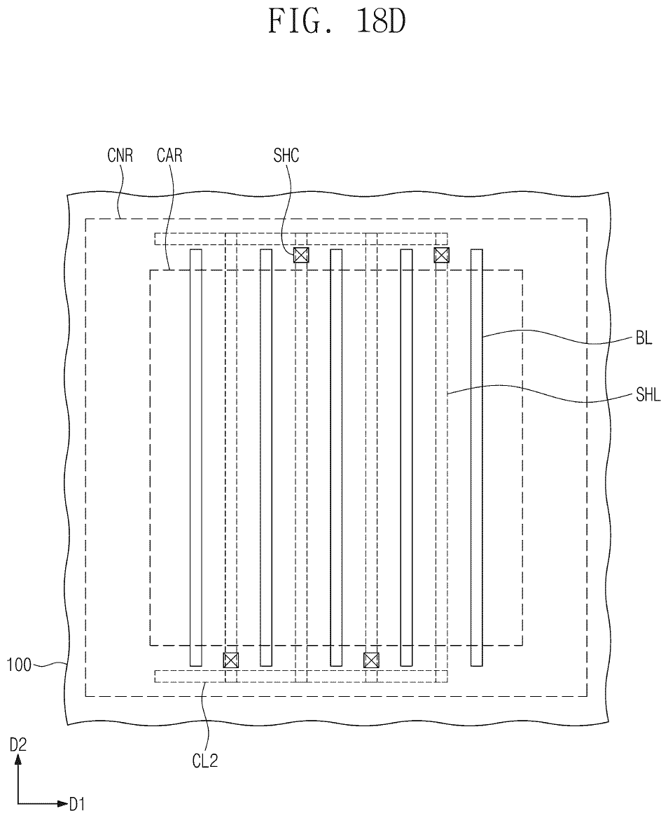

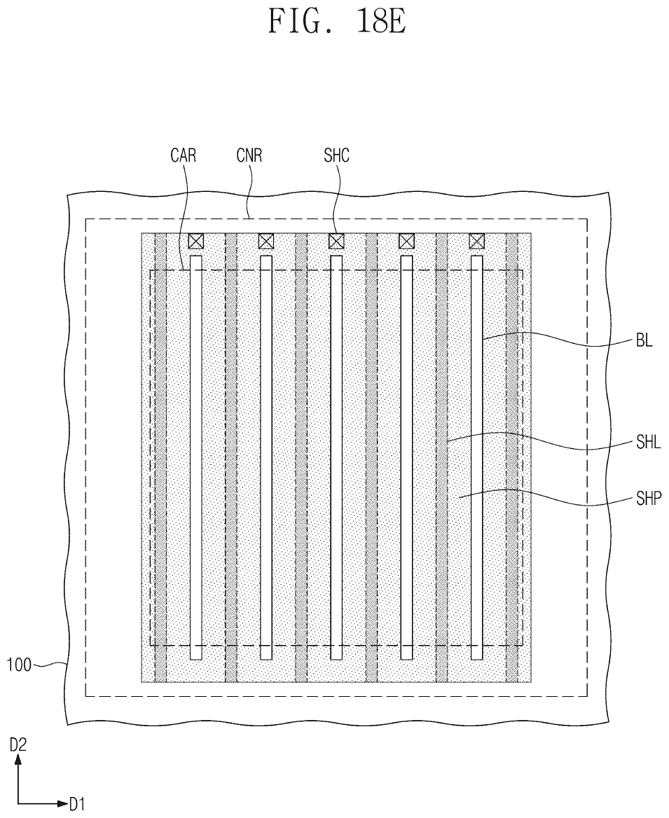

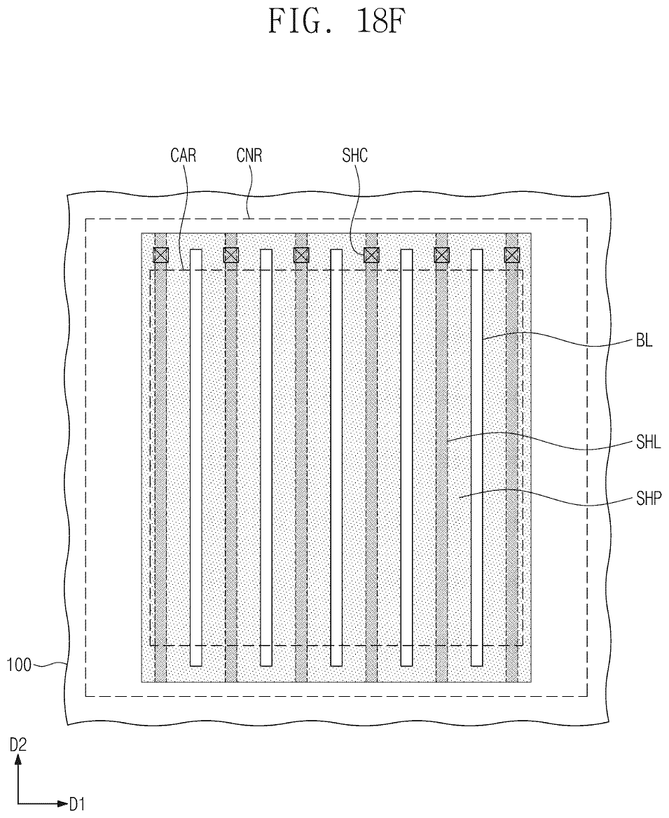

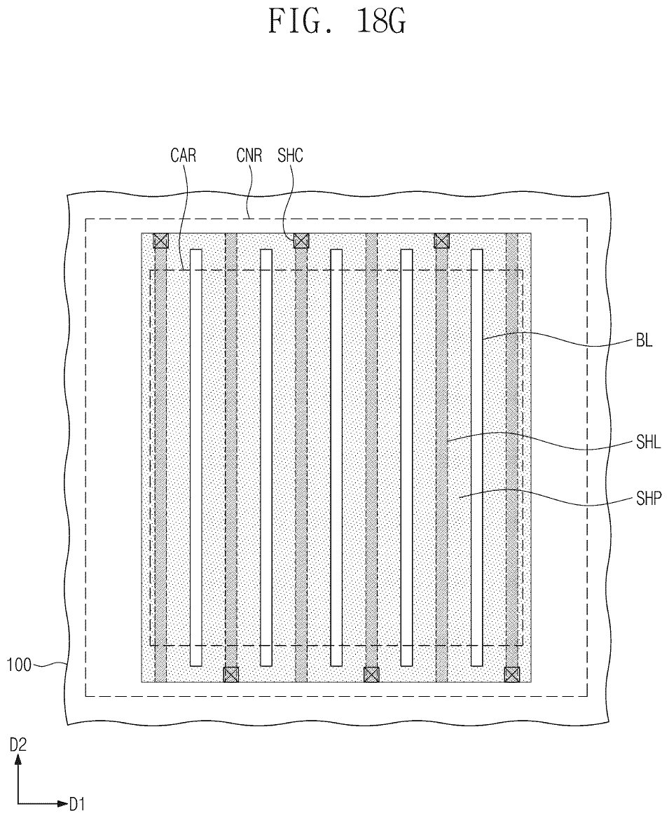

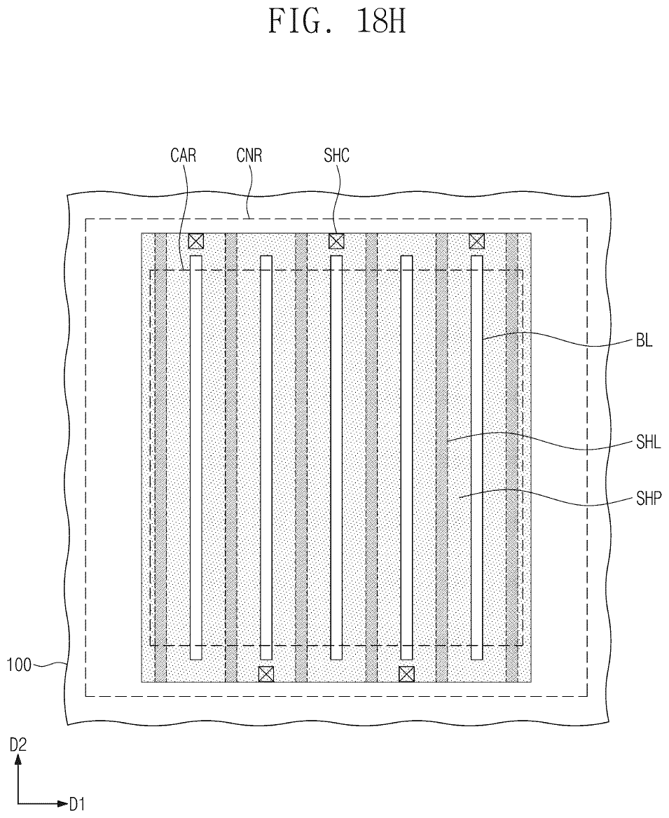

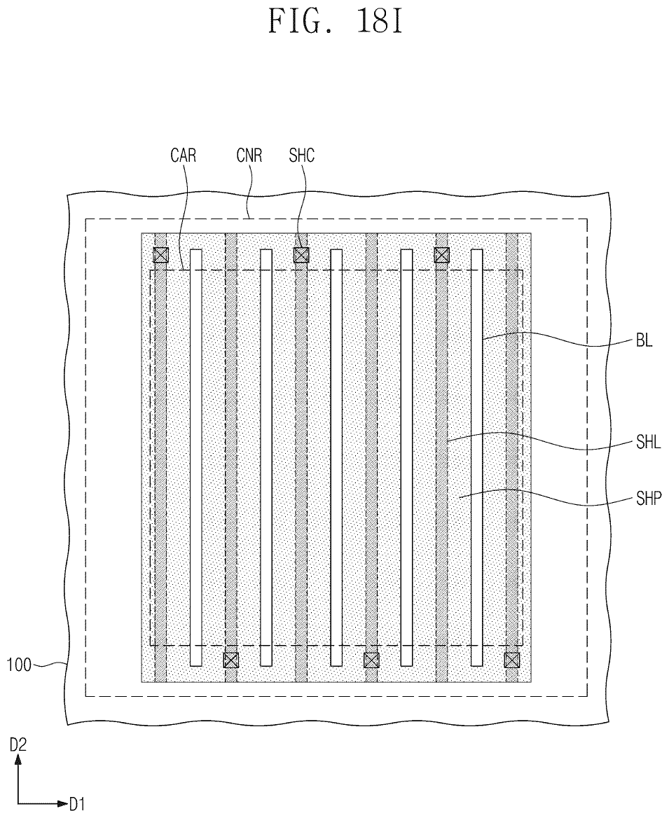

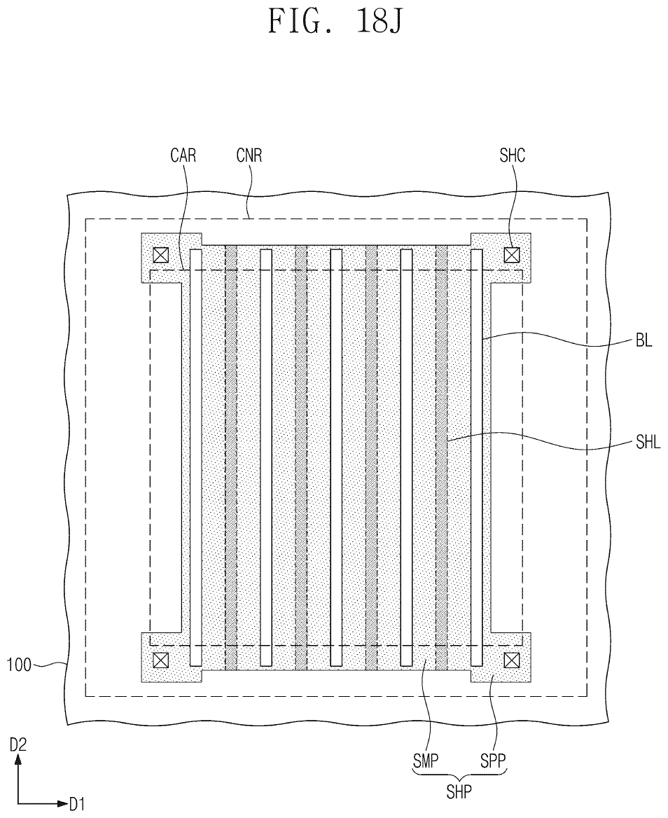

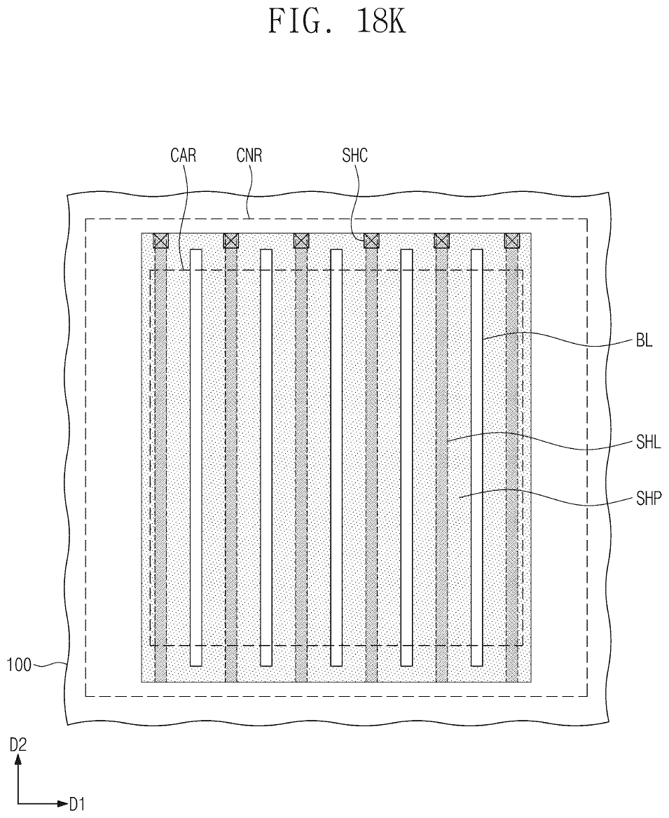

FIGS. 18A to 18L are plan views each showing an arrangement of shield line contact plugs according to an embodiment of the present inventive concept.

Referring to FIG. 18A, the shield lines SHL may extend across the cell array region CAR and into the connection region CNR. Both ends of the shield lines SHL may be connected to two second connection lines CL2. The second connection lines CL2 may be disposed on the connection region CNR. The shield line contact plugs SHC may be disposed at the intersection of the shield lines SHL and one second connection line CL2, respectively. The shield line contact plugs SHC may be arranged in a row in the first direction D1.

Alternatively, referring to FIG. 18B, the shield line contact plugs SHC may be alternately arranged on the two second connection lines CL2 and may be arranged in a zigzag manner. The shield line contact plugs SHC may be disposed at the intersections of the odd shield lines SHL and one second connection line CL2, and may be disposed at the intersections of the even shield lines SHL and the other second connection line CL2.

Alternatively, referring to FIG. 18C, the shield line contact plugs SHC may be in contact with each of the shield lines SHL and may be disposed between ends of the bit lines BL. The shield line contact plugs SHC may be arranged in a row in the first direction D1.

Alternatively, referring to FIG. 18D, the shield line contact plugs SHC may be in alternate contact with both ends of the shield lines SHL and may be disposed between ends of the bit lines BL. Here, the ends of the shield lines SHL do not overlap the second connection lines CL2. The shield line contact plugs SHC may be arranged in a zigzag manner in the first direction D1. The shield line contact plugs SHC may be in contact with one ends of the odd shield lines SHL and may be in contact with other ends of the even shield lines SHL.

Referring to FIG. 18E, the shield plate SHP may be disposed not only in the cell array region CAR but also in the connection region CNR. A length of the shield lines SHL in the second direction D2 may be longer than a length of the bit lines BL in the second direction D2. Shield line contact plugs SHC may be in contact with the shield plate SHP between one ends of the shield lines SHL. The shield line contact plugs SHC may be arranged in a row in the first direction D1. Each of the shield line contact plugs SHC may be arranged side by side with each of the bit lines BL in the second direction D2.

Alternatively, referring to FIG. 18F, the shield line contact plugs SHC may be in contact with the shield lines SHL, and may be spaced apart from outermost ends of the shield lines SHL. The shield line contact plugs SHC may be arranged in a row in the first direction D1 and may be disposed between ends of the bit lines BL.

Alternatively, referring to FIG. 18G, the shield line contact plugs SHC may be in alternate contact with the ends of the shield lines SHL, and may be spaced apart from the ends of the bit lines BL in the second direction D2. The shield line contact plugs SHC may be arranged in a zigzag manner. For example, the shield line contact plugs SHC may be in contact with one ends of the odd shield lines SHL, and may be in contact with other ends of the even shield lines SHL.

Alternatively, referring to FIG. 18H, the shield line contact plugs SHC may be in contact with the shield plate SHP between the shield lines SHL and may be arranged in a zigzag manner. The shield line contact plugs SHC may be arranged to be adjacent to one ends of the odd bit lines BL, and may be arranged to be adjacent to other ends of the even bit lines BL.

Alternatively, referring to FIG. 18I, the shield line contact plugs SHC may be in alternate contact with both ends of the shield lines SHL and may be disposed between ends of the bit lines BL. The shield line contact plugs SHC may be arranged in a zigzag manner in the first direction D1. For example, the shield line contact plugs SHC may be in contact with one ends of the odd shield lines SHL between one ends of the bit lines BL, and may be in contact with other ends of the even shield lines SHL between other ends of the bit lines BL. If the shield line SHL is only adjacent to one bit line BL, the shield line contact plug SHC is located adjacent to the one end or the other end of the adjacent bit line BL.

Alternatively, referring to FIG. 18J, the shield plate SHP includes a shield main portion SMP that connects the shield lines SHL and overlaps the bit lines BL, and shield protrusions SPP protruding out from four corners of the shield main portion SMP. The shield line contact plugs SHC are in contact with the shield protrusions SPP, respectively. For example, four shield line contact plugs SHC may be respectively in contact with four shield protrusions SPP, respectively.

Alternatively, referring to FIG. 18K, the shield line contact plugs SHC may be in contact with the ends of the shield lines SHL. The shield line contact plugs SHC are arranged in a row in the first direction D1 and do not overlap the bit lines BL in the first direction D1.

Alternatively, referring to FIG. 18L, shield line contact plugs SHC may be disposed on the outermost shield lines SHL connected to the shield plate SHP. For example, three shield line contact plugs SHC may be disposed on each of the two outmost shield lines SHL connected to the shield plate SHP, but the present inventive concept is not limited thereto. The arrangement of shield line contact plugs SHC is not limited to those illustrated in FIGS. 18A to 18L, and may be variously changed.

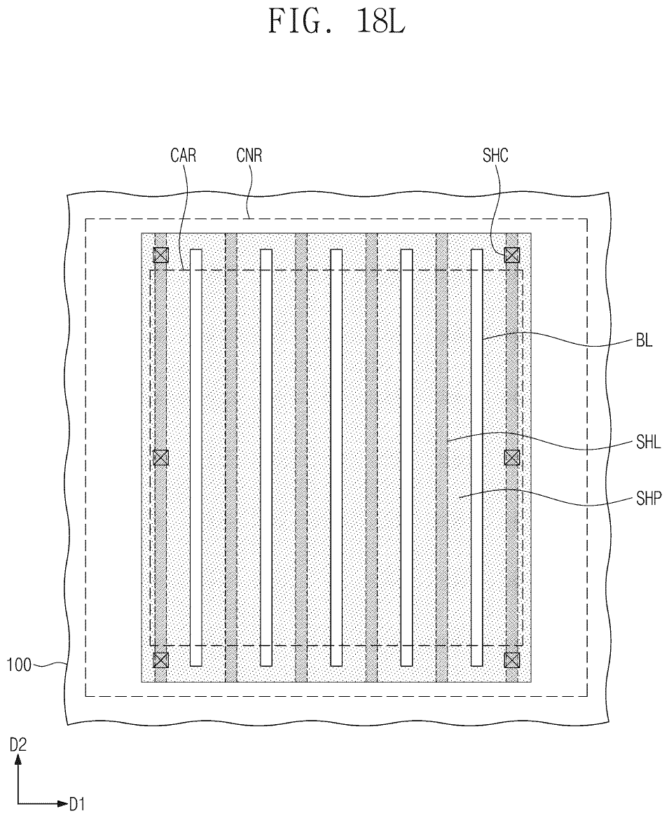

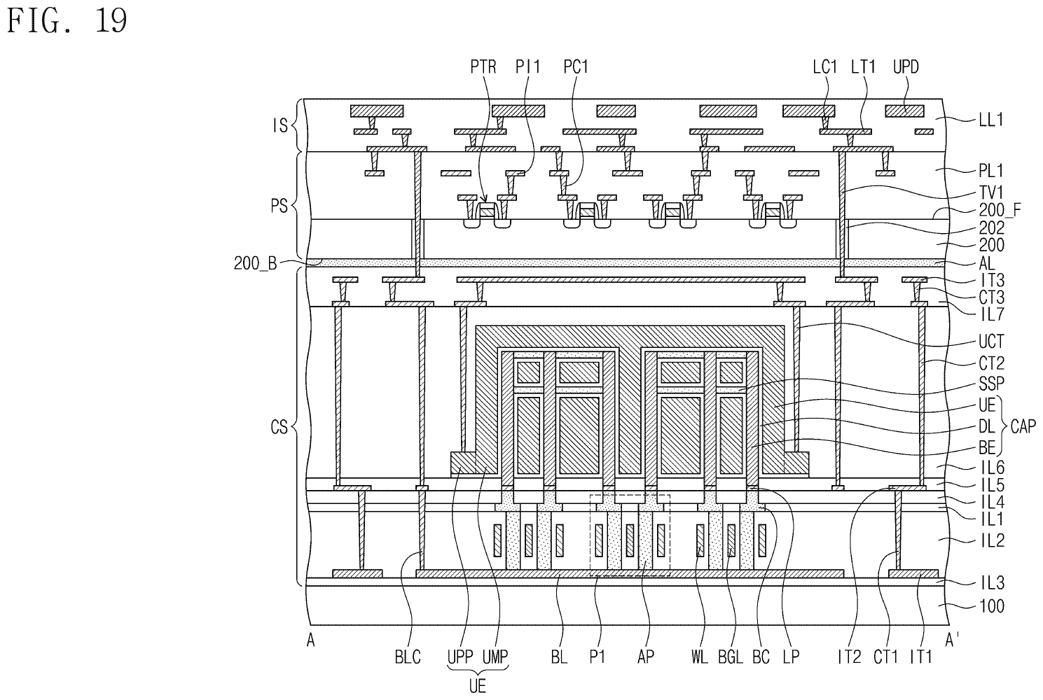

FIG. 19 is a cross-sectional view taken along line A-A′ of FIG. 2 according to an embodiment of the present inventive concept.

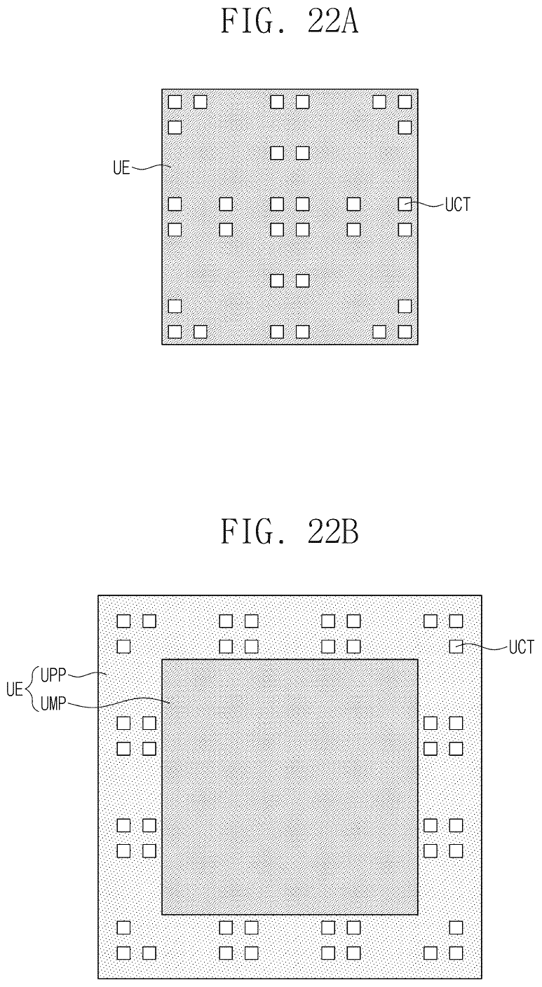

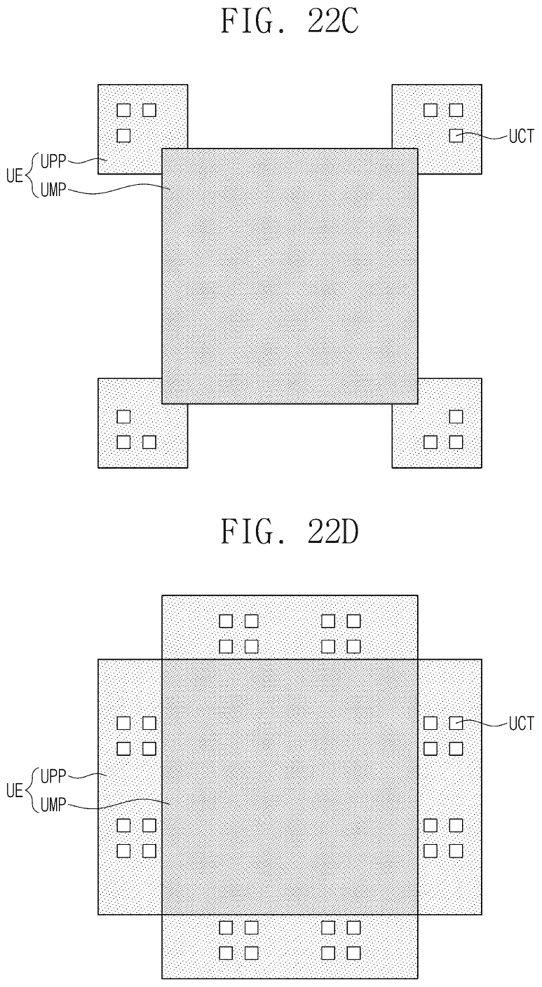

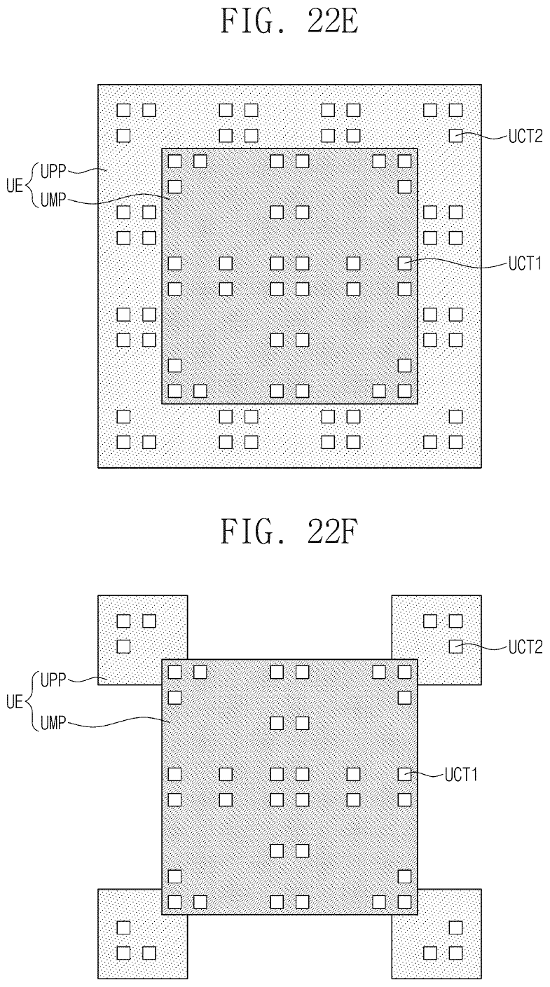

Referring to FIG. 19, in the semiconductor memory device according to the present embodiment, a shape of the upper electrode UE is different from that of FIG. 3. The upper electrode UE may include an electrode main portion UMP that covers upper and side surfaces of the lower electrodes BE, and an electrode protrusion UPP that protrudes laterally from a sidewall of the electrode main portion UMP. In a plan view, the electrode protrusion UPP may be connected to four corners of the electrode main portion UMP and may protrude diagonally (see FIG. 22C), or may protrude from sides (see FIG. 22D) or from both sides and corners (see FIG. 22B) of the electrode main portion UMP. The upper electrode UE may have a hat-like shape. The electrode main portion UMP may overlap the lower electrodes BE and have a rectangular plane. The electrode protrusion UPP has a thinner thickness than that of the electrode main portion UMP. The electrode protrusion UPP covers the fifth cell insulating layer IL5. In FIG. 19, the upper electrode contact plugs UCT may be in contact with an upper surface of the electrode protrusion UPP. Other structures may be the same as/similar to FIG. 3. The structure of the semiconductor memory device of FIG. 19 facilitates interconnection routing between the cell structure CS and the peripheral structure PS and high integration may be realized.

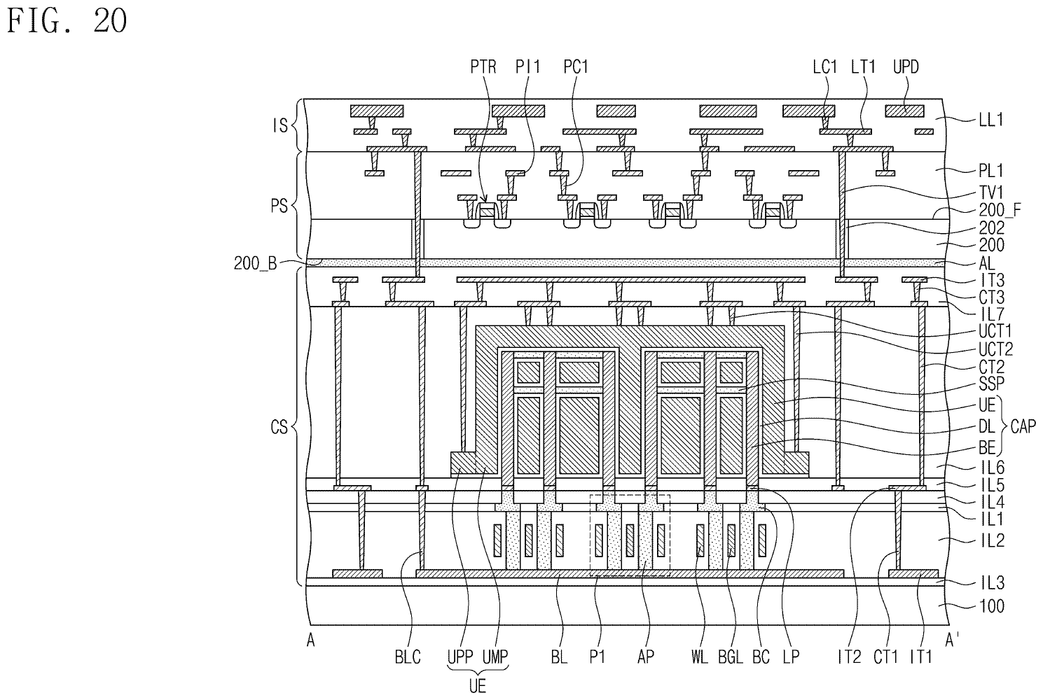

FIG. 20 is a cross-sectional view taken along line A-A′ of FIG. 2 according to an embodiment of the present inventive concept.

Referring to FIG. 20, the semiconductor memory device according to the present embodiment may include first and second upper electrode contact plugs UCT1 and UCT2. The first upper electrode contact plugs UCT1 may be in contact with upper surfaces of the electrode main portion UMP of the upper electrode UE. The second upper electrode contact plugs UCT2 may be in contact with upper surfaces of the electrode protrusion UPP of the upper electrode UE. Other structures may be the same as/similar to FIG. 19. The structure of the semiconductor memory device of FIG. 20 facilitates interconnection routing between the cell structure CS and the peripheral structure PS and high integration may be realized.

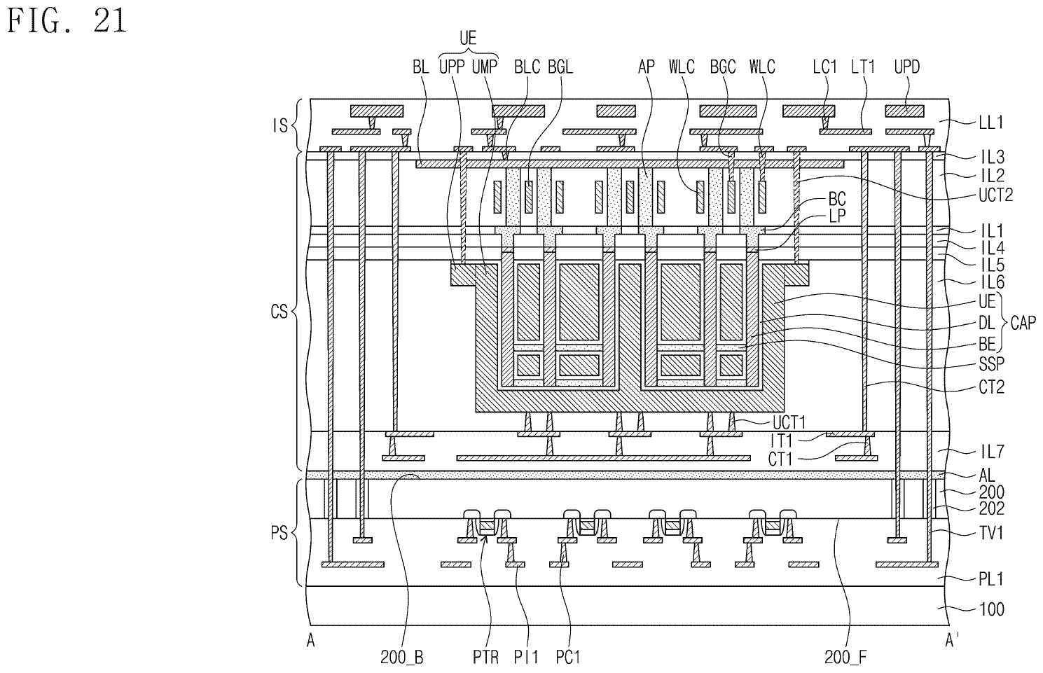

FIG. 21 is a cross-sectional view taken along line A-A′ of FIG. 2 according to an embodiment of the present inventive concept.

Referring to FIG. 21, in the semiconductor memory device according to the present embodiment, a shape of the upper electrode UE is different from that of FIG. 8. The upper electrode UE may include an electrode main portion UMP that covers lower surfaces and side surfaces of the lower electrodes BE, and an electrode protrusion UPP that protrudes laterally from a sidewall of the electrode main portion UMP. The upper electrode UE may have the shape of an inverted hat. The electrode protrusion UPP has a thinner thickness than that of the electrode main portion UMP. The electrode protrusion UPP covers a lower surface of the fifth cell insulating layer IL5.

The semiconductor memory device according to the present embodiment may include first and second upper electrode contact plugs UCT1 and UCT2. The first upper electrode contact plugs UCT1 may partially penetrate the sixth cell insulating layer IL6 to be in contact with a lower surface of the electrode main portion UMP of the upper electrode UE. The second upper electrode contact plugs UCT2 may penetrate the third, second, first, fourth, and fifth cell insulating layers IL3, IL2, IL1, IL4, and IL5 to be in contact with an upper surface of the electrode protrusion UPP of the upper electrode UE. The second upper electrode contact plugs UCT2 may also penetrate the dielectric layer DL to be in contact with an upper surface of the electrode protrusion UPP of the upper electrode UE. Other structures may be the same as/similar to FIG. 8. The structure of the semiconductor memory device of FIG. 21 facilitates interconnection routing between the cell structure CS and the peripheral structure PS and high integration may be realized.

FIGS. 22A to 22G are plan views each showing an arrangement of an upper electrode and upper electrode contact plugs according to an embodiment of the present inventive concept.

Referring to FIG. 22A, the upper electrode UE according to an embodiment of the present inventive concept has a square shape when viewed from above compared to the upper electrode UE of FIG. 3. The upper electrode contact plugs UCT may be arranged on the upper electrode UE in pairs of two or three.

Referring to FIGS. 22B to 22D, the upper electrode UE according to the present example may include an electrode main portion UMP and an electrode protrusion UPP, as shown in FIG. 19. The electrode protrusion UPP may surround the electrode main portion UMP as shown in FIG. 22B when viewed in a plan view. Alternatively, the electrode protrusion UPP may protrude diagonally from the four corners of the electrode main portion UMP as shown in FIG. 22C when viewed in a plan view. Alternatively, the electrode protrusion UPP may protrude out from the four sidewalls of the electrode main portion UMP as shown in FIG. 22D when viewed in a plan view. The upper electrode contact plugs UCT may be arranged in pairs of 3 to 4 only on the upper or lower surface of the electrode protrusion UPP.

Referring to FIGS. 22E to 22G, the upper electrode UE according to an embodiment of the present inventive concept may include an electrode main portion UMP and an electrode protrusion UPP, as shown in FIG. 20 or 21. The electrode protrusion UPP may surround the electrode main portion UMP as shown in FIG. 22E when viewed in a plan view. Alternatively, the electrode protrusion UPP may protrude diagonally from the four corners of the electrode main portion UMP as shown in FIG. 22F when viewed in a plan view. Alternatively, the electrode protrusion UPP may protrude out from the four sidewalls of the electrode main portion UMP as shown in FIG. 22G when viewed in a plan view. The first upper electrode contact plugs UCT1 may be in contact with the lower or upper surface of the electrode main portion UMP of the upper electrode UE. The second upper electrode contact plugs UCT2 may be in contact with the upper or lower surface of the electrode protrusion UPP of the upper electrode UE. In FIGS. 22B to 22D, no upper electrode contact plugs UCT are formed to be in contact with the lower or upper surface of the electrode main portion UMP of the upper electrode UE, while in FIGS. 22E to 22G, the first upper electrode contact plugs UCT1 may be in contact with the lower or upper surface of the electrode main portion UMP of the upper electrode UE. In FIG. 19, no upper electrode contact plugs UCT are formed to be in contact with the upper surface of the electrode main portion UMP of the upper electrode UE, while in FIGS. 20 and 21, the first upper electrode contact plugs UCT1 may be in contact with the lower or upper surface of the electrode main portion UMP of the upper electrode UE.

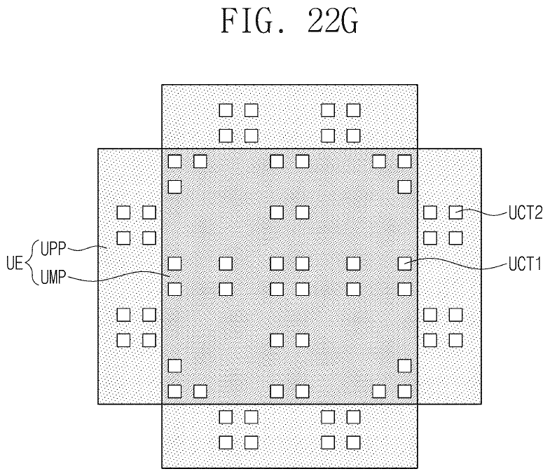

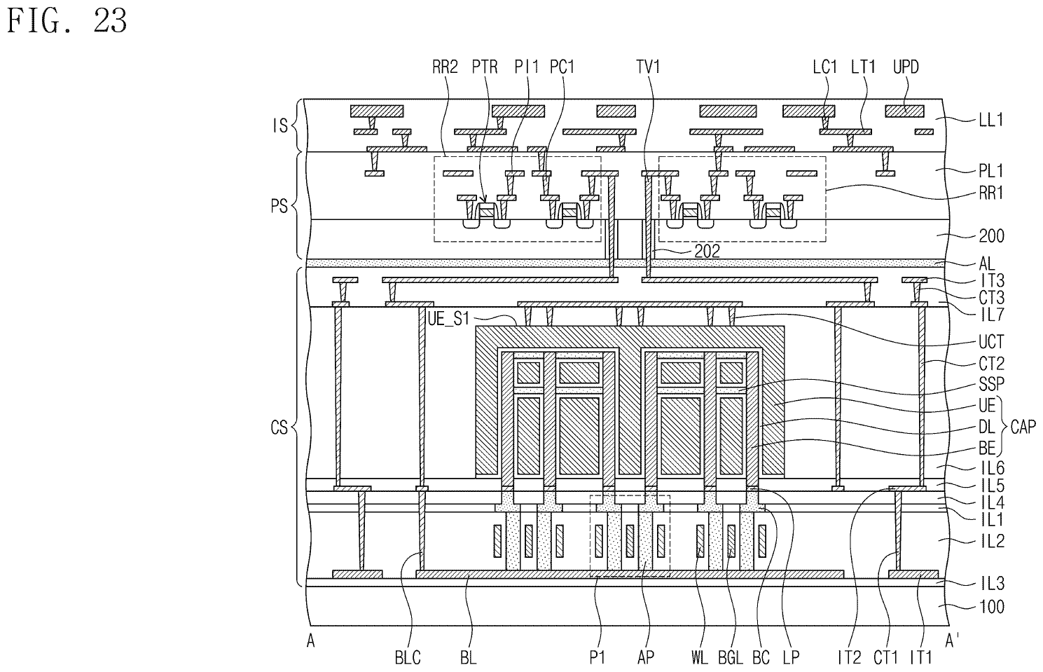

FIG. 23 is a cross-sectional view taken along line A-A′ of FIG. 2 according to an embodiment of the present inventive concept.

Referring to FIG. 23, in the semiconductor memory device according to the present embodiment, the peripheral structure PS includes a first region RR1 and a second region RR2. The first region RR1 and the second region RR2 may independently be where circuits for one of the sub-word line driver 22, sense amplifier 24, row decoder 32, column decoder 34, and control logic 36 as described in FIG. 1A are disposed. The first region RR1 and the second region RR2 may vertically overlap the upper electrode UE. The through vias TV1 may be respectively connected to the first region RR1 and the second region RR2 and may vertically overlap the upper electrode UE. Other structures may be the same as/similar to FIG. 3. The structure of the semiconductor memory device of FIG. 23 facilitates interconnection routing between the cell structure CS and the peripheral structure PS and high integration may be realized.

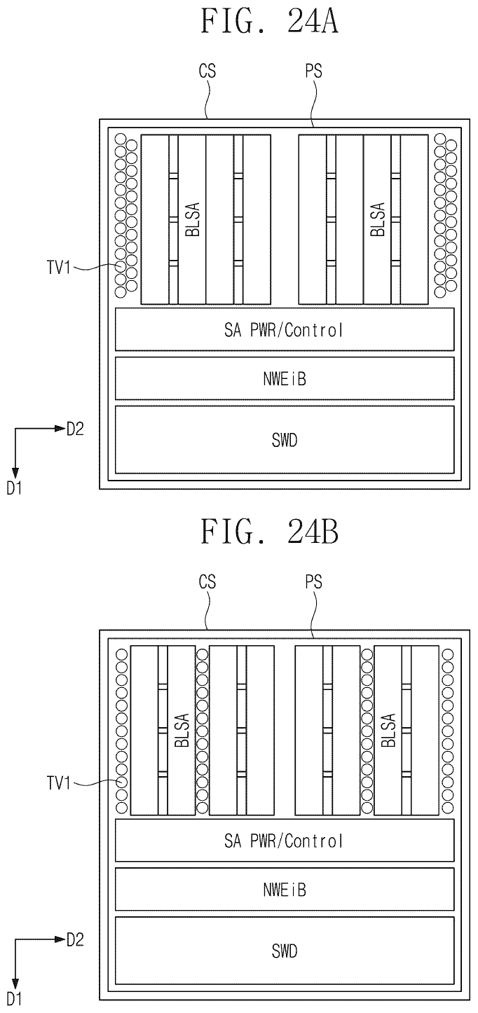

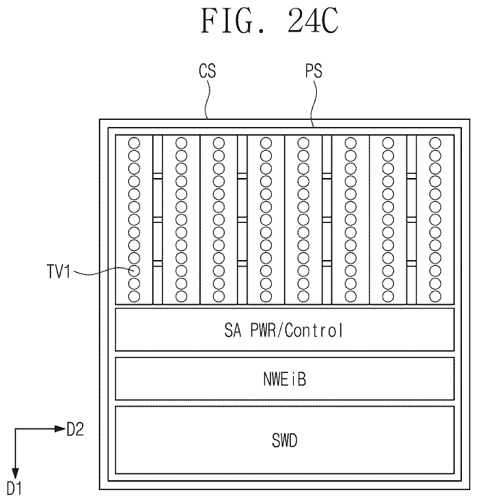

FIGS. 24A to 24C are plan views of semiconductor memory devices each according to an embodiment of the present inventive concept.

Referring to FIG. 24A, the peripheral structure PS may include bit line sense amplifier regions BLSA, sense amplifier power/control region SA PWR/Control, word line driver enable signal region NWEiB, and sub word line region SWD. The through vias TV1 may be disposed adjacent to sides of the outermost ones of the bit line sense amplifier regions BLSA.

Alternatively, referring to FIG. 24B, the through vias TV1 may be disposed between the bit line sense amplifier regions BLSA.

Alternatively, referring to FIG. 24C, the through vias TV1 may be disposed within each bit line sense amplifier region BLSA.

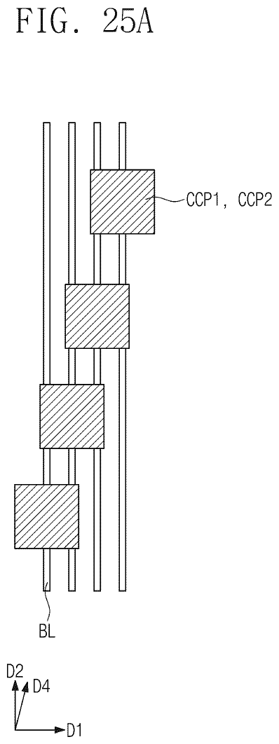

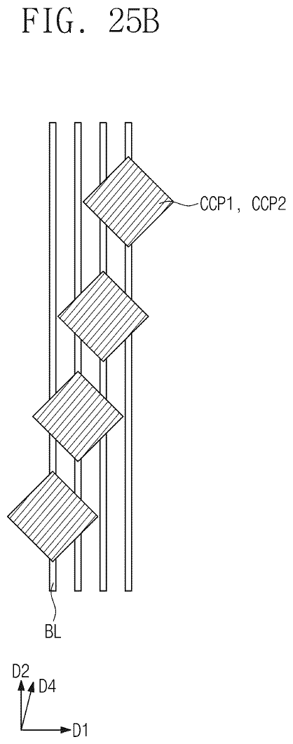

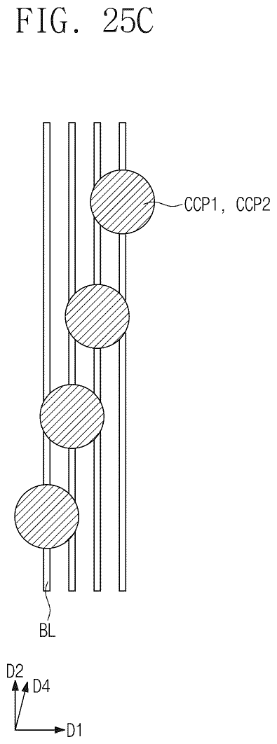

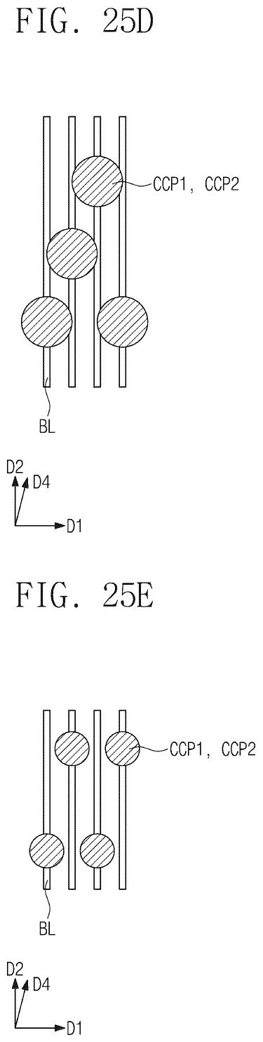

FIGS. 25A to 25E are plan views each showing an arrangement and shape of cell connection pads and peripheral connection pads according to an embodiment of the present inventive concept.

Referring to FIGS. 25A to 25E, the cell connection pads CCP1 and the peripheral connection pads CCP2 may each overlap the bit lines BL and may have widths wider than that of the bit lines BL. Each of the cell connection pads CCP1 and the peripheral connection pads CCP2 may be square as shown in FIG. 25A, diamond shaped as shown in FIG. 25B, or circular as shown in FIGS. 25C to 25E. The cell connection pads CCP1 and peripheral connection pads CCP2 may be arranged in a row in the fourth direction D4 that simultaneously intersects the first direction D1 and the second direction D2, as shown in FIGS. 25A to 25C. Alternatively, the cell connection pads CCP1 and the peripheral connection pads CCP2 may be arranged such that first to third ones are arranged in a row in the fourth direction D4 and a fourth one is spaced apart from the first one in the first direction D1 as shown in FIG. 25D. Alternatively, as shown in FIG. 25E, the cell connection pads CCP1 and peripheral connection pads CCP2 may be arranged in a zigzag manner in the first direction D1.

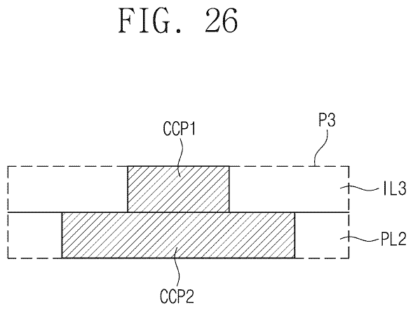

FIG. 26 is an enlarged view of ‘P2’ of FIG. 6 according to an embodiment of the present inventive concept.

The cell connection pads CCP1 and the peripheral connection pads CCP2 may have the same width as shown in FIG. 6. Alternatively, referring to FIG. 26, a width of the cell connection pads CCP1 may be smaller than a width of the peripheral connection pads CCP2.

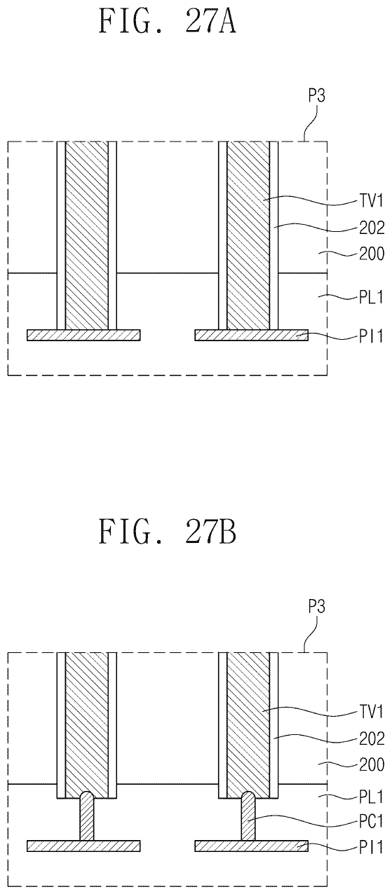

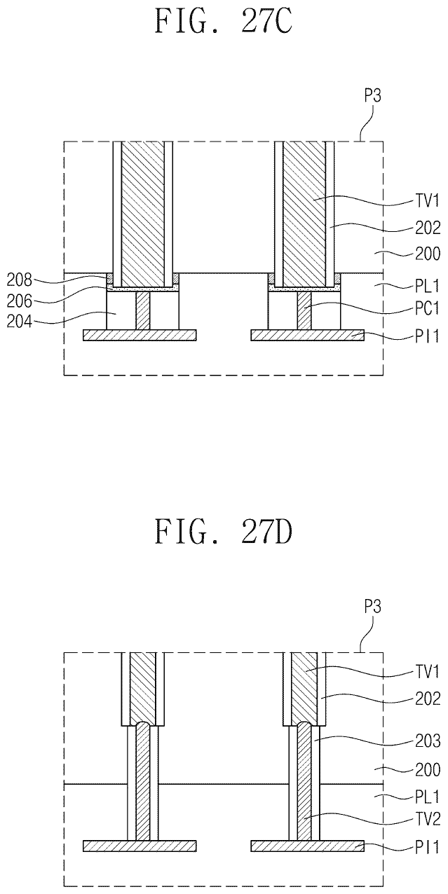

FIGS. 27A to 27D are enlarged views of ‘P3’ in FIG. 6 each according to an embodiment of the present inventive concept.

Referring to FIG. 27A, the first through via TV1 may partially penetrate the peripheral substrate 200 and the first peripheral insulating layer PL1 to be in contact with the first peripheral interconnection PI1. A first via insulating layer 202 may be interposed between the first through via TV1 and the peripheral substrate 200 and between the through via TV1 and the first peripheral insulating layer PL1. The first through via TV1 may be electrically isolated from the surrounding peripheral substrate 200 by the first via insulating layer 202.

Alternatively, referring to FIG. 27B, the first through via TV1 is spaced apart from the first peripheral interconnection PI1, and the first peripheral contact plug PC1 may connect the first peripheral interconnection PI1 to the first through via TV1.

Alternatively, referring to FIG. 27C, the first conductive pattern 208 and the second conductive pattern 206 may be sequentially disposed on the lower surface of the peripheral substrate 200. The first conductive pattern 208 may be formed of polysilicon (p-Si). The second conductive pattern 206 may be formed of a metal such as tungsten (W) or titanium (Ti). The first through via TV1 penetrates the first conductive pattern 208 to be in contact with the second conductive pattern 206. The first peripheral contact plug PC1 may connect the first peripheral interconnection PI1 to the second conductive pattern 206. A second peripheral insulating layer 204 may be disposed between the first peripheral contact plug PC1 and the first peripheral insulating layer PL1. The second peripheral insulating layer 204 may be formed of a material different from the first peripheral insulating layer PL1. For example, the first peripheral insulating layer PL1 may be formed of silicon oxide (SiO₂), and the second peripheral insulating layer 204 may be formed of silicon nitride (Si₃N₄). The first conductive pattern 208, the second conductive pattern 206, and the second peripheral insulating layer 204 may function as an etch stop layer when forming the through-via hole for the first through via TV1. As a result, the first peripheral interconnection PI1 may be protected.

Alternatively, referring to FIG. 27D, the first through via TV1 and the first via insulating layer 202 may partially penetrate the peripheral substrate 200. The second through via TV2 and the second via insulating layer 203 penetrate a portion of the first peripheral insulating layer PL1 and another portion of the peripheral substrate 200. The first through via TV1 may be electrically isolated from the surrounding peripheral substrate 200 by the first via insulating layer 202, and the second through via TV2 may be electrically isolated from the surrounding peripheral substrate 200 by the second via insulating layer 203. The second through via TV2 connects the first peripheral interconnection PI1 to the first through via TV1. The second through via TV2 is in contact with the first through via TV1 and vertically overlaps the first through via TV1.

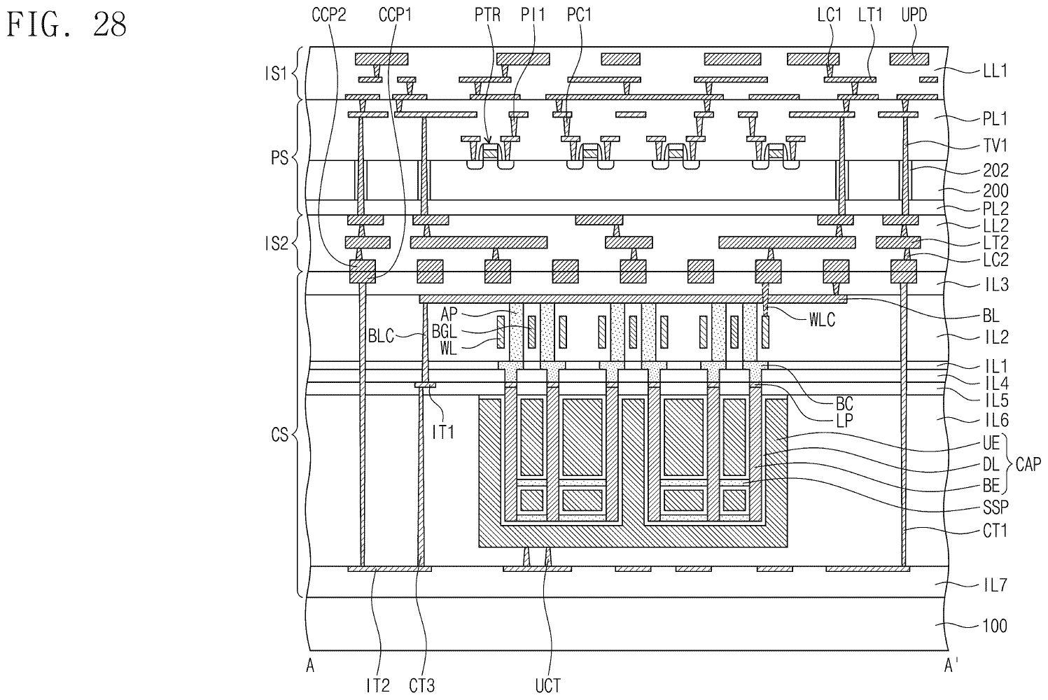

FIG. 28 is a cross-sectional view taken along line A-A′ of FIG. 2 according to an embodiment of the present inventive concept.

Referring to FIG. 28, in the semiconductor memory device according to the present embodiment, a cell structure CS, a second interconnection structure IS2, a peripheral structure PS, and a first interconnection structure IS1 are sequentially stacked on a support substrate 100. The cell structure CS and peripheral structure PS of FIG. 28 may be the same as/similar to the cell structure CS and peripheral structure PS of FIG. 13. The peripheral structure PS does not include the peripheral connection pads CCP2 of FIG. 13. For example, the peripheral connection pads CCP2 of FIG. 28 may not be formed in the peripheral structure PS.

The first interconnection structure IS1 may be identical/similar to the interconnection structure IS of FIG. 13. The first interconnection structure IS1 is disposed on the peripheral structure PS. The first interconnection structure IS1 may include a first interconnection insulating layer LL1 and multi-layered upper interconnections LT1, upper contact plugs LC1, and upper connection pads UPD.

The second interconnection structure IS2 may be disposed between the cell structure CS and the peripheral structure PS. The second interconnection structure IS2 is in contact with the second peripheral insulating layer PL2. The second interconnection structure IS2 may include a second interconnection insulating layer LL2 and multi-layered lower interconnections LT2, lower contact plugs LC2, and peripheral connection pads CCP2. The peripheral connection pads CCP2 of FIG. 28 are formed in the second interconnection structure IS2 not in the peripheral structure PS. The second interconnection structure IS2 may be a backside power delivery network (BSPDN) layer. Some of the lower interconnections LT2 may be interconnections for transmitting power, and other portions of the lower interconnections LT2 may be interconnections for transmitting signals. Some of the lower interconnections LT2 may be thicker than some of the upper interconnections LT1.

The peripheral connection pads CCP2 may be in contact with the cell connection pads CCP1 of the cell structure CS, respectively. An upper surface of the third cell insulating layer IL3 of the cell structure CS may be in contact with a lower surface of the second interconnection insulating layer LL2. In this case, the cell connection pads CCP1 and the peripheral connection pads CCP2 may be bonded to each other through a metal to metal bonding (e.g., copper (Cu) to copper (Cu) bonding), while the third cell insulating layer IL3 and the second interconnection insulating layer LL2 may be boded to each other through a dielectric to dielectric bonding (e.g., silicon oxide (SiO₂) to silicon oxide (SiO₂) bonding). The through vias TV1 partially penetrate the second peripheral insulating layer PL2, the peripheral substrate 200, and the first peripheral insulating layer PL1 to connect the lower interconnections LT2 of the second interconnection structure IS2 to the peripheral interconnections PI1. The through via TV1 may be electrically isolated from the surrounding peripheral substrate 200 by the via insulating layer 202. Other structures may be the same as/similar to FIG. 13. The structure of the semiconductor memory device of FIG. 28 facilitates interconnection routing between the cell structure CS and the peripheral structure PS and high integration may be realized.

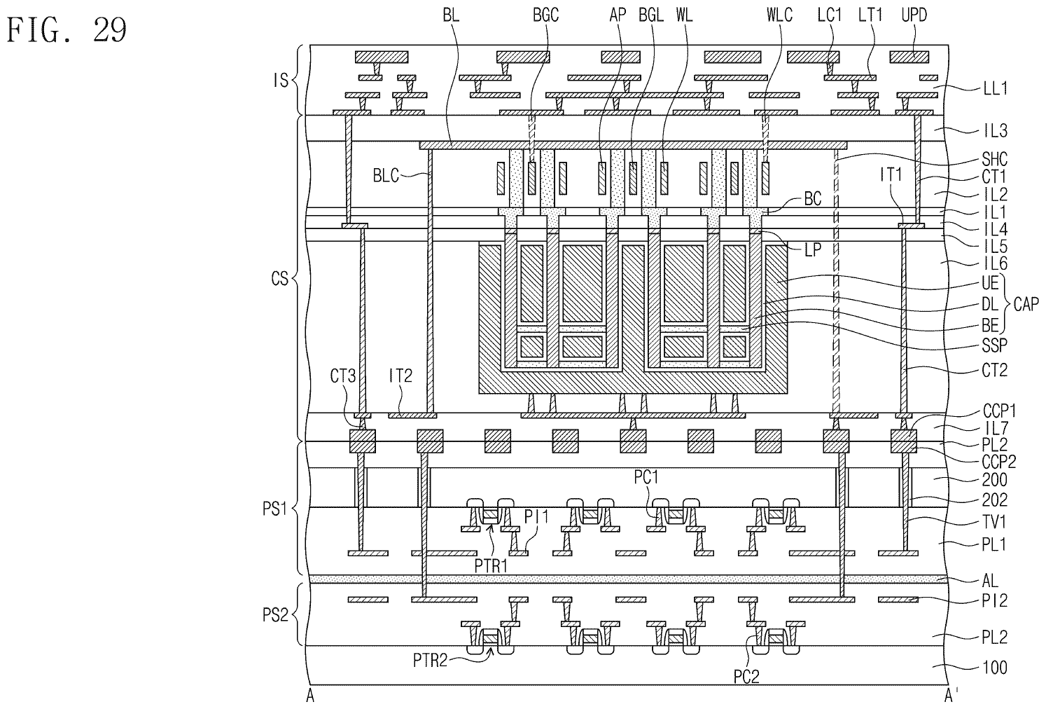

FIG. 29 is a cross-sectional view taken along line A-A′ of FIG. 2 according to an embodiment of the present inventive concept.

Referring to FIG. 29, in the semiconductor memory device according to the present embodiment, a second peripheral structure PS2, an interface layer AL, a first peripheral structure PS1, a cell structure CS, and interconnection structure IS are sequentially stacked on a support substrate 100. The cell structure CS and the interconnection structure IS may be the same as those described with reference to FIG. 11.

The first peripheral structure PS1 may be identical/similar to the peripheral structure PS of FIG. 11. A front surface 200_F of the peripheral substrate 200 of the first peripheral structure PS1 faces the support substrate 100. A second peripheral insulating layer PL2 is disposed on a back surface 200_B of the peripheral substrate 200. First peripheral transistors PTR1, first peripheral interconnections PI1, first peripheral contact plugs PC1, and first peripheral insulating layer PL1 are disposed on the front surface 200_F of the peripheral substrate 200.

The second peripheral structure PS2 includes second peripheral transistors PTR2, second peripheral interconnections PI2, second peripheral interconnections PI2, and second peripheral contact plugs PC2, a second peripheral insulating layer PL2 on the support substrate 100. An interface layer AL is interposed between the second peripheral insulating layer PL2 of the second peripheral structure PS2 and the first peripheral insulating layer PL1 of the first peripheral structure PS1. The second peripheral insulating layer PL2 of the second peripheral structure PS2 and the first peripheral insulating layer PL1 of the first peripheral structure PS1 may include the same material, but the present inventive concept is not limited thereto. The second peripheral insulating layer PL2 of the second peripheral structure PS2 and the second peripheral insulating layer PL2 of the first peripheral structure PS1 may include the same material, but the present inventive concept is not limited thereto. One of the through vias TV1 may penetrate the first peripheral structure PS1 and the interface layer AL to connect some of the second peripheral interconnections PI2 to the peripheral connection pads CCP2. Alternatively, the second peripheral structure PS2 may include a second peripheral substrate. The second peripheral transistors PTR2 may be disposed on the front surface of the second peripheral substrate, and the second peripheral insulating layer PL2 of the second peripheral structure PS2 may cover the front surface of the second peripheral substrate. A lower surface of the first peripheral insulating layer PL1 of the first peripheral structure PS1 may face an upper surface of the second peripheral insulating layer PL2 of the second peripheral structure PS2. In addition, the second peripheral structure PS2 described above for FIG. 29 may also be formed under the peripheral structure PS of FIG. 6 to have two peripheral structures PS (e.g., PS1 and PS2).

The first peripheral structure PS1 may be a core region, and the second peripheral structure PS2 may be a peripheral circuit region. Sub-word line driver circuits and bit line sense amplifier circuits may be disposed in the first peripheral structure PS1. Row decoder circuits, column decoder circuits, and interface regions of input/output circuits may be disposed in the second peripheral structure PS2. In the present embodiment, the peripheral structure PS may be divided into two, and thus, a horizontal size of the semiconductor memory device may be reduced. The structure of the semiconductor memory device of FIG. 29 facilitates interconnection routing between the cell structure CS and the peripheral structure PS and high integration may be realized.

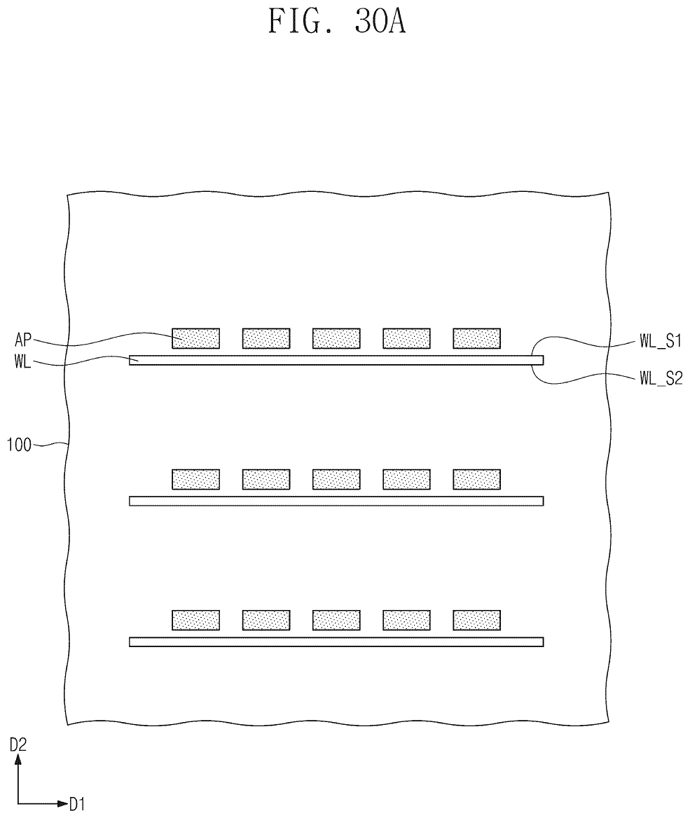

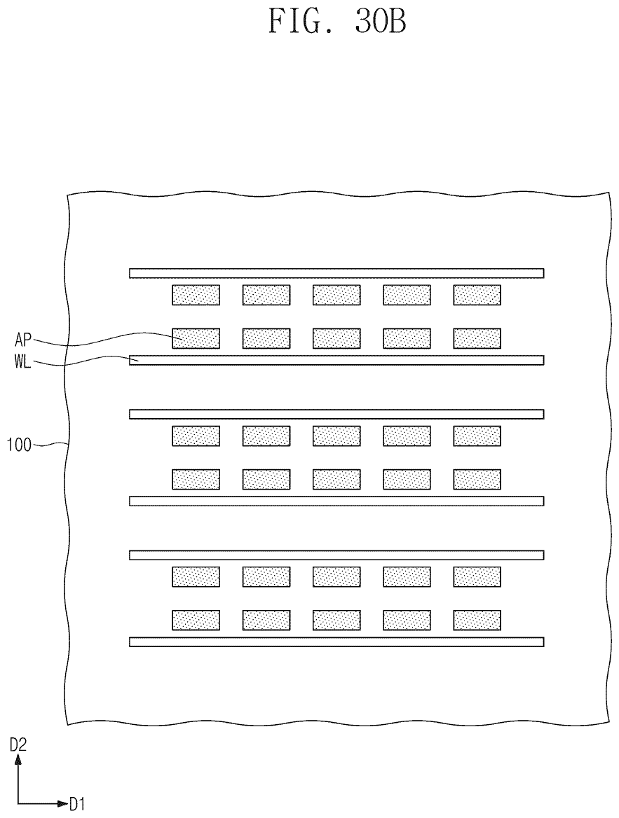

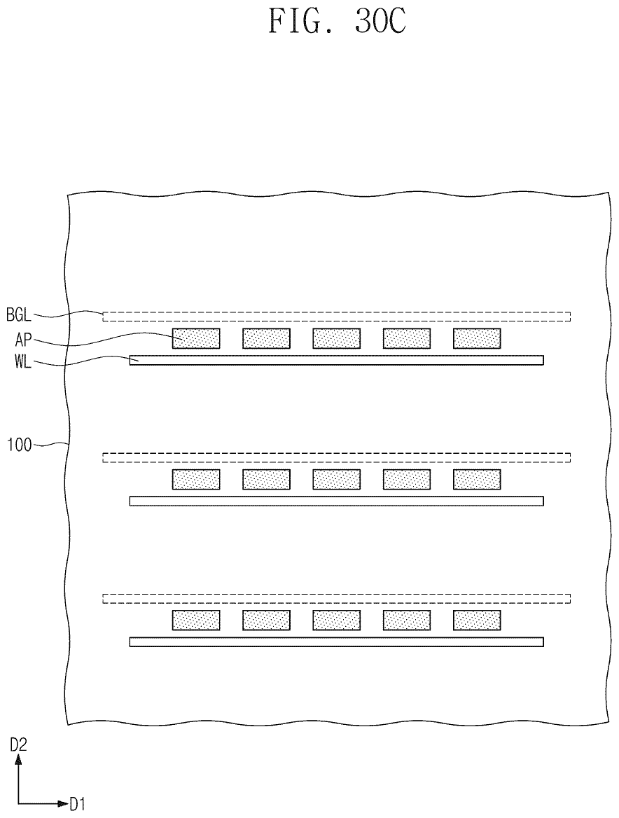

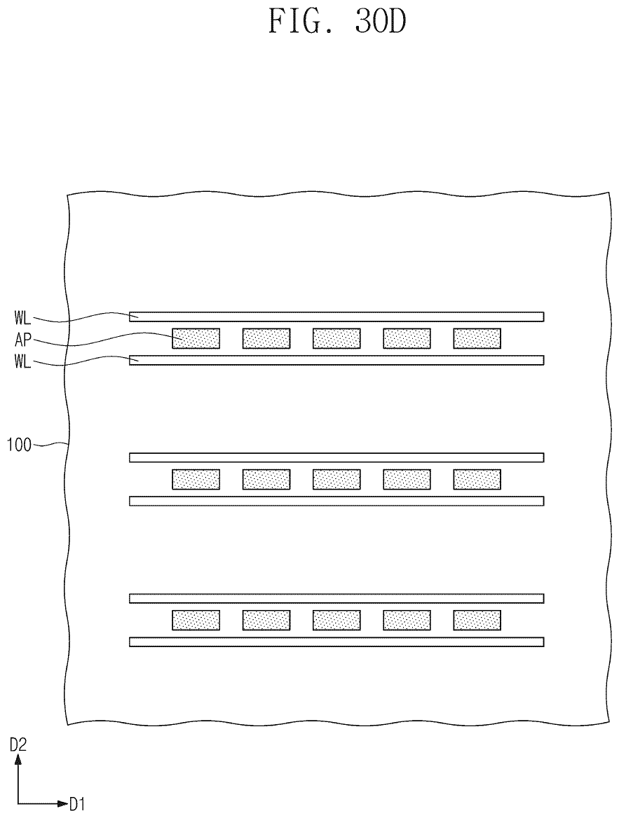

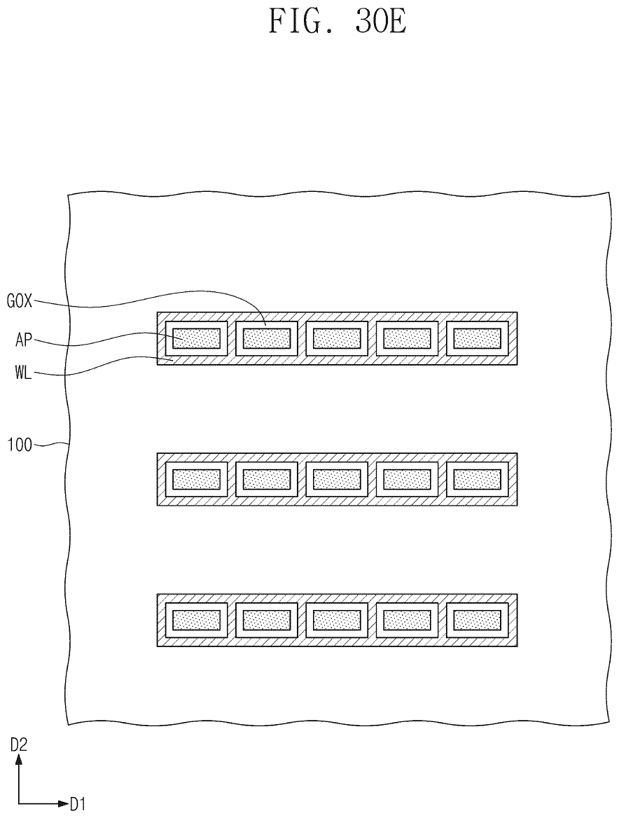

FIGS. 30A to 30E are plan views each showing an arrangement and structure of word lines and active patterns according to an embodiment of the present inventive concept.

Referring to FIG. 30A, each of the word lines WL may have a first sidewall WL_S1 and a second sidewall WL_S2 that are opposite to each other. The active patterns AP forming a row in the first direction D1 are disposed adjacent to the first sidewalls WL_S1 of the word lines WL, and may be spaced farther apart from the second sidewalls WL-S2 of the word lines WL.

Alternatively, referring to FIG. 30B, the back gate line BGL may be excluded between a pair of adjacent word lines WL in the arrangement of FIG. 2. For example, no back gate line BGL is interposed between two adjacent active patterns AP arranged in the second direction D2 in FIG. 30B.

Alternatively, referring to FIG. 30C, in the structure of FIG. 30A, the back gate line BGL may be spaced apart from the word line WL with a row of active patterns AP interposed therebetween. For example, the row of active patterns AP is disposed between a pair of adjacent back gate lines BGL and word lines WL. The back gate lines BGL and word lines WL may be alternately and repeatedly arranged in the second direction D2. For example, two adjacent active patterns AP arranged in the second direction D2 may be separated by one world line WL and one back gate line BGL.

Alternatively, referring to FIG. 30D, the semiconductor memory device according to an embodiment of the present inventive concept may have a double word line structure with a row of active patterns AP interposed therebetween. For example, the row of active patterns AP are arranged between a pair of adjacent word lines WL in the structure of FIG. 30A. The same voltage is applied to a pair of word lines WL adjacent to each other, such that they may operate as one word line WL.

Alternatively, referring to FIG. 30E, one word line WL may extend in the first direction D1 and surround each row of active patterns AP. For example, a portion of one word line WL may be interposed between the active patterns AP spaced apart from each other in the first direction D1. A gate insulating layer GOX may be interposed between one word line WL and one row of active patterns AP. The word line WL may have a gate all around (GAA) structure.

The arrangement and structure of word lines and active patterns are not limited to FIGS. 30A to 30E and may be variously changed.

The semiconductor memory device according to the present inventive concept provides the stacked memory device with the various connection structures. In the present inventive concept, the degree of freedom in the interconnection routing between the cell structure and the peripheral structures may be increased, the connection between the cell structure and the peripheral structures may be facilitated, and high integration may be realized.

While specific embodiments are described above, a person skilled in the art may understand that many modifications and variations can be made without departing from the spirit and scope of the present inventive concept as defined in the appended claims. Accordingly, the embodiments of the present inventive concept should be considered in all respects as illustrative and not restrictive, with the spirit and scope of the present inventive concept being indicated by the appended claims. The embodiments of FIG. 2 through FIG. 30E can be combined with each other.

What is claimed is:

1. A semiconductor memory device comprising:
a cell structure, a peripheral structure, and an interconnection structure sequentially stacked on a support substrate,
wherein the cell structure includes lower electrodes, a dielectric layer and an upper electrode, with the dielectric layer and the upper electrode sequentially covering the lower electrodes,
wherein the peripheral structure includes a peripheral substrate and transistors disposed on a front surface of the peripheral substrate, and
wherein an upper surface of the upper electrode faces a back surface of the peripheral substrate.

2. The semiconductor memory device of claim 1, wherein the cell structure further includes:
active patterns disposed between the lower electrodes and the support substrate and arranged two-dimensionally along an upper surface of the support substrate;
bit lines disposed between the active patterns and the support substrate and extending in a first direction; and
word lines being adjacent to sidewalls of the active patterns and extending in a second direction intersecting the first direction, and
wherein the semiconductor memory device further includes a through via penetrating the peripheral substrate to be connected to the interconnection structure and applying an electrical signal to one of the bit lines.

3. The semiconductor memory device of claim 2, wherein the cell structure further includes:
a first cell insulating layer covering the upper electrode;
first cell contact plugs disposed within the first cell insulating layer;
a second cell insulating layer disposed on the first cell insulating layer; and
cell interconnections disposed in the second cell insulating layer,
wherein the semiconductor memory device further includes an interface layer disposed between the back surface of the peripheral substrate and the second cell insulating layer, and
wherein the through via penetrates the interface layer and a part of the second cell insulating layer to be connected to one of the cell interconnections.

4. The semiconductor memory device of claim 2, wherein the through via vertically overlaps the upper electrode.

5. The semiconductor memory device of claim 2, wherein the cell structure further includes shield lines respectively disposed between the bit lines.

6. The semiconductor memory device of claim 5, wherein the support substrate includes a cell array region and a connection region,
wherein the shield lines extend across the cell array region to the connection region, and
wherein the cell structure further includes a shield plate connecting upper or lower surfaces of the shield lines.

7. The semiconductor memory device of claim 6, wherein the shield plate includes at least one opening exposing a portion of the bit lines, and
wherein the cell structure further includes bit line contact plugs connected to the bit lines through the at least one opening.

8. The semiconductor memory device of claim 1, wherein the cell structure further includes:
a first cell insulating layer covering the upper electrode;
first cell contact plugs disposed within the first cell insulating layer;
a second cell insulating layer disposed on the first cell insulating layer;
cell interconnections disposed in the second cell insulating layer; and
cell connection pads disposed within and at an upper end of the second cell insulating layer,
wherein the peripheral structure further includes:
a peripheral insulating layer disposed below the peripheral substrate;
peripheral connection pads disposed within and at a lower end of the peripheral insulating layer and contacting the cell connection pads, respectively; and
through vias penetrating the peripheral insulating layer and the peripheral substrate to connect the peripheral connection pads to the interconnection structure.

9. The semiconductor memory device of claim 1, wherein the upper electrode includes:
an electrode main portion that overlaps the lower electrodes and has a rectangular plane; and
an electrode protrusion that is connected to four corners of the electrode main portion and protrudes diagonally,
wherein a thickness of the electrode protrusion is thinner than a thickness of the electrode main portion, and
wherein the cell structure further includes upper electrode contact plugs in contact with the electrode protrusion.

10. A semiconductor memory device comprising:
a first peripheral structure, a cell structure, and an interconnection structure stacked sequentially,
wherein the cell structure includes:
a first cell insulating layer;
cell connection pads disposed within and at a lower end of the first cell insulating layer;
lower electrodes disposed on the first cell insulating layer; and
a dielectric layer and an upper electrode, the dielectric layer and the upper electrode sequentially covering the lower electrodes,
wherein the first peripheral structure includes:
a first peripheral substrate;
a first peripheral insulating layer covering a back surface of the first peripheral substrate;
peripheral connection pads disposed within and at an upper end of the first peripheral insulating layer and connected to the cell connection pads; and
first peripheral transistors disposed on a front surface of the first peripheral substrate, and
wherein a lower surface of the upper electrode faces the back surface of the first peripheral substrate.

11. The semiconductor memory device of claim 10, wherein the cell structure further includes:
active patterns disposed between the lower electrodes and the first cell insulating layer and arranged two-dimensionally along an upper surface of the first cell insulating layer;
bit lines disposed between the active patterns and the first cell insulating layer and extending in a first direction;
word lines adjacent to sidewalls of the active patterns and extending in a second direction intersecting the first direction; and
word line contact plugs penetrating the first cell insulating layer to be connected to ends of the word lines.

12. The semiconductor memory device of claim 11, wherein the cell structure further includes:
a second cell insulating layer covering the upper electrode; and
bit line contact plugs penetrating the second cell insulating layer to connect one of the bit lines to the interconnection structure.

13. The semiconductor memory device of claim 12, wherein the cell structure further includes:
a first cell contact plug penetrating the second cell insulating layer and the first cell insulating layer to connect one of the cell connection pads to the interconnection structure.

14. The semiconductor memory device of claim 10, wherein the first peripheral structure further includes a through via penetrating the first peripheral substrate and the first peripheral insulating layer to be connected to at least one of the peripheral connection pads.

15. The semiconductor memory device of claim 10, further comprising:
a second peripheral structure disposed below the first peripheral structure;
an interface layer disposed between the first peripheral structure and the second peripheral structure; and
a through via penetrating the first peripheral structure and the interface layer to be connected to the second peripheral structure,
wherein the first peripheral structure further includes a second peripheral insulating layer covering the first peripheral transistors,
wherein the second peripheral structure includes a second peripheral substrate, second peripheral transistors on a front surface of the second peripheral substrate, and a third peripheral insulating layer covering the front surface of the second peripheral substrate, and
wherein a lower surface of the second peripheral insulating layer faces an upper surface of the third peripheral insulating layer.

16. A semiconductor memory device comprising:
a peripheral structure, a cell structure, and an interconnection structure stacked sequentially,
wherein the peripheral structure includes:
a peripheral substrate;
transistors disposed on a front surface of the peripheral substrate;
a first peripheral insulating layer covering the front surface of the peripheral substrate; and
first peripheral interconnections disposed within the first peripheral insulating layer,
wherein the cell structure includes:
first to third cell insulating layers sequentially covering the peripheral structure;
first cell interconnections disposed in the first cell insulating layer;
lower electrodes, a dielectric layer, and an upper electrode disposed in the second cell insulating layer; and
active patterns, word lines, and bit lines disposed in the third cell insulating layer,
wherein the bit lines connect upper surfaces of the active patterns and extend in a first direction,
wherein the word lines are adjacent to one side of the active patterns and extend in a second direction intersecting the first direction,
wherein the dielectric layer and the upper electrode sequentially cover sidewalls and lower surfaces of the lower electrodes, and
wherein a first distance between the upper electrode and the peripheral substrate is smaller than a second distance between the lower electrodes and the peripheral substrate.

17. The semiconductor memory device of claim 16, further comprising:
an interface layer disposed between a back surface of the peripheral substrate and the first cell insulating layer; and
a through via penetrating the third cell insulating layer, the second cell insulating layer, the first cell insulating layer, the interface layer, the peripheral substrate, and a part of the first peripheral insulating layer to connect one of the first peripheral interconnections to the interconnection structure.

18. The semiconductor memory device of claim 16, wherein the cell structure further includes:
cell connection pads disposed within and at a lower end of the first cell insulating layer; and
a cell contact plug penetrating at least one of the first to third cell insulating layers to connect one of the cell connection pads to the interconnection structure,
wherein the peripheral structure further includes:
a second peripheral insulating layer covering a back surface of the peripheral substrate;
peripheral connection pads disposed within and at an upper end of the second peripheral insulating layer and respectively connected to the cell connection pads; and
a through via penetrating the second peripheral insulating layer, the peripheral substrate, and a part of the first peripheral insulating layer to connect one of the peripheral connection pads to one of the first peripheral interconnections.

19. The semiconductor memory device of claim 18, further comprising a bit line contact plug penetrating the first cell insulating layer, the second cell insulating layer, and the third cell insulating layer to connect one of the bit lines to one of the cell connection pads.

20. The semiconductor memory device of claim 16, further comprising a word line contact plug penetrating a part of the third cell insulating layer to connect one of the word lines to the interconnection structure.
